(19) United States
(12) Patent Application Publication
(10) Pub. No.: US 2026/0020434 A1
(43) Pub. Date: Jan. 15, 2026

(54) Light-Emitting Device

(71) Applicant: Semiconductor Energy Laboratory Co., Ltd., Kanagawa-ken (JP)

(72) Inventors: Yasuhiro Niikura, Tokyo (JP); Tsunenori Suzuki, Yokohama (JP); Sachiko Kawakami, Atsugi (JP); Yuki Hayashi, Atsugi (JP); Satoshi Seo, Sagamihara (JP)

(73) Assignee: Semiconductor Energy Laboratory Co., Ltd., Kanagawa-ken (JP)

(21) Appl. No.: 19/262,432

(22) Filed: Jul. 8, 2025

(30) Foreign Application Priority Data
Jul. 12, 2024 (JP) 2024-112240

(51) Int. Cl. H10K 50/13; H10K 50/15; H10K 50/16; H10K 59/123; H10K 59/131; H10K 59/35; H10K 59/38; H10K 85/60

(52) U.S. Cl. CPC H10K 50/13; H10K 50/15; H10K 50/16; H10K 59/123; H10K 59/131; H10K 59/351; H10K 59/38; H10K 85/626; H10K 85/633; H10K 85/636; H10K 85/6572; H10K 85/6574

(57) ABSTRACT

A light-emitting device with high emission efficiency is provided. A light-emitting device with high reliability is provided. A light-emitting device with high emission efficiency and high reliability is provided. The light-emitting device includes a first electrode, a second electrode, a light-emitting layer positioned between the first electrode and the second electrode, and a cap layer. The second electrode is positioned between the light-emitting layer and the cap layer. The cap layer includes at least a first substance and a second substance. The first substance and the second substance are substances having a difference of 0.1 or more between ordinary refractive indices of respective evaporated films at a wavelength of 380 nm to 760 nm. The first substance is a monoamine compound having an alkyl group. The second substance is an organic compound having a carbazole skeleton.

### BACKGROUND OF THE INVENTION

### 1. Field of the Invention

One embodiment of the present invention relates to an organic compound, an organic semiconductor element, a light-emitting device, a photodiode sensor, a display module, a lighting module, a display device, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, specific examples of the technical field of one embodiment of the present invention disclosed in this specification include a semiconductor device, a display device, a liquid crystal display device, a lighting device, a power storage device, a memory device, an imaging device, a driving method thereof, and a manufacturing method thereof.

### 2. Description of the Related Art

Light-emitting devices (also referred to as organic EL elements) including organic compounds and utilizing electroluminescence (EL) have been put into practical use. In the basic structure of such light-emitting devices, an organic compound layer including a light-emitting material is sandwiched between a pair of electrodes. Carriers are injected by application of voltage to the device, and recombination energy of the carriers is used, whereby light emission can be obtained from the light-emitting material.

Since such light-emitting devices are of self-luminous type, display devices in which the light-emitting devices are used in pixels have higher visibility than liquid crystal display devices and do not need a backlight. Display devices that include such light-emitting devices are also highly advantageous in that they can be thin and lightweight. Another feature of such light-emitting devices is that they have an extremely fast response speed.

Since light-emitting layers of such light-emitting devices can be successively formed in a planar shape, planar light emission can be achieved. This feature is difficult to realize with point light sources typified by incandescent lamps and LEDs or linear light sources typified by fluorescent lamps; thus, the light-emitting devices also have great potential as planar light sources, which can be used for lighting devices and the like.

Display devices or lighting devices that include light-emitting devices are suitable for a variety of electronic appliances as described above, and research and development of light-emitting devices have progressed for better characteristics.

Patent Document 1 discloses a light-emitting device utilizing organic electroluminescence and including a capping layer capable of improving light extraction efficiency.

### REFERENCE

### Patent Document

[Patent Document 1] Japanese Published Patent Application No. 2015-092485

### SUMMARY OF THE INVENTION

An object of one embodiment of the present invention is to provide a novel light-emitting device. Another object of one embodiment of the present invention is to provide a light-emitting device with favorable characteristics. Another object of one embodiment of the present invention is to provide a light-emitting device with high reliability. Another object of one embodiment of the present invention is to provide a light-emitting device with high emission efficiency. Another object of one embodiment of the present invention is to provide a light-emitting device with high reliability and high emission efficiency.

Another object of one embodiment of the present invention is to provide a display device with favorable characteristics. Another object of one embodiment of the present invention is to provide a display device with high reliability. Another object of one embodiment of the present invention is to provide a display device with low power consumption. Another object of one embodiment of the present invention is to provide a light-emitting device with high reliability and low power consumption.

Another object of one embodiment of the present invention is to provide any of an electronic appliance with high reliability and a lighting device with high reliability. Another object of one embodiment of the present invention is to provide any of an electronic appliance with low power consumption and a lighting device with low power consumption.

It is acceptable that at least one of the above-described objects be achieved in the present invention. Note that the description of these objects does not preclude the presence of other objects. In one embodiment of the present invention, there is no need to achieve all of these objects. Other objects will be apparent from and can be derived from the description of the specification, the drawings, the claims, and the like.

One embodiment of the present invention is a light-emitting device that includes a first electrode, a second electrode, a light-emitting layer positioned between the first electrode and the second electrode, and a cap layer. The second electrode is positioned between the light-emitting layer and the cap layer. The cap layer includes at least a first substance and a second substance. The first substance and the second substance are substances having a difference of 0.1 or more between ordinary refractive indices of respective evaporated films at a wavelength of 380 nm to 760 nm. The first substance is a monoamine compound having an alkyl group. The second substance is an organic compound having a carbazole skeleton.

Another embodiment of the present invention is a light-emitting device that includes a first electrode, a second electrode, a light-emitting layer positioned between the first electrode and the second electrode, and a cap layer. The second electrode is positioned between the light-emitting layer and the cap layer. The cap layer includes at least a first layer including a first substance and a second layer including a second substance. The first substance and the second substance are substances having a difference of 0.1 or more between ordinary refractive indices of respective evaporated films at a wavelength of 380 nm to 760 nm. The first substance is a monoamine compound having an alkyl group. The second substance is an organic compound having a carbazole skeleton.

Another embodiment of the present invention is a light-emitting device that includes a first electrode, a second electrode, a light-emitting layer positioned between the first electrode and the second electrode, and a cap layer. The second electrode is positioned between the light-emitting layer and the cap layer. The cap layer includes at least a first layer including a second substance and a second layer including a first substance. The first layer is positioned between the second electrode and the second layer. The first substance and the second substance are substances having a difference of 0.1 or more between ordinary refractive indices of respective evaporated films at a wavelength of 380 nm to 760 nm. The first substance is a monoamine compound having an alkyl group. The second substance is an organic compound having a carbazole skeleton.

Another embodiment of the present invention is a light-emitting device that includes a first electrode, a second electrode, a light-emitting layer positioned between the first electrode and the second electrode, and a cap layer. The second electrode is positioned between the light-emitting layer and the cap layer. The cap layer includes at least a first layer including a first substance and a second layer including a second substance. The first layer is in contact with the second electrode. The first substance and the second substance are substances having a difference of 0.1 or more between ordinary refractive indices of respective evaporated films at a wavelength of 380 nm to 760 nm. The first substance is a monoamine compound having an alkyl group. The second substance is an organic compound having a carbazole skeleton.

Another embodiment of the present invention is the light-emitting device having any of the above structures, in which the first substance and the second substance are substances having a difference of 0.3 or more between ordinary refractive indices of respective evaporated films at a wavelength of 380 nm to 760 nm.

Another embodiment of the present invention is the light-emitting device having any of the above structures, in which the monoamine compound does not include a trifluoromethyl group.

Another embodiment of the present invention is the light-emitting device having any of the above structures, in which the monoamine compound is an organic compound represented by General Formula (G_{L}1).

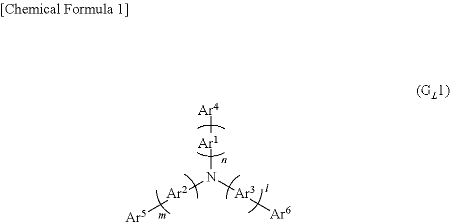

In the organic compound represented by General Formula (G_{L}1), Ar¹ to Ar³ each independently represent any one of a substituted or unsubstituted arylene group having 6 to 30 carbon atoms and a substituted or unsubstituted heteroarylene group having 1 to 30 carbon atoms, Ar⁴ to Ar⁶ each independently represent any one of a substituted or unsubstituted aryl group having 6 to 30 carbon atoms and a substituted or unsubstituted heteroaryl group having 1 to 30 carbon atoms, and n, m, and l each independently represent any one integer of 0 to 3. In the case where one or more of n, m, and l represent 2 or more, a plurality of Aris may be the same or different from each other, a plurality of Ar²s may be the same or different from each other, and a plurality of Ar³s may be the same or different from each other. The organic compound represented by General Formula (G_{L}1) includes one or more alkyl groups and the one or more alkyl groups are each any of a straight-chain or branched-chain alkyl group having 1 to 10 carbon atoms and a cycloalkyl group having 3 to 10 carbon atoms. Note that hydrogen atoms in the organic compound represented by General Formula (G_{L}1) may each independently be a deuterium atom.

Another embodiment of the present invention is the light-emitting device having any of the above structures, in which the organic compound having a carbazole skeleton is an organic compound represented by General Formula (G_{H}1).

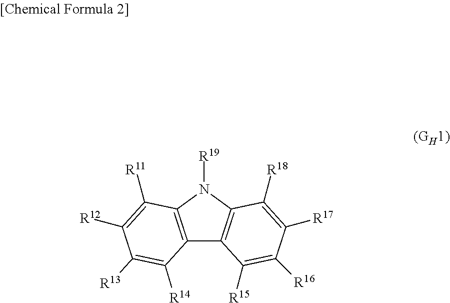

In the organic compound represented by General Formula (G_{H}1), R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms. Note that all hydrogen atoms may be deuterium atoms. The aromatic hydrocarbon group and the heteroaromatic group may each have a structure in which a plurality of rings are bonded to each other. In the case of the structure in which the plurality of rings are bonded to each other, the plurality of rings may be composed of a plurality of aromatic hydrocarbon groups, a plurality of heteroaromatic groups, or both an aromatic hydrocarbon group and a heteroaromatic group.

Another embodiment of the present invention is the light-emitting device having any of the above structures, in which the monoamine compound is an organic compound represented by General Formula (G_{L}1) and the organic compound having a carbazole skeleton is an organic compound represented by General Formula (G_{H}1).

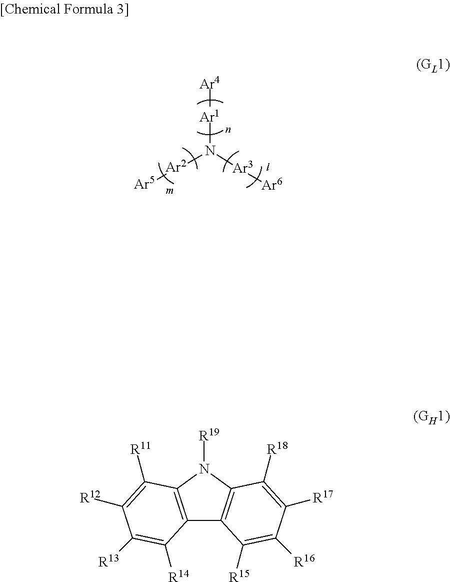

In the organic compound represented by General Formula (G_{L}1), Ar¹ to Ar³ each independently represent any one of a substituted or unsubstituted arylene group having 6 to 30 carbon atoms and a substituted or unsubstituted heteroarylene group having 1 to 30 carbon atoms, Ar⁴ to Ar⁶ each independently represent any one of a substituted or unsubstituted aryl group having 6 to 30 carbon atoms and a substituted or unsubstituted heteroaryl group having 1 to 30 carbon atoms, and n, m, and l each independently represent any one integer of 0 to 3. In the case where one or more of n, m, and l represent 2 or more, a plurality of Aris may be the same or different from each other, a plurality of Ar²s may be the same or different from each other, and a plurality of Ar³s may be the same or different from each other. The organic compound represented by General Formula (G_{L}1) includes one or more alkyl groups and the one or more alkyl groups are each any of a straight-chain or branched-chain alkyl group having 1 to 10 carbon atoms and a cycloalkyl group having 3 to 10 carbon atoms. Note that hydrogen atoms in the organic compound represented by General Formula (G_{L}1) may each independently be a deuterium atom.

In the organic compound represented by General Formula (G_{H}1), R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms. Note that all hydrogen atoms may be deuterium atoms. The aromatic hydrocarbon group and the heteroaromatic group may each have a structure in which a plurality of rings are bonded to each other. In the case of the structure in which the plurality of rings are bonded to each other, the plurality of rings may be composed of a plurality of aromatic hydrocarbon groups, a plurality of heteroaromatic groups, or both an aromatic hydrocarbon group and a heteroaromatic group.

Another embodiment of the present invention is the light-emitting device having any of the above structures, in which an ordinary refractive index of the evaporated film of the first substance is lower than or equal to 1.70 at a wavelength of 450 nm and an ordinary refractive index of the evaporated film of the second substance is higher than or equal to 1.80 at a wavelength of 450 nm.

Another embodiment of the present invention is the light-emitting device having any of the above structures, in which an ordinary refractive index of the evaporated film of the first substance is lower than or equal to 1.70 at a wavelength of 450 nm and an ordinary refractive index of the evaporated film of the second substance is higher than or equal to 2.00 at a wavelength of 450 nm.

Another embodiment of the present invention is a display device including any of the above-described light-emitting devices.

Another embodiment of the present invention is an electronic appliance including any of the above-described light-emitting devices, and any of a sensor, an operation button, a speaker, and a microphone.

Another embodiment of the present invention is a lighting device including any of the above-described light-emitting devices and a housing.

One embodiment of the present invention can provide a novel light-emitting device. Another embodiment of the present invention can provide a light-emitting device with favorable characteristics. Another embodiment of the present invention can provide a light-emitting device with high reliability. Another embodiment of the present invention can provide a light-emitting device with high emission efficiency. Another embodiment of the present invention can provide a light-emitting device with high reliability and high emission efficiency.

Another embodiment of the present invention can provide a display device with favorable characteristics. Another embodiment of the present invention can provide a display device with high reliability. Another embodiment of the present invention can provide a display device with low power consumption. Another embodiment of the present invention can provide a light-emitting device with high reliability and low power consumption.

Another embodiment of the present invention can provide any of an electronic appliance with high reliability and a lighting device with high reliability. Another embodiment of the present invention can provide any of an electronic appliance with low power consumption and a lighting device with low power consumption.

Note that the description of these effects does not preclude the presence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

### In the Accompanying Drawings:

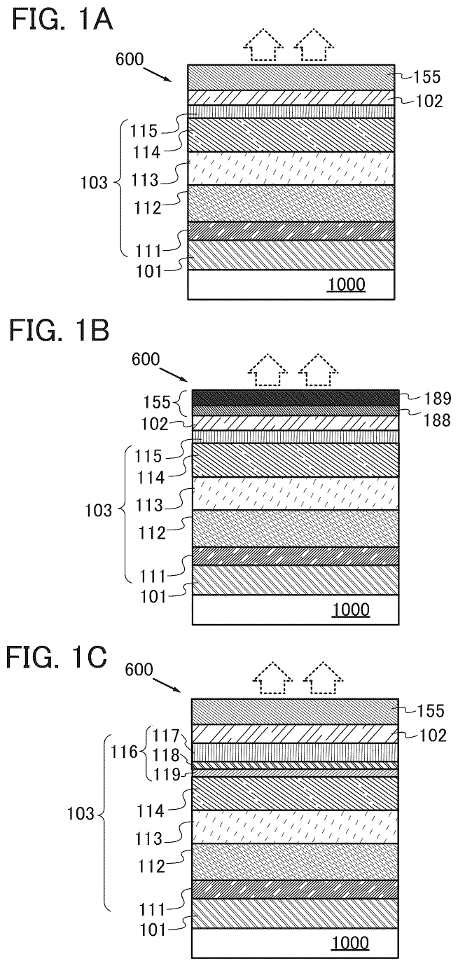

FIGS. 1A to 1C are each a schematic view of a light-emitting device of one embodiment of the present invention;

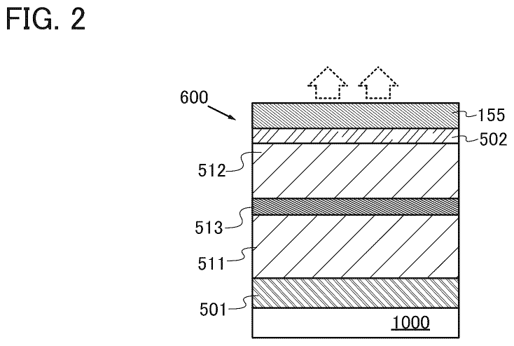

FIG. 2 is a schematic view of a light-emitting device of one embodiment of the present invention;

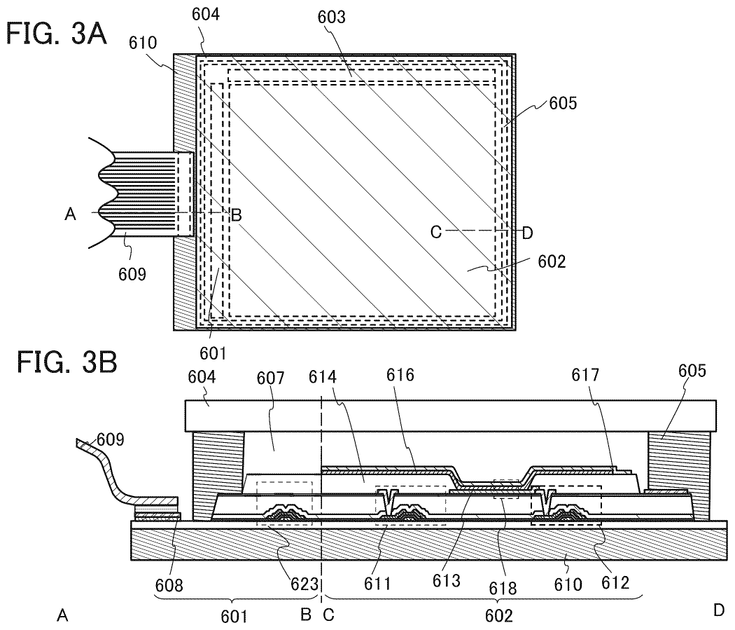

FIGS. 3A and 3B illustrate a display device of one embodiment of the present invention;

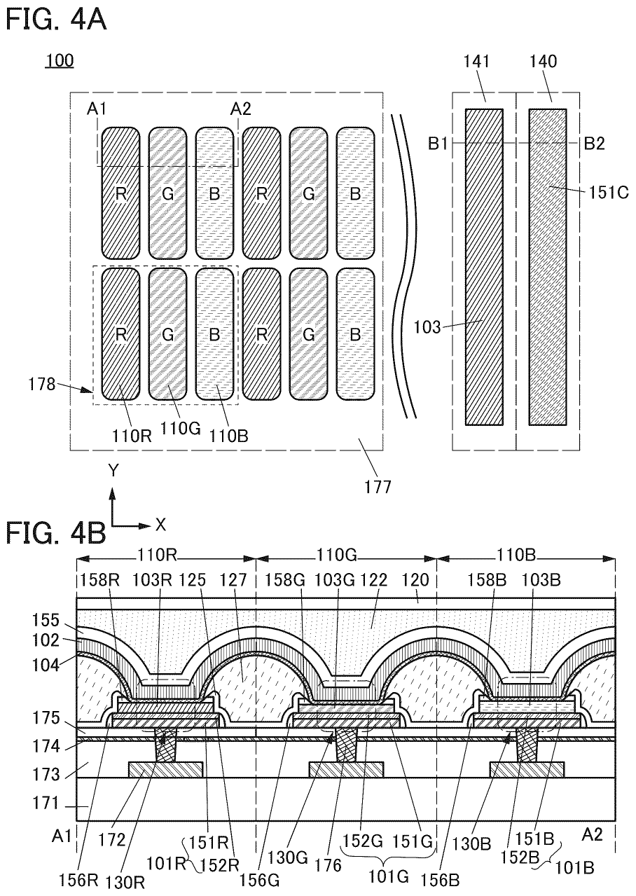

FIGS. 4A and 4B illustrate a display device of one embodiment of the present invention;

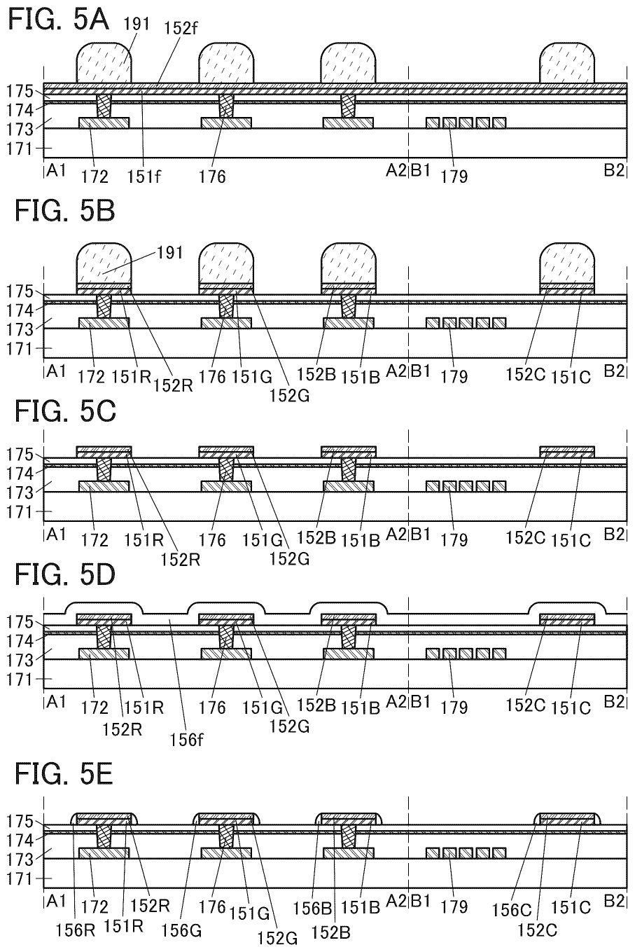

FIGS. 5A to 5E are cross-sectional views illustrating an example of a method for manufacturing a display device;

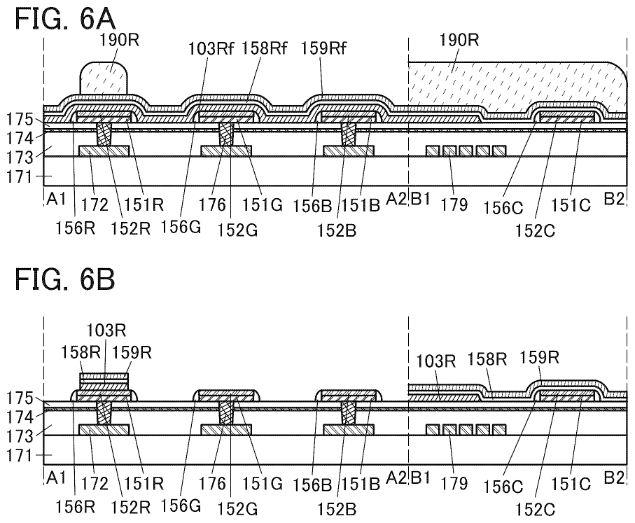

FIGS. 6A and 6B are cross-sectional views illustrating an example of a method for manufacturing a display device;

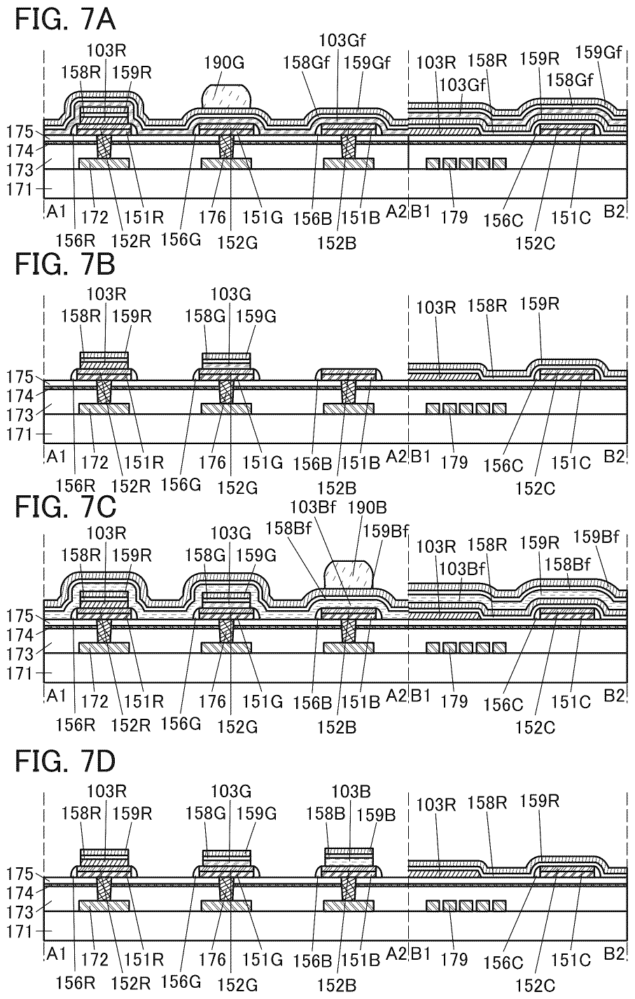

FIGS. 7A to 7D are cross-sectional views illustrating an example of a method for manufacturing a display device;

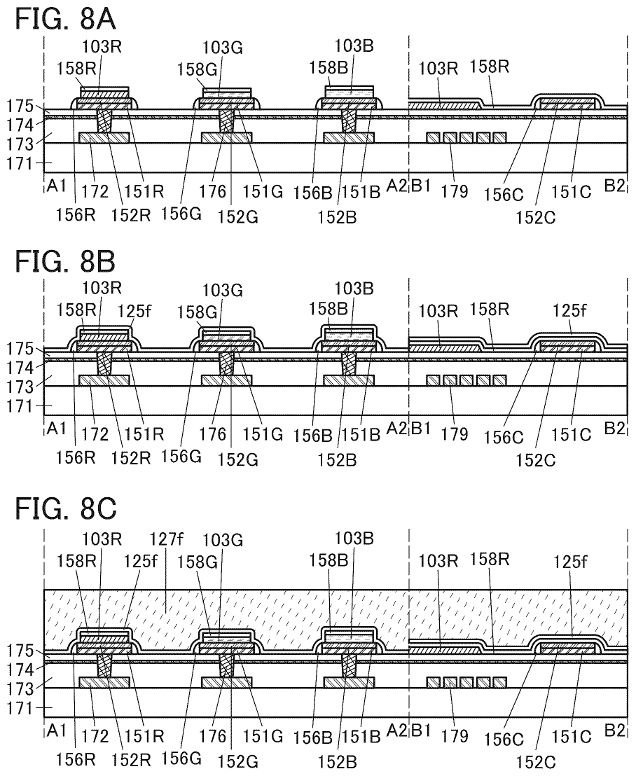

FIGS. 8A to 8C are cross-sectional views illustrating an example of a method for manufacturing a display device;

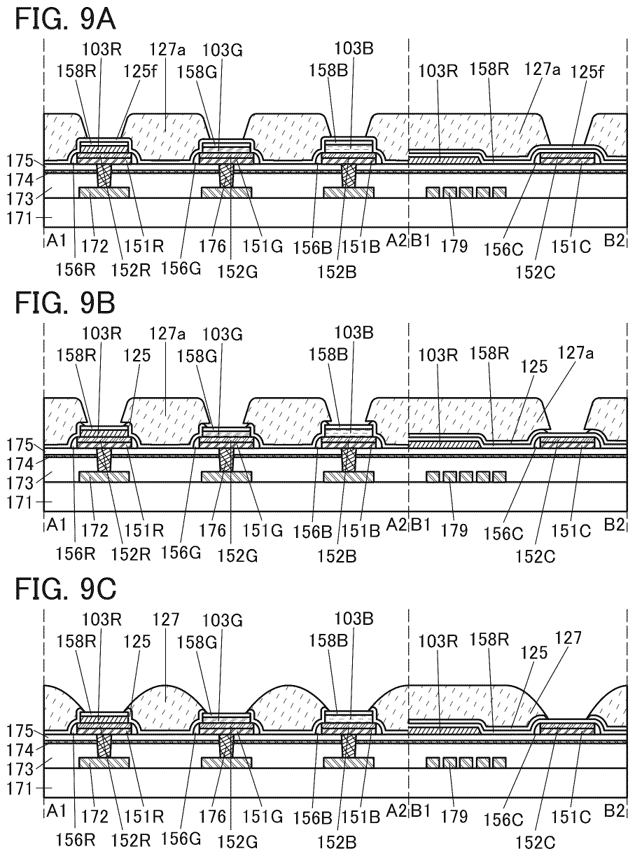

FIGS. 9A to 9C are cross-sectional views illustrating an example of a method for manufacturing a display device;

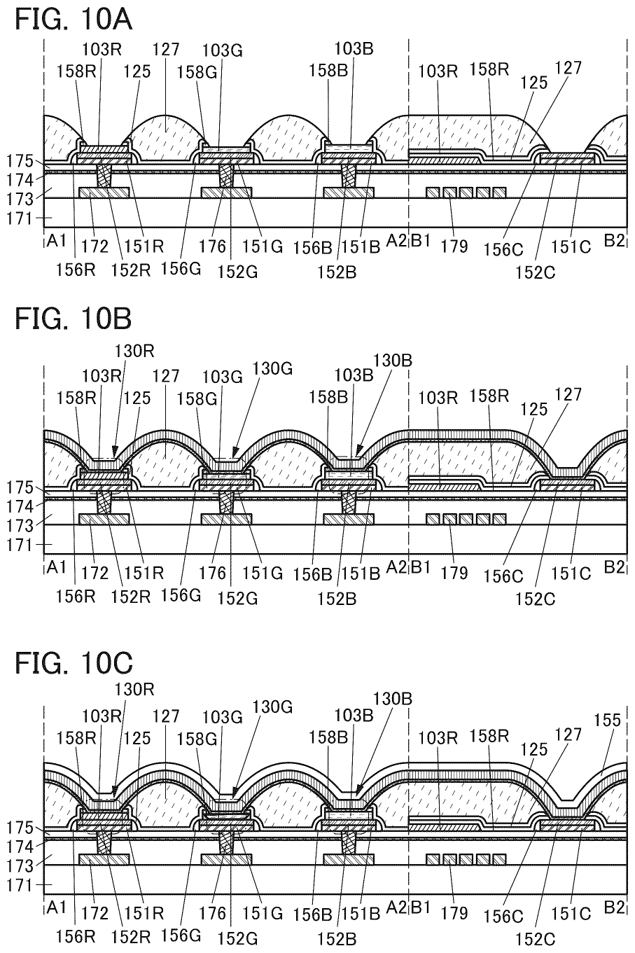

FIGS. 10A to 10C are cross-sectional views illustrating an example of a method for manufacturing a display device;

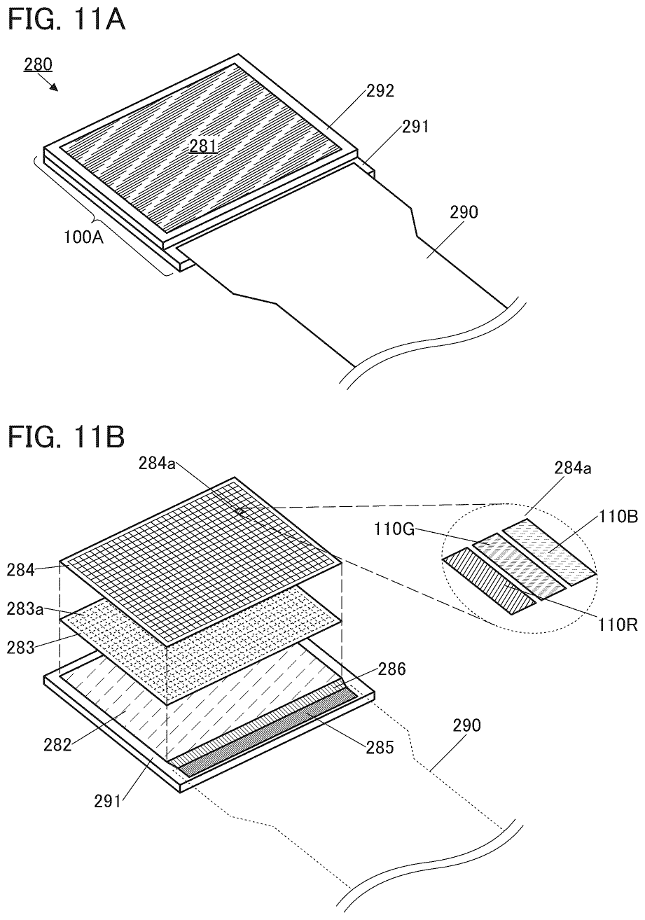

FIGS. 11A and 11B are perspective views illustrating a structure example of a display module;

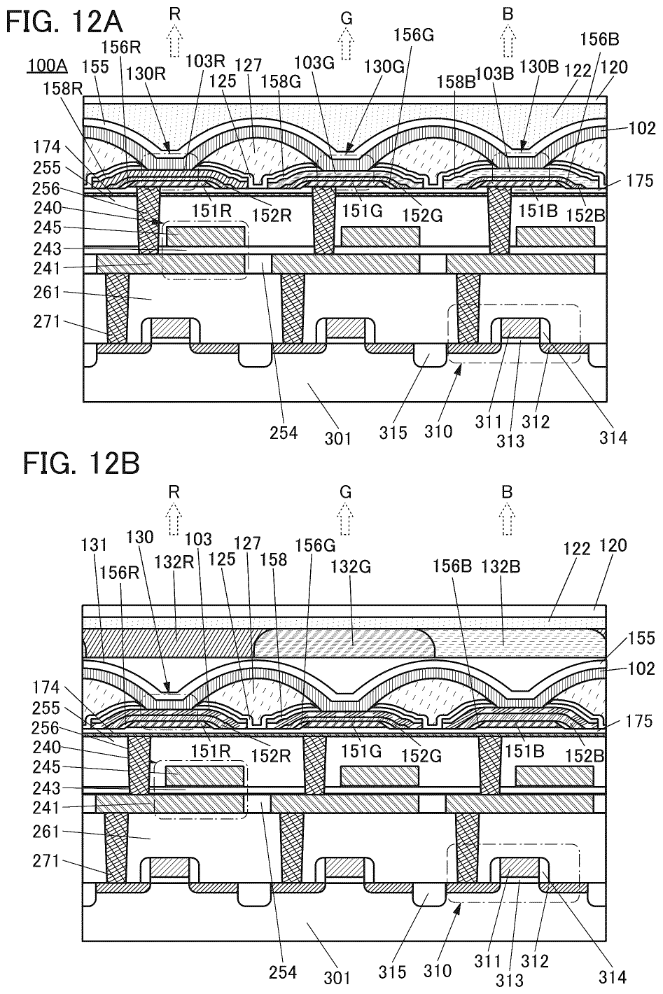

FIGS. 12A and 12B are cross-sectional views illustrating structure examples of display devices;

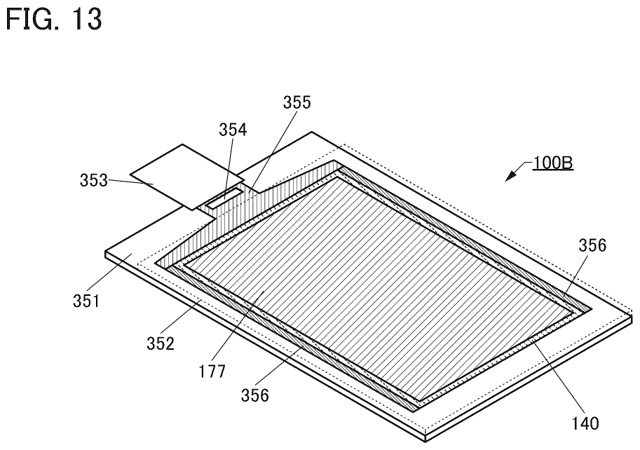

FIG. 13 is a perspective view illustrating a structure example of a display device;

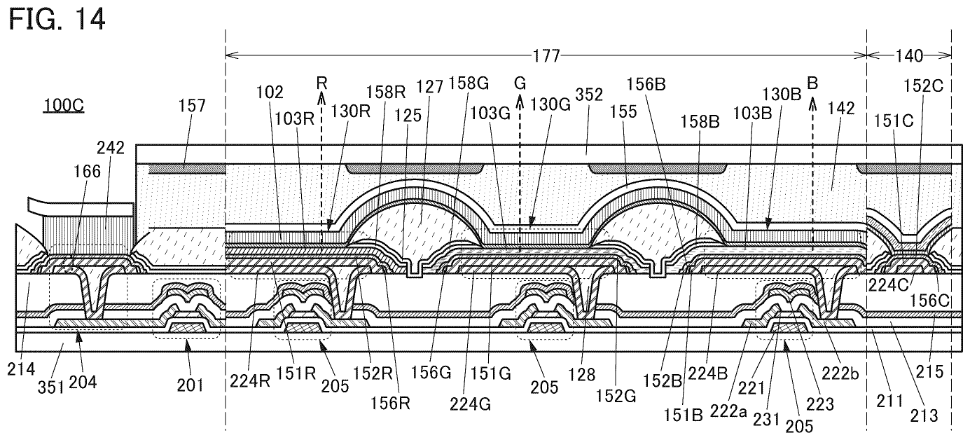

FIG. 14 is a cross-sectional view illustrating a structure example of a display device;

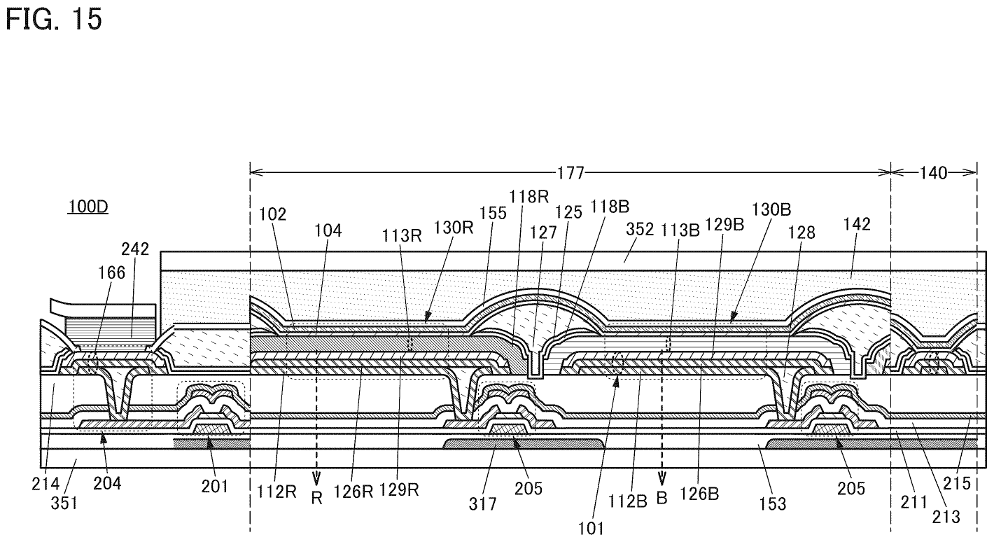

FIG. 15 is a cross-sectional view illustrating a structure example of a display device;

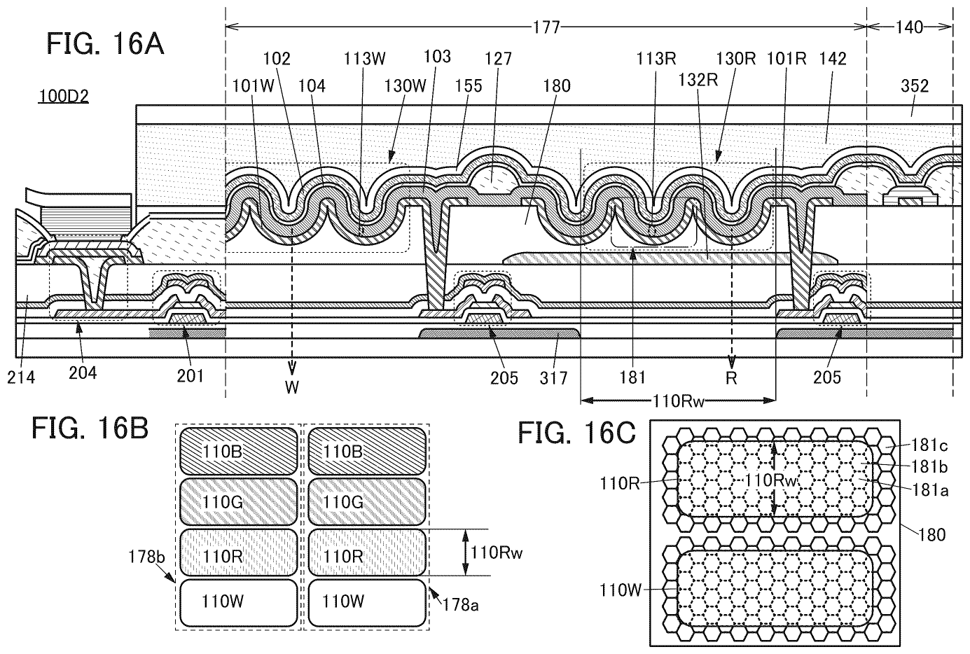

FIGS. 16A to 16C illustrate a structure example of a display device;

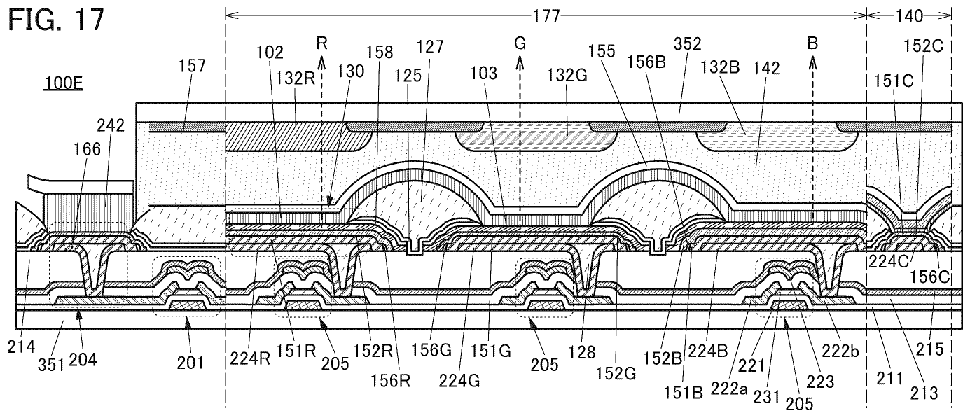

FIG. 17 is a cross-sectional view illustrating a structure example of a display device;

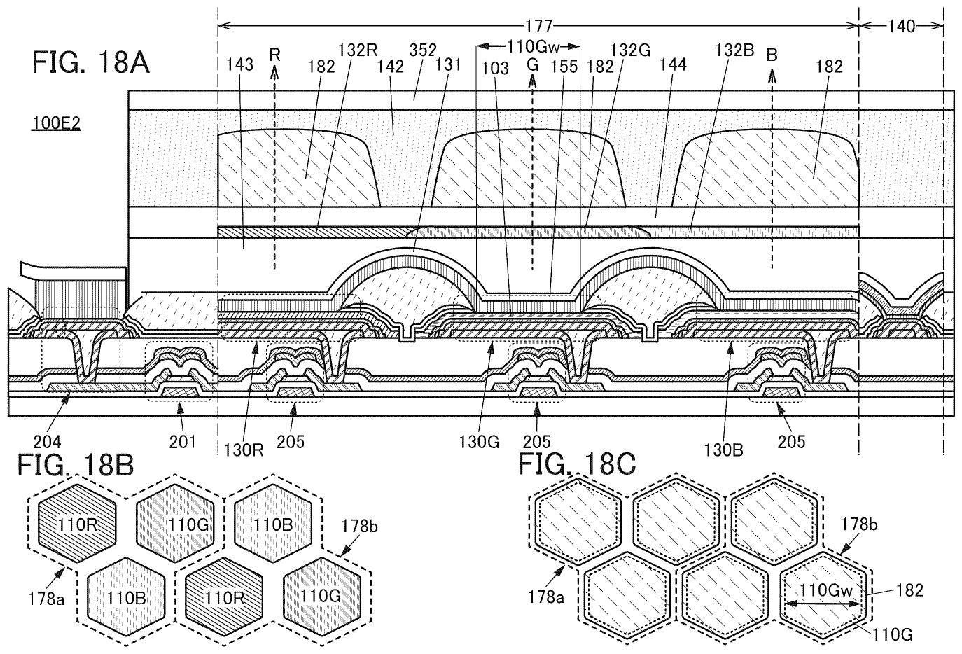

FIGS. 18A to 18C illustrate a structure example of a display device;

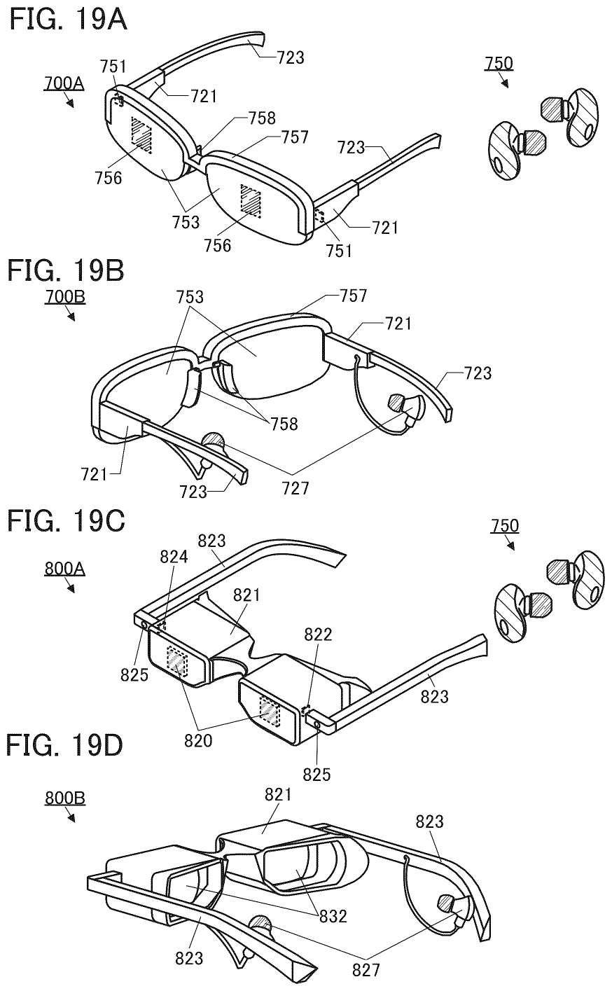

FIGS. 19A to 19D each illustrate an example of an electronic appliance;

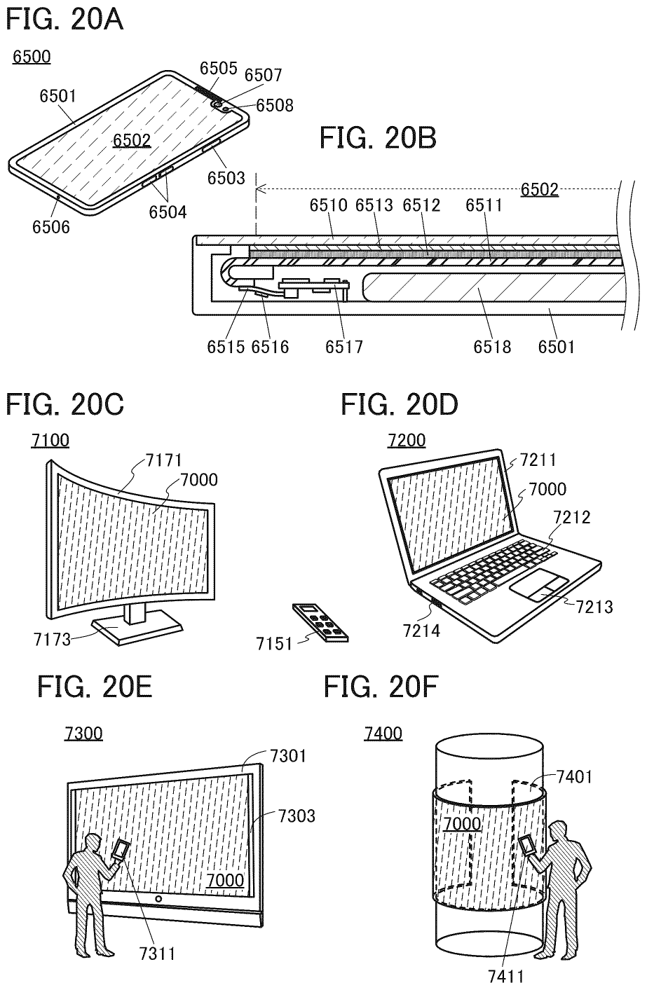

FIGS. 20A to 20F each illustrate an example of an electronic appliance;

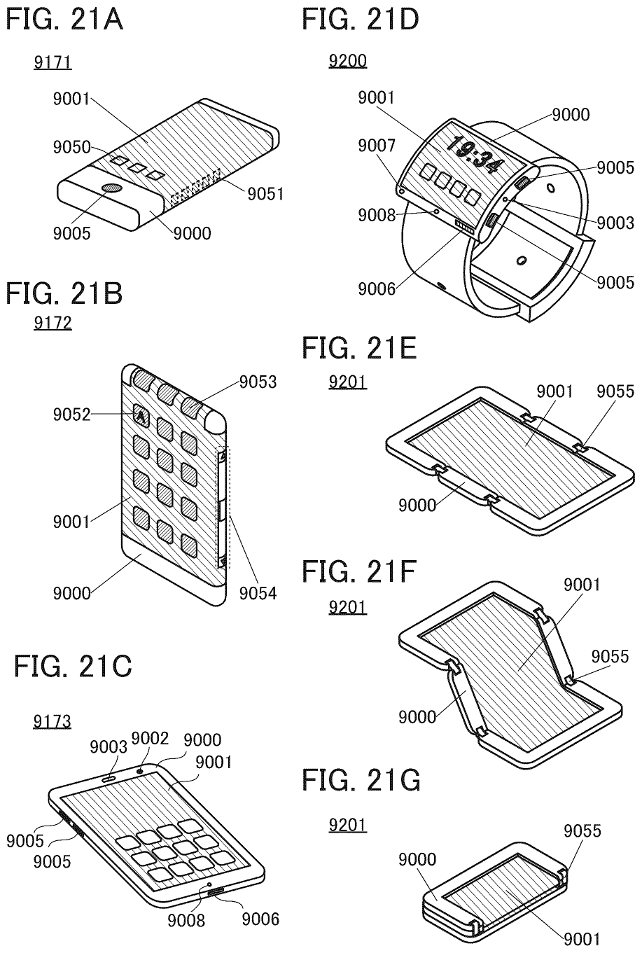

FIGS. 21A to 21G each illustrate an example of an electronic appliance;

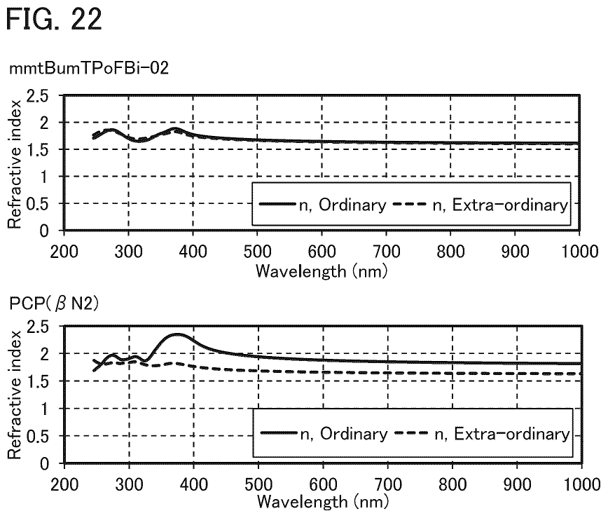

FIG. 22 shows refractive indices of mmtBumTPoFBi-02 and PCP(βN2);

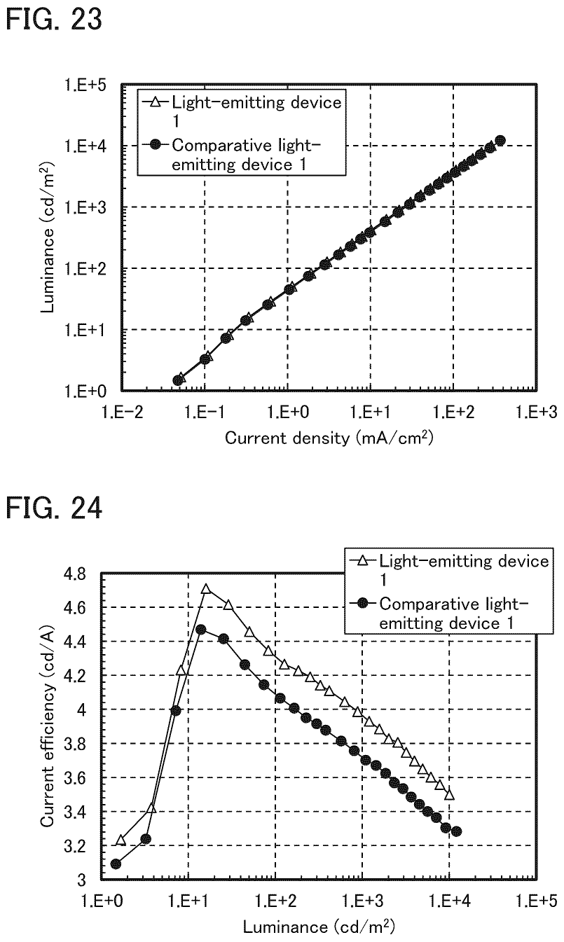

FIG. 23 shows the luminance-current density characteristics of a light-emitting device 1 and a comparative light-emitting device 1;

FIG. 24 shows the current efficiency-luminance characteristics of the light-emitting device 1 and the comparative light-emitting device 1;

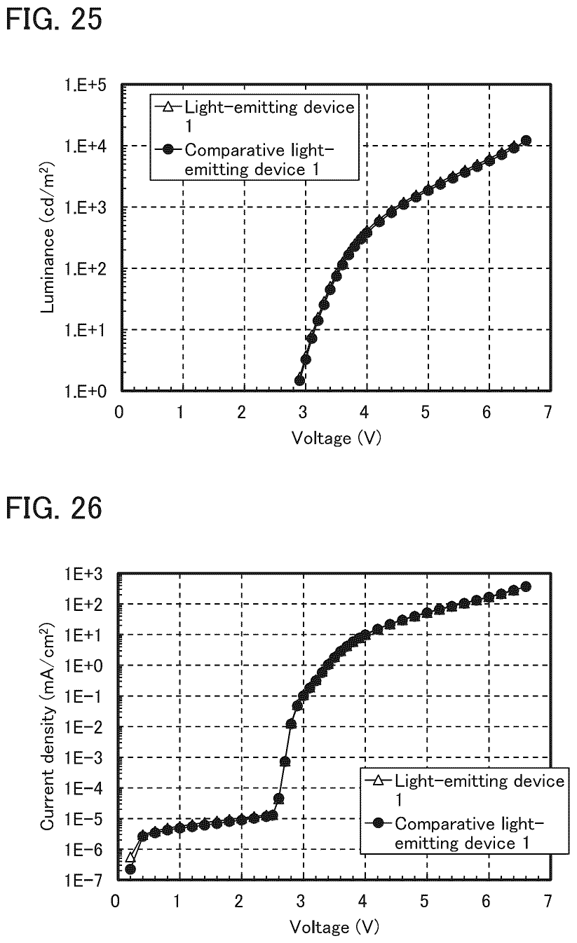

FIG. 25 shows the luminance-voltage characteristics of the light-emitting device 1 and the comparative light-emitting device 1;

FIG. 26 shows the current density-voltage characteristics of the light-emitting device 1 and the comparative light-emitting device 1;

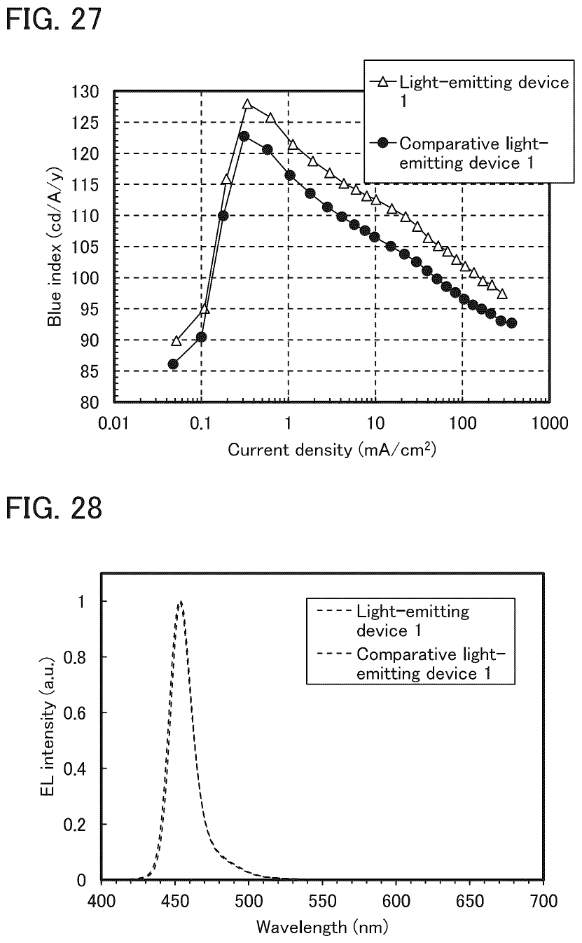

FIG. 27 shows the blue index-current density characteristics of the light-emitting device 1 and the comparative light-emitting device 1;

FIG. 28 shows electroluminescence spectra of the light-emitting device 1 and the comparative light-emitting device 1;

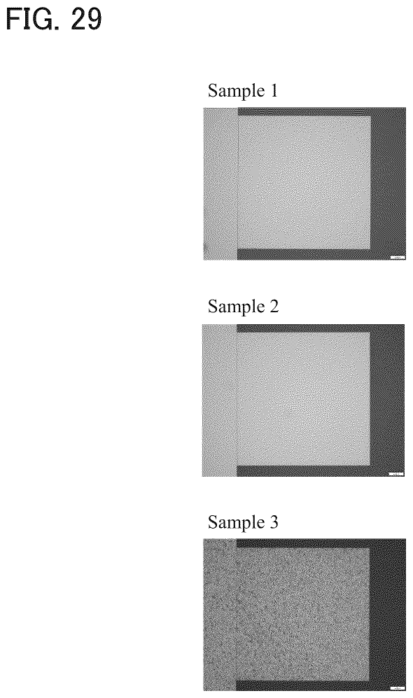

FIG. 29 shows reflected bright-field images of a sample 1 to a sample 3 with an optical microscope after a high-temperature preservation test;

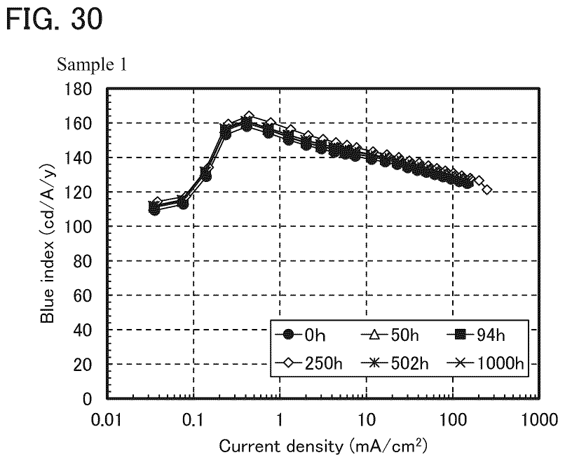

FIG. 30 shows the blue index-current density characteristics of the sample 1;

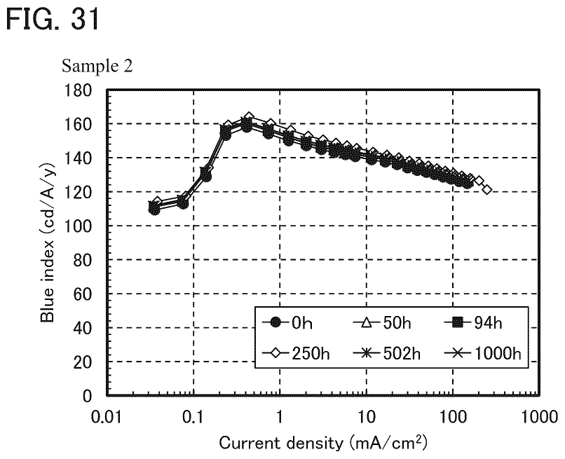

FIG. 31 shows the blue index-current density characteristics of the sample 2; and

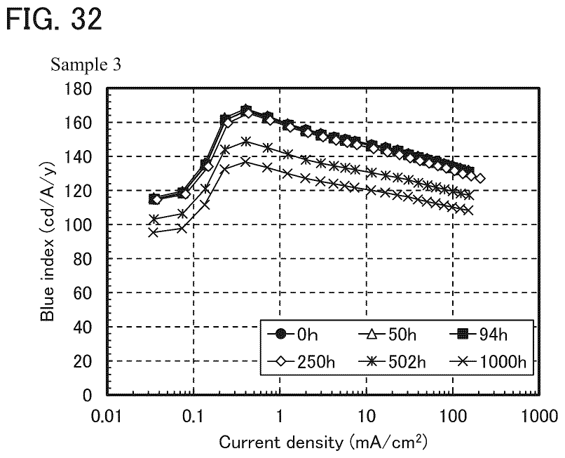

FIG. 32 shows the blue index-current density characteristics of the sample 3.

### DETAILED DESCRIPTION OF THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Ordinal numbers such as “first” and “second” in this specification and the like are used in order to avoid confusion among components. Thus, the terms do not limit the number of components or the order of components (e.g., the order of steps or the stacking order of layers). A term without an ordinal number in this specification and the like may be described with an ordinal number in a claim in order to avoid confusion among components. A term with an ordinal number in this specification and the like may be described with a different ordinal number in a claim. A term with an ordinal number in this specification and the like may be described without an ordinal number in a claim.

In this specification and the like, a device manufactured using a metal mask or a fine metal mask (FMM) is sometimes referred to as a device having a metal mask (MM) structure. In this specification and the like, a device manufactured without using a metal mask or an FMM is sometimes referred to as a device having a metal maskless (MML) structure.

In the case where light is incident on a material having optical anisotropy, light with a plane of vibration parallel to the optical axis is referred to as extraordinary light (rays) and light with a plane of vibration perpendicular to the optical axis is referred to as ordinary light (rays); the refractive index of the material with respect to ordinary light may differ from that with respect to extraordinary light. In such a case, the ordinary refractive index and the extraordinary refractive index can be separately calculated by anisotropy analysis. Note that in the case where the measured material has both the ordinary refractive index and the extraordinary refractive index, the ordinary refractive index is used as an index in this specification.

As is the case with the refractive index, the extinction coefficient with respect to ordinary light may differ from that with respect to extraordinary light, and the ordinary extinction coefficient and the extraordinary extinction coefficient can be separately calculated by anisotropy analysis. In the case where the measured material has both the ordinary extinction coefficient and the extraordinary extinction coefficient, the ordinary extinction coefficient is used as an index in this specification.

An evaporated film in this specification refers to a film deposited by an evaporation method in the state where a substrate is at room temperature.

Note that in this specification and the like, a photoluminescence (PL) spectrum refers to a spectrum obtained by measuring the wavelength of light emission while an excitation wavelength of excitation light is fixed in a fluorometry. Such a spectrum is also referred to as an emission spectrum in some cases. Note that an emission spectrum may include a fluorescent component and a phosphorescent component. In this specification and the like, an emission spectrum including a fluorescent component is particularly referred to as a fluorescent spectrum, and an emission spectrum including a phosphorescent component is particularly referred to as a phosphorescent spectrum in some cases.

### Embodiment 1

FIGS. 1A to 1C each illustrate a light-emitting device 600 of one embodiment of the present invention. The light-emitting devices illustrated in FIGS. 1A to 1C each include a first electrode 101, a second electrode 102, an organic compound layer 103, and a cap layer 155. The organic compound layer 103 includes at least a light-emitting layer 113.

Here, the second electrode 102 of each of the light-emitting devices illustrated in FIGS. 1A to 1C is a light-transmitting electrode; each of the light-emitting devices illustrated in FIGS. 1A to 1C is what is called a top-emission light-emitting device that emits light from the second electrode 102 side. Note that the light-emitting device of one embodiment of the present invention may be a dual-emission light-emitting device that emits light from both the first electrode 101 side and the second electrode 102 side.

The second electrode 102 is provided in contact with and sandwiched between the organic compound layer 103 and the cap layer 155. The cap layer 155 provided over the second electrode 102 can increase the light extraction efficiency.

The cap layer 155 is a layer including at least a first substance and a second substance. The first substance is a monoamine compound having an alkyl group. The second substance is an organic compound having a carbazole skeleton.

When the first substance and the second substance are included in the cap layer 155, an evaporated film with improved heat resistance and favorable film quality can be used as the cap layer. Since the highly stable cap layer can be formed, a highly reliable light-emitting device can be provided. It is thus possible to provide a device that has high reliability in an environment where high-temperature driving or high-temperature preservation is required.

Note that each of a plurality of substances included in the cap layer 155 is preferably an organic compound, in which case the cap layer can be formed successively by vacuum evaporation after the formation of the electrode.

The cap layer 155 preferably includes a first layer including the first substance and a second layer including the second substance. The monoamine compound having an alkyl group, which is the first substance included in the first layer, is an organic compound that can easily have a low refractive index and the organic compound having a carbazole skeleton, which is the second substance included in the second layer, is an organic compound that can easily have a high refractive index; thus, the first layer and the second layer can have significantly different refractive indices. Specifically, the difference in the ordinary refractive index at a wavelength of 380 nm to 760 nm between the first layer and the second layer can be easily made greater than or equal to 0.1, preferably greater than or equal to 0.3. In this manner, the light extraction efficiency of the light-emitting device can be improved.

The first layer includes the first substance and the second layer includes the second substance, which allows the ordinary refractive index of the first layer to be easily made lower than that of the second layer. Thus, a structure in which the first layer is positioned between the second electrode and the second layer is preferably employed in order to increase the light extraction efficiency. That is, the cap layer 155 preferably has the stacked-layer structure as in FIG. 1B in order to further increase the light extraction efficiency. Although a first layer 188 and a second layer 189 are stacked in FIG. 1B, a stacked-layer structure of more than two layers is employed in some cases.

Note that the refractive index of the evaporated film of the first substance with respect to light with a certain wavelength is preferably lower than the refractive index of the evaporated film of the second substance with respect to light with the same wavelength. Specifically, the ordinary refractive index of the evaporated film of the first substance at a wavelength of 380 nm to 760 nm is preferably lower than the ordinary refractive index of the evaporated film of the second substance at the same wavelength. Note that the difference in the ordinary refractive index is preferably greater than or equal to 0.1, further preferably greater than or equal to 0.2, still further preferably greater than or equal to 0.3.

More specifically, for improvement of the light extraction efficiency, it is preferable that the ordinary refractive index of the evaporated film of the first substance at a wavelength greater than or equal to 380 nm and less than 500 nm be lower than or equal to 1.80 and the ordinary refractive index of the evaporated film of the second substance at a wavelength greater than or equal to 380 nm and less than 500 nm be higher than or equal to 1.90, and it is further preferable that the ordinary refractive index of the evaporated film of the first substance at a wavelength greater than or equal to 380 nm and less than 500 nm be lower than or equal to 1.70 and the ordinary refractive index of the evaporated film of the second substance at a wavelength greater than or equal to 380 nm and less than 500 nm be higher than or equal to 2.00.

For improvement of the light extraction efficiency, it is preferable that the ordinary refractive index of the evaporated film of the first substance at a wavelength greater than or equal to 500 nm and less than 600 nm be lower than or equal to 1.72 and the ordinary refractive index of the evaporated film of the second substance at a wavelength greater than or equal to 500 nm and less than 600 nm be higher than or equal to 1.90, and it is further preferable that the ordinary refractive index of the evaporated film of the first substance at a wavelength greater than or equal to 500 nm and less than 600 nm be lower than or equal to 1.68 and the ordinary refractive index of the evaporated film of the second substance at a wavelength greater than or equal to 500 nm and less than 600 nm be higher than or equal to 1.93.

For improvement of the light extraction efficiency, it is preferable that the ordinary refractive index of the evaporated film of the first substance at a wavelength of 600 nm to 760 nm be lower than or equal to 1.70 and the ordinary refractive index of the evaporated film of the second substance at a wavelength of 600 nm to 760 nm be higher than or equal to 1.80, and it is further preferable that the ordinary refractive index of the evaporated film of the first substance at a wavelength of 600 nm to 760 nm be lower than or equal to 1.65 and the ordinary refractive index of the evaporated film of the second substance at a wavelength of 600 nm to 760 nm be higher than or equal to 1.85.

Note that it is further preferable that the ordinary refractive index of the evaporated film of the first substance at a wavelength of 380 nm to 760 nm be higher than or equal to 1.40 and the ordinary refractive index of the evaporated film of the second substance at a wavelength of 380 nm to 760 nm be lower than or equal to 2.40.

When a layer including a substance with a low refractive index and a layer including a substance with a high refractive index are stacked, light scattered in the light-emitting device is more easily extracted, whereby the emission efficiency of the light-emitting device can be improved. As described above, the first layer 188 and the second layer 189 preferably have a low refractive index and a high refractive index, respectively, in which case light can be extracted more easily.

The monoamine compound having an alkyl group, which is the first substance, is an organic compound that has a relatively low evaporation temperature and is easily evaporated. That is, since the organic compound can be deposited at a low temperature, the influence of heat on another organic compound used in the light-emitting device during deposition can be reduced.

In particular, materials are heated continuously for a long time in a mass production process; thus, an organic compound having a high evaporation temperature is easily decomposed. When a material is decomposed, stable mass production is difficult. Thus, an organic compound material that can be deposited at a low temperature can be deposited without decomposition of the material, resulting in stable mass production.

Particularly when the first layer including the first substance is positioned between the second electrode and the second layer, the first substance with a relatively low evaporation temperature can be deposited first. Thus, even when the second substance has a higher evaporation temperature than the first substance, the influence of heat on a layer including the organic compound can be reduced.

The monoamine compound having an alkyl group, which is the first substance, is easily evaporated, enables a film with high quality and stability, and can have a molecular structure with a short effective conjugation length and thus does not absorb visible light. Accordingly, a light-emitting device using the monoamine compound having an alkyl group as the first substance can be suitably used to provide a display device with high display quality. Furthermore, the light extraction efficiency can be improved, which can reduce the load of current required for obtaining high luminance and provide a highly reliable light-emitting device.

The monoamine compound having an alkyl group can be an organic compound with a lower refractive index than an organic compound having no alkyl group.

More specifically, the ordinary refractive index of the evaporated film of the monoamine compound having an alkyl group at a wavelength of 380 nm to 500 nm is preferably lower than or equal to 1.80, further preferably lower than or equal to 1.70 for improvement of the light extraction efficiency.

The ordinary refractive index of the evaporated film of the monoamine compound having an alkyl group at a wavelength of 500 nm to 600 nm is preferably lower than or equal to 1.72, further preferably lower than or equal to 1.68 for improvement of the light extraction efficiency.

The ordinary refractive index of the evaporated film of the monoamine compound having an alkyl group at a wavelength of 600 nm to 760 nm is preferably lower than or equal to 1.70, further preferably lower than or equal to 1.65 for improvement of the light extraction efficiency.

Note that the ordinary refractive index of the evaporated film of the monoamine compound having an alkyl group at a wavelength of 380 nm to 760 nm is preferably higher than or equal to 1.40.

The alkyl group included in the monoamine compound is preferably a cycloalkyl group or a branched-chain alkyl group having 3 or more carbon atoms, in which case the refractive index is lowered, and further preferably a cyclohexyl group or a tert-butyl group, in which case high heat resistance and stable film quality are obtained. The number of alkyl groups included in the monoamine compound is preferably greater than or equal to 1 and less than or equal to 10, in which case both a low refractive index and stable film quality with high heat resistance can be obtained. Since the compound of the present invention has an amine structure and thus has a hole-transport property, the compound can also be used for a hole-transport layer in an organic EL layer. In that case, the number of alkyl groups included in the monoamine compound is preferably greater than or equal to 1 and less than or equal to 10, in which case both a low refractive index and a carrier-transport property can be easily obtained. In addition, the use of the same material for the cap layer and the hole-transport layer is preferable because the number of kinds of materials used for the organic EL device can be reduced, leading to a reduction in manufacturing cost.

The amine compound including an alkyl group can be an organic compound having a high lowest unoccupied molecular orbital (LUMO) level. The cap layer is preferably formed in contact with the second electrode, and the second electrode is a cathode in many cases. When a substance with a low LUMO level is used for the cathode, an interaction is caused and thereby the characteristics are adversely affected in some cases. Thus, when an amine compound including an alkyl group having a high LUMO level is used for the cap layer and particularly when the first layer including the first substance is in contact with the second electrode, an interaction between the cap layer and the second electrode can be inhibited and a light-emitting device with favorable characteristics can be provided.

The monoamine compound having an alkyl group preferably includes an aryl group. When an aryl group is included, stable film quality with high heat resistance can be obtained. An aryl group having 6 to 30 carbon atoms is preferably used as the aryl group, in which case high heat resistance is obtained and thus decomposition by an excessively high evaporation temperature can be prevented. A group having a fluorene skeleton is preferable, enabling stable film quality with high heat resistance. Examples of the group having a fluorene skeleton include a fluorenyl group, a dimethylfluorenyl group, a diphenylfluorenyl group, and a spirobifluorenyl group. In particular, the dimethylfluorenyl group and the diphenylfluorenyl group are preferable because a low refractive index is achieved. The group having a fluorene skeleton is preferably directly bonded to nitrogen of an amine of the monoamine compound, in which case both a low refractive index and stable film quality with high heat resistance are obtained.

As the aryl group included in the monoamine compound having an alkyl group, a group having a biphenyl skeleton is preferably used, in which case stable film quality with high heat resistance can be obtained. Examples of the group having a biphenyl skeleton include an o-biphenyl group, an m-biphenyl group, ap-biphenyl group, and a terphenyl group. The p-biphenyl group and the o-biphenyl group are preferable, which enables high heat resistance and prevents decomposition by an excessively high evaporation temperature. The o-biphenyl group is further preferably used for the cap film of the organic EL device for obtaining visible light emission, because the absorption edge of the monoamine compound having an alkyl group in a film state is located at a shorter wavelength than that in the case of the p-biphenyl group.

The aryl group included in the monoamine compound having an alkyl group is preferably a phenyl group, in which case the evaporation temperature is not increased excessively and the absorption edge of the monoamine compound having an alkyl group in a film state is located at a short wavelength, and a group having a naphthalene skeleton is preferable because stable film quality with high heat resistance can be obtained.

Note that the monoamine compound having an alkyl group preferably has both a group having a fluorene skeleton and a group having a biphenyl skeleton, in which case the effect of the biphenyl group and the effect of the fluorenyl group are both obtained and the evaporation temperature does not become too high; in particular, the monoamine compound having a combination of a biphenyl group and a fluorenyl group is preferable for the cap film, in which case a film with extremely high thermal stability can be formed. The alkyl group included in the monoamine compound is preferably bonded to these aryl groups.

Since a fluorine atom has a low atomic refraction, an organic compound having a fluorine atom can be a substance with a low refractive index. However, since the influence of a fluorine compound, which is difficult to decompose, on the human body has become a concern for society and the international restriction on the fluorine compound is becoming strict, it is preferable that the monoamine compound having an alkyl group not include a group having a fluorine atom, e.g., a trifluoromethyl group, and it is further preferable that the monoamine compound not have a fluorine atom. In addition, a monoamine compound having a trifluoromethyl group may have a risk of generating hydrofluoric acid when the trifluoromethyl group is decomposed in evaporation; thus, there is probably a risk of corroding a sublimation purifier of a purification apparatus and a chamber of an evaporator of an evaporation apparatus. In addition, since hydrofluoric acid generated in manufacturing a device might adversely affect wirings and the like and the reliability of the device, it is preferable not to use the monoamine compound having a trifluoromethyl group.

Since the monoamine compound having an alkyl group enables an evaporated film with good film quality to be formed, the monoamine compound of one embodiment of the present invention is preferably a monoamine compound having an alkyl group.

The monoamine compound having an alkyl group in one embodiment of the present invention may be a compound including a plurality of monoamine skeletons. Note that the plurality of monoamine skeletons in the monoamine compound are bonded to each other through a carbon atom having sp³ hybrid orbitals and are not conjugated with each other. With such a structure, a film formed using a compound that includes a plurality of monoamine skeletons has an absorption edge located at a short wavelength and does not have absorption in the visible light region. Accordingly, the compound can be suitably used for the cap film of the organic EL device for obtaining visible light emission. The compound having such a structure is preferable for the cap film because a stable film with high heat resistance can be formed even with a molecular structure with a small monoamine skeleton.

The monoamine compound having an alkyl group is preferably an organic compound represented by General Formula (G_{L}1).

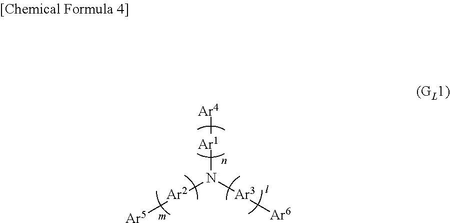

In the organic compound represented by General Formula (G_{L}1), Ar¹ to Ar³ each independently represent any one of a substituted or unsubstituted arylene group having 6 to 30 carbon atoms and a substituted or unsubstituted heteroarylene group having 1 to 30 carbon atoms, Ar⁴ to Ar⁶ each independently represent any one of a substituted or unsubstituted aryl group having 6 to 30 carbon atoms and a substituted or unsubstituted heteroaryl group having 1 to 30 carbon atoms.

In General Formula (G_{L}1), n, m, and l each independently represent any one integer of 0 to 3. In the case where one or more of n, m, and l represent 2 or more, a plurality of Ar¹s may be the same or different from each other, a plurality of Ar²s may be the same or different from each other, and a plurality of Ar³s may be the same or different from each other.

The organic compound represented by General Formula (G_{L}1) includes one or more alkyl groups; the one or more alkyl groups are each any of a straight-chain or branched-chain alkyl group having 1 to 10 carbon atoms and a cycloalkyl group having 3 to 10 carbon atoms; a branched-chain alkyl group having 3 to 10 carbon atoms or a cycloalkyl group having 6 to 10 carbon atoms is preferable; and a tert-butyl group or a cyclohexyl group is further preferable. Among them, a tert-butyl group is particularly preferable. Note that the number of the alkyl groups included in the organic compound represented by General Formula (G_{L}1) is preferably greater than or equal to 1 and less than or equal to 10, in which case both a low refractive index and a carrier-transport property are easily achieved.

Note that hydrogen atoms in the organic compound represented by General Formula (G_{L}1) may each independently be a deuterium atom.

The monoamine compound having an alkyl group may be an organic compound in which two to four partial structures represented by General Formula (G_{L}2) are included and the partial structures are bonded to each other through a carbon atom having sp³ hybrid orbitals. When the monoamine compound having an alkyl group has such a structure, a cap layer with high heat resistance can be formed.

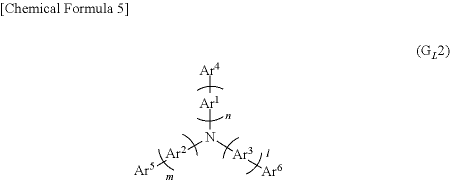

In the partial structure represented by General Formula (G_{L}2), Ar¹ to Ar³ each independently represent any one of a substituted or unsubstituted arylene group having 6 to 30 carbon atoms and a substituted or unsubstituted heteroarylene group having 1 to 30 carbon atoms, Ar⁴ to Ar⁶ each independently represent any one of a substituted or unsubstituted aryl group having 6 to 30 carbon atoms and a substituted or unsubstituted heteroaryl group having 1 to 30 carbon atoms.

In the partial structure represented by General Formula (G_{L}2), n, m, and l each independently represent any one integer of 0 to 3. In the case where one or more of n, m, and l represent 2 or more, a plurality of Ar¹s may be the same or different from each other, a plurality of Ar²s may be the same or different from each other, and a plurality of Ar³s may be the same or different from each other.

The partial structure represented by General Formula (G_{L}2) includes one or more alkyl groups; the one or more alkyl groups are each any of a straight-chain or branched-chain alkyl group having 1 to 10 carbon atoms and a cycloalkyl group having 3 to 10 carbon atoms; a branched-chain alkyl group having 3 to 10 carbon atoms or a cycloalkyl group having 6 to 10 carbon atoms is preferable; and a tert-butyl group or a cyclohexyl group is further preferable. Among them, a tert-butyl group is particularly preferable. Note that the number of the alkyl groups included in the organic compound represented by General Formula (G_{L}2) is preferably greater than or equal to 1 and less than or equal to 20, in which case both a low refractive index and a carrier-transport property are easily achieved.

Note that hydrogen atoms in the organic compound having the partial structure represented by General Formula (G_{L}2) may each independently be a deuterium atom.

Note that the organic compound preferably has two or more partial structures represented by General Formula (G_{L}2), in which case a highly stable film can be obtained. That is, the organic compound having the partial structures represented by General Formula (G_{L}2) is preferably any of the organic compounds represented by General Formulas (G_{L}3) to (G_{L}5).

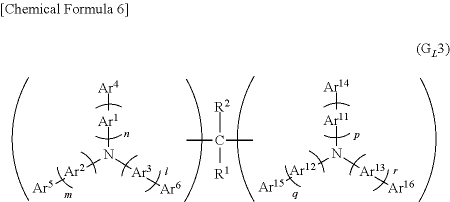

In the organic compound represented by General Formula (G_{L}3), Ar¹ to Ar³ and Ar¹¹ to Ar¹³ each independently represent any one of a substituted or unsubstituted arylene group having 6 to 30 carbon atoms and a substituted or unsubstituted heteroarylene group having 1 to 30 carbon atoms, Ar⁴ to Ar⁶ and Ar¹⁴ to Ar¹⁶ each independently represent any one of a substituted or unsubstituted aryl group having 6 to 30 carbon atoms and a substituted or unsubstituted heteroaryl group having 1 to 30 carbon atoms.

In the organic compound represented by General Formula (G_{L}3), n, m, l, p, q, and r each independently represent any one integer of 0 to 3. In the case where one or more of n, m, l, p, q, and r represent 2 or more, a plurality of Aris may be the same or different from each other, a plurality of Ar²s may be the same or different from each other, a plurality of Ar³s may be the same or different from each other, a plurality of Ar¹¹s may be the same or different from each other, a plurality of Ar¹²s may be the same or different from each other, and a plurality of Ar¹³s may be the same or different from each other.

In the organic compound represented by General Formula (G_{L}3), R¹ and R² each independently represent an alkyl group having 1 to 10 carbon atoms or a substituted or unsubstituted phenyl group, and R¹ and R² may be bonded to each other to form a ring.

The organic compound represented by General Formula (G_{L}3) includes one or more alkyl groups; the one or more alkyl groups are each any of a straight-chain or branched-chain alkyl group having 1 to 10 carbon atoms and a cycloalkyl group having 3 to 10 carbon atoms; a branched-chain alkyl group having 3 to 10 carbon atoms or a cycloalkyl group having 6 to 10 carbon atoms is preferable; and a tert-butyl group or a cyclohexyl group is further preferable. Among them, a tert-butyl group is particularly preferably used to form a compound having a high sublimation property. Note that the number of the alkyl groups included in the organic compound represented by General Formula (G_{L}3) is preferably greater than or equal to 1 and less than or equal to 20, in which case both a low refractive index and stable film quality with high heat resistance can be achieved. Since the organic compound represented by General Formula (G_{L}3) has an amine structure and thus has a hole-transport property, the organic compound can also be used for a hole-transport layer in an organic EL layer. In that case, the number of the alkyl groups included in the organic compound represented by General Formula (G_{L}3) is preferably greater than or equal to 1 and less than or equal to 20, in which case both a low refractive index and a carrier-transport property are easily achieved.

Note that hydrogen atoms in the organic compound represented by General Formula (G_{L}3) may each independently be a deuterium atom.

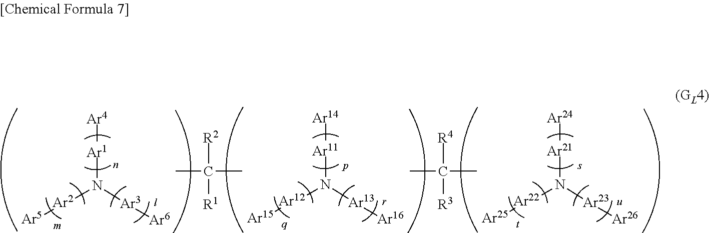

In the organic compound represented by General Formula (G_{L}4), Ar¹ to Ar³, Ar¹¹ to Ar¹³, and Ar²¹ to Ar²³ each independently represent any one of a substituted or unsubstituted arylene group having 6 to 30 carbon atoms and a substituted or unsubstituted heteroarylene group having 1 to 30 carbon atoms, Ar⁴ to Ar⁶, Ar¹⁴ to Ar¹⁶, and Ar²⁴ to Ar²⁶ each independently represent any one of a substituted or unsubstituted aryl group having 6 to 30 carbon atoms and a substituted or unsubstituted heteroaryl group having 1 to 30 carbon atoms.

In the organic compound represented by General Formula (G_{L}4), n, m, l, p, q, r, s, t, and u each independently represent any one integer of 0 to 3. In the case where one or more of n, m, l, p, q, r, s, t, and u represent 2 or more, a plurality of Ar¹s may be the same or different from each other, a plurality of Ar²s may be the same or different from each other, a plurality of Ar³s may be the same or different from each other, a plurality of Ar¹¹s may be the same or different from each other, a plurality of Ar¹²s may be the same or different from each other, a plurality of Ar¹³s may be the same or different from each other, a plurality of Ar²¹s may be the same or different from each other, a plurality of Ar²²s may be the same or different from each other, and a plurality of Ar²³s may be the same or different from each other.

In the organic compound represented by General Formula (G_{L}4), R¹, R², R³, and R⁴ each independently represent an alkyl group having 1 to 10 carbon atoms or a substituted or unsubstituted phenyl group, and R¹ and R² may be bonded to each other to form a ring and the same applies to R³ and R⁴.

The organic compound represented by General Formula (G_{L}4) includes one or more alkyl groups; the one or more alkyl groups are each independently any of a straight-chain or branched-chain alkyl group having 1 to 10 carbon atoms and a cycloalkyl group having 3 to 10 carbon atoms; a branched-chain alkyl group having 3 to 10 carbon atoms or a cycloalkyl group having 6 to 10 carbon atoms is preferable, and a tert-butyl group or a cyclohexyl group is further preferable. Among them, a tert-butyl group is particularly preferable. Note that the number of the alkyl groups included in the organic compound represented by General Formula (G_{L}4) is preferably greater than or equal to 1 and less than or equal to 30, in which case both a low refractive index and stable film quality with high heat resistance can be achieved. Since the organic compound represented by General Formula (G_{L}4) has an amine structure and thus has a hole-transport property, the organic compound can also be used for a hole-transport layer in an organic EL layer. In that case, the number of the alkyl groups included in the organic compound represented by General Formula (G_{L}4) is preferably greater than or equal to 1 and less than or equal to 30, in which case both the low refractive index and the carrier-transport property are easily achieved.

Note that hydrogen atoms in the organic compound represented by General Formula (G_{L}4) may each independently be a deuterium atom.

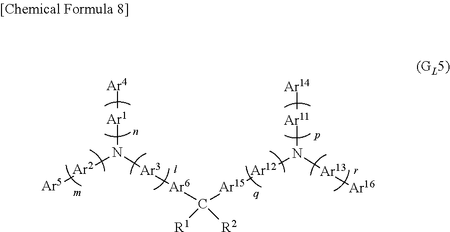

In the organic compound represented by General Formula (G_{L}5), Ar¹ to Ar³ and Ar¹¹ to Ar¹³ each independently represent any one of a substituted or unsubstituted arylene group having 6 to 30 carbon atoms and a substituted or unsubstituted heteroarylene group having 1 to 30 carbon atoms, Ar⁴ to Ar⁶ and Ar¹⁴ to Ar¹⁶ each independently represent any one of a substituted or unsubstituted aryl group having 6 to 30 carbon atoms and a substituted or unsubstituted heteroaryl group having 1 to 30 carbon atoms.

In the organic compound represented by General Formula (G_{L}5), n, m, l, p, q, and r each independently represent any one integer of 0 to 3. In the case where one or more of n, m, l, p, q, and r represent 2 or more, a plurality of Ar¹s may be the same or different from each other, a plurality of Ar²s may be the same or different from each other, a plurality of Ar³s may be the same or different from each other, a plurality of Ar¹¹s may be the same or different from each other, a plurality of Ar¹²s may be the same or different from each other, and a plurality of Ar¹³s may be the same or different from each other.

In the organic compound represented by General Formula (G_{L}5), R¹ and R² each independently represent an alkyl group having 1 to 10 carbon atoms or a substituted or unsubstituted phenyl group, and R¹ and R² may be bonded to each other to form a ring.

The organic compound represented by General Formula (G_{L}5) includes one or more alkyl groups; the one or more alkyl groups are each any of a straight-chain or branched-chain alkyl group having 1 to 10 carbon atoms and a cycloalkyl group having 3 to 10 carbon atoms; a branched-chain alkyl group having 3 to 10 carbon atoms or a cycloalkyl group having 6 to 10 carbon atoms is preferable; and a tert-butyl group or a cyclohexyl group is further preferable. Among them, a tert-butyl group is particularly preferable. Note that the number of the alkyl groups included in the organic compound represented by General Formula (G_{L}5) is preferably greater than or equal to 1 and less than or equal to 20, in which case both a low refractive index and stable film quality with high heat resistance can be achieved. Since the organic compound represented by General Formula (G_{L}5) has an amine structure and thus has a hole-transport property, the organic compound can also be used for a hole-transport layer in an organic EL layer. In that case, the number of the alkyl groups included in the organic compound represented by General Formula (G_{L}5) is preferably greater than or equal to 1 and less than or equal to 20, in which case both a low refractive index and a carrier-transport property are easily achieved.

Note that hydrogen atoms in the organic compound represented by General Formula (G_{L}5) may each independently be a deuterium atom.

Examples of the aryl group having 6 to 30 carbon atoms in General Formulas (G_{L}1) to (G_{L}5) include a phenyl group, an o-tolyl group, a m-tolyl group, a p-tolyl group, a mesityl group, a biphenyl-2-yl group (o-biphenyl group), a biphenyl-3-yl group (m-biphenyl group), a biphenyl-4-yl group (p-biphenyl group), a 1-naphthyl group, a 2-naphthyl group, a phenylnaphthyl group, a naphthylphenyl group, a terphenyl group, a fluorenyl group, a 9,9-dimethylfluorenyl group, a quaterphenyl group, a spirobifluorenyl group, a phenanthryl group, an anthryl group, a binaphthylphenyl group, a fluoranthenyl group, and a triphenylenyl group. In the case where the aryl group having 6 to 30 carbon atoms has a substituent, examples of the substituent include an alkyl group having 1 to 4 carbon atoms, a cycloalkyl group having 3 to 6 carbon atoms, or an aryl group having 6 to 13 carbon atoms.

Specific examples of the heteroaryl group having 1 to 30 carbon atoms in General Formulas (G_{L}1) to (G_{L}5) include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, a dinaphthofuranyl group, a dinaphthothiophenyl group, an indolocarbazolyl group, a benzofurocarbazolyl group, a benzothienocarbazolyl group, an indenocarbazolyl group, a dibenzocarbazolyl group, an indolyl group, a pyrrolyl group, a 1,2,3-triazol-yl group, and a 1,2,4-triazol-yl group. In the case where the heteroaryl group having 1 to 30 carbon atoms has a substituent, examples of the substituent include an alkyl group having 1 to 4 carbon atoms, a cycloalkyl group having 3 to 6 carbon atoms, and an aromatic hydrocarbon group having 6 to 13 carbon atoms.

Examples of the arylene group having 6 to 30 carbon atoms in General Formulas (G_{L}1) to (G_{L}5) include divalent groups obtained by removing one hydrogen atom from the groups given as the aryl group having 6 to 30 carbon atoms. In the case where the arylene group having 6 to 30 carbon atoms has a substituent, examples of the substituent include an alkyl group having 1 to 4 carbon atoms, a cycloalkyl group having 3 to 6 carbon atoms, and an aryl group having 6 to 13 carbon atoms.

Examples of the heteroarylene group having 1 to 30 carbon atoms in General Formulas (G_{L}1) to (G_{L}5) include divalent groups obtained by removing one hydrogen atom from the groups given as the arylene group having 6 to 30 carbon atoms. In the case where the arylene group having 6 to 30 carbon atoms has a substituent, examples of the substituent include an alkyl group having 1 to 4 carbon atoms, a cycloalkyl group having 3 to 6 carbon atoms, and an aryl group having 6 to 13 carbon atoms.

Examples of the straight-chain or branched-chain alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a heptyl group, an octyl group, a 3-methylpentyl group, a 2-methylpentyl group, a 2-ethylbutyl group, a 1,2-dimethylbutyl group, a 2,3-dimethylbutyl group, a 2-ethylhexyl group, a 1-ethylpropyl group, a nonyl group, a 3,7-dimethyl-1-octyl group, a 3,7-dimethyl-2-octyl group, and a decyl group.

Specific examples of the cycloalkyl group having 3 to 10 carbon atoms include a cyclopropyl group, a cyclobutyl group, a cyclopentyl group, a cyclohexyl group, a cycloheptyl group, a cyclooctyl group, a cyclononyl group, a cyclodecyl group, an adamantyl group, a bicyclo[2.2.1]heptyl group, a tricyclo[5.2.1.0(2,6)]decyl group, a noradamantyl group, a 1-methylcyclohexyl group, a bicyclo[2,2,2]octyl group, and a norbornyl group. In the case where the cycloalkyl group having 3 to 10 carbon atoms has a substituent, examples of the substituent include an alkyl group having 1 to 4 carbon atoms, a cycloalkyl group having 3 to 6 carbon atoms, and an aryl group having 6 to 13 carbon atoms.

Preferable specific examples of the monoamine compound having an alkyl group and having the above-described structure include organic compounds represented by Structural Formulas (100) to (107), (200) to (224), (300) to (308), and (400) to (404) shown below.

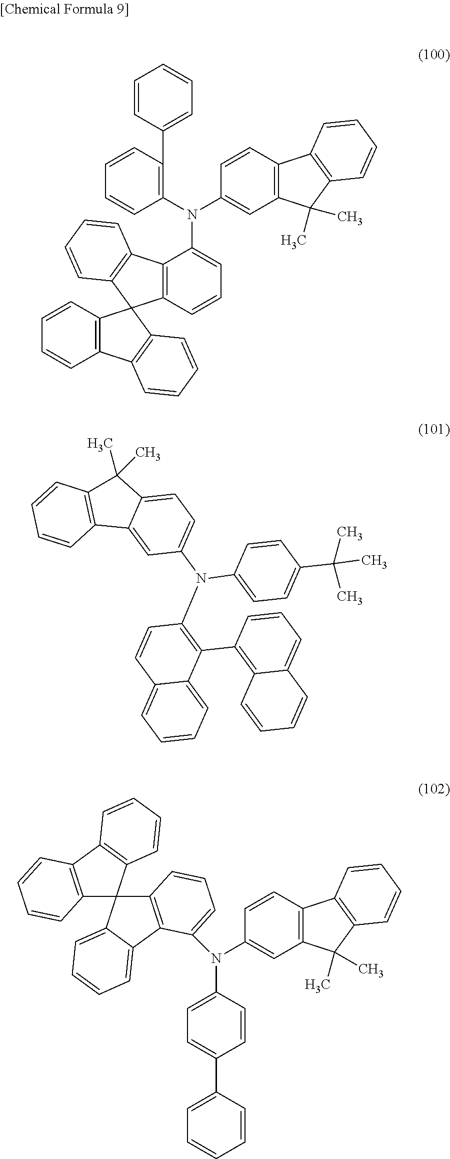 [SMILES: CC1(C)c2ccccc2-c2ccc(N(c3ccccc3-c3ccccc3)c3cccc4c3-c3ccccc3C43c4ccccc4-c4ccccc43)cc21 ; CC(C)(C)c1ccc(N(c2ccc3c(c2)-c2ccccc2C3(C)C)c2ccc3ccccc3c2-c2cccc3ccccc23)cc1 ; CC1(C)c2ccccc2-c2ccc(N(c3ccc(-c4ccccc4)cc3)c3cccc4c3-c3ccccc3C43c4ccccc4-c4ccccc43)cc21]

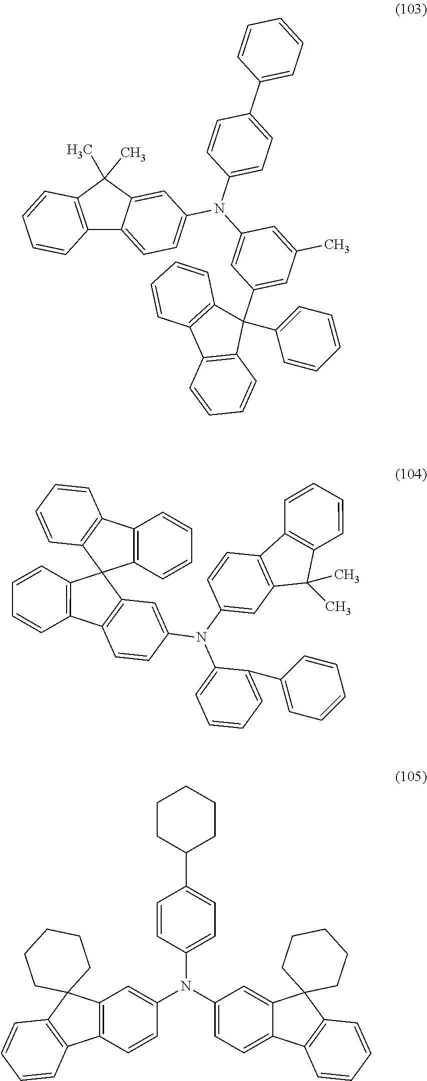 [SMILES: Cc1cc(N(c2ccc(-c3ccccc3)cc2)c2ccc3c(c2)C(C)(C)c2ccccc2-3)cc(C2(c3ccccc3)c3ccccc3-c3ccccc32)c1 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc2c(c1)-c1ccc(N(c3ccc(C4CCCCC4)cc3)c3ccc4c(c3)C3(CCCCC3)c3ccccc3-4)cc1C21CCCCC1]

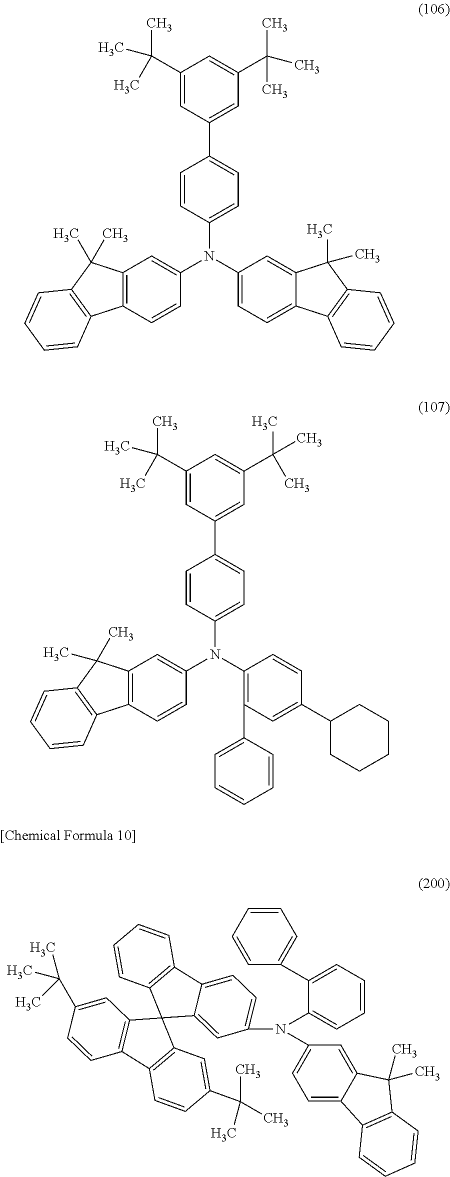 [SMILES: CC(C)(C)c1cc(-c2ccc(N(c3ccc4c(c3)C(C)(C)c3ccccc3-4)c3ccc4c(c3)C(C)(C)c3ccccc3-4)cc2)cc(C(C)(C)C)c1 ; CC(C)(C)c1cc(-c2ccc(N(c3ccc4c(c3)C(C)(C)c3ccccc3-4)c3ccc(C4CCCCC4)cc3-c3ccccc3)cc2)cc(C(C)(C)C)c1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

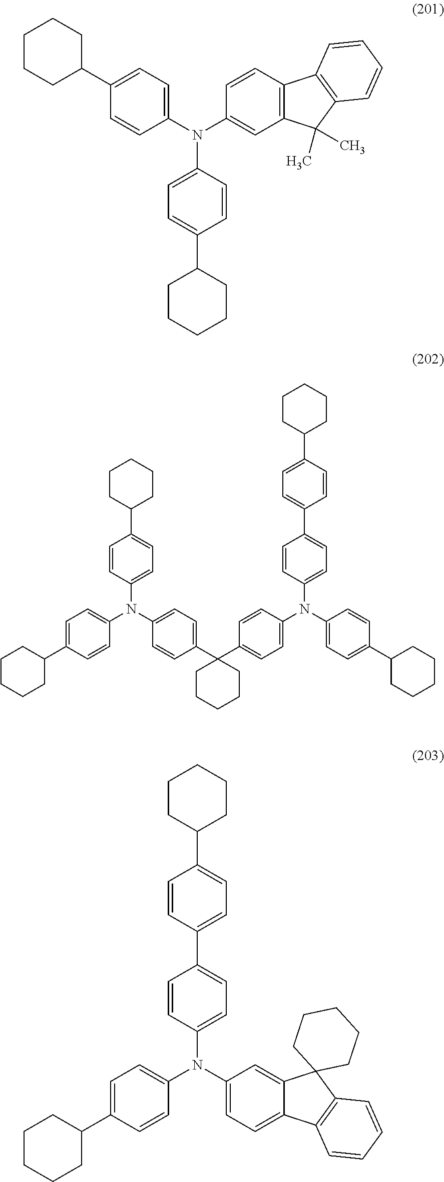 [SMILES: CC1(C)c2ccccc2-c2ccc(N(c3ccc(C4CCCCC4)cc3)c3ccc(C4CCCCC4)cc3)cc21 ; c1cc(C2CCCCC2)ccc1-c1ccc(N(c2ccc(C3CCCCC3)cc2)c2ccc(C3(c4ccc(N(c5ccc(C6CCCCC6)cc5)c5ccc(C6CCCCC6)cc5)cc4)CCCCC3)cc2)cc1 ; c1ccc2c(c1)-c1ccc(N(c3ccc(-c4ccc(C5CCCCC5)cc4)cc3)c3ccc(C4CCCCC4)cc3)cc1C21CCCCC1]

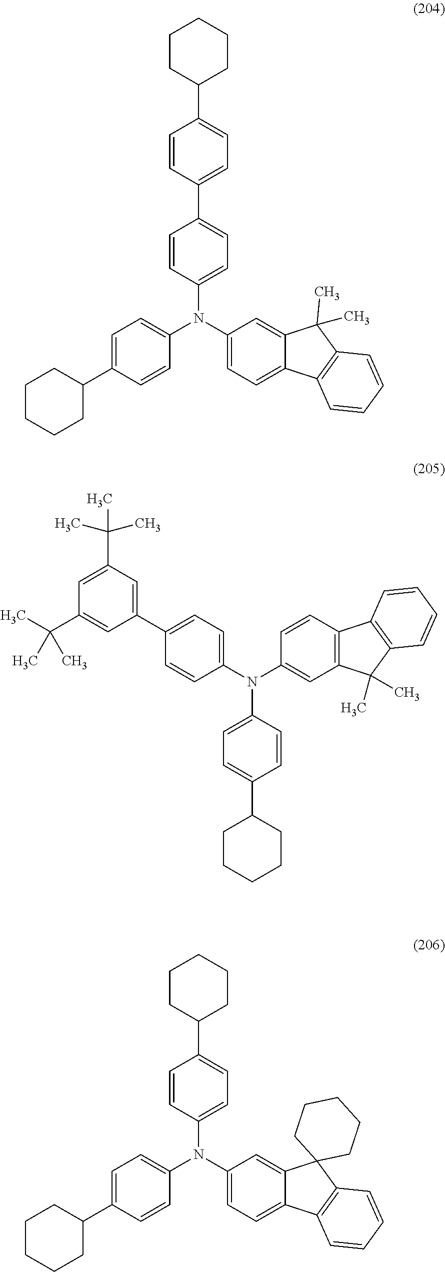 [SMILES: CC1(C)c2ccccc2-c2ccc(N(c3ccc(-c4ccc(C5CCCCC5)cc4)cc3)c3ccc(C4CCCCC4)cc3)cc21 ; CC(C)(C)c1cc(-c2ccc(N(c3ccc(C4CCCCC4)cc3)c3ccc4c(c3)C(C)(C)c3ccccc3-4)cc2)cc(C(C)(C)C)c1 ; c1ccc2c(c1)-c1ccc(N(c3ccc(C4CCCCC4)cc3)c3ccc(C4CCCCC4)cc3)cc1C21CCCCC1]

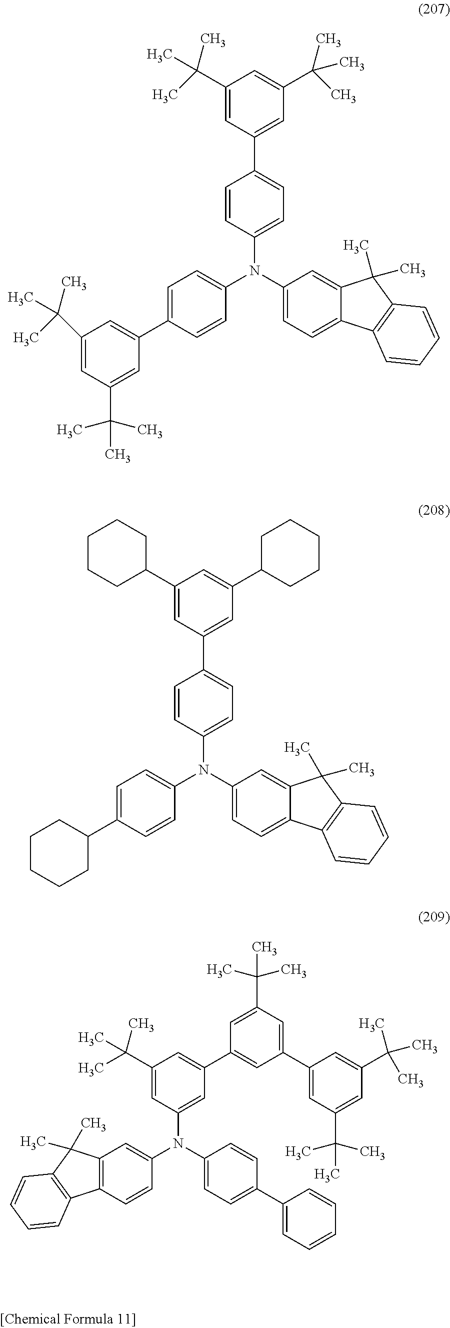 [SMILES: CC(C)(C)c1cc(-c2ccc(N(c3ccc(-c4cc(C(C)(C)C)cc(C(C)(C)C)c4)cc3)c3ccc4c(c3)C(C)(C)c3ccccc3-4)cc2)cc(C(C)(C)C)c1 ; CC1(C)c2ccccc2-c2ccc(N(c3ccc(-c4cc(C5CCCCC5)cc(C5CCCCC5)c4)cc3)c3ccc(C4CCCCC4)cc3)cc21 ; CC(C)(C)c1cc(-c2cc(N(c3ccc(-c4ccccc4)cc3)c3ccc4c(c3)C(C)(C)c3ccccc3-4)cc(C(C)(C)C)c2)cc(-c2cc(C(C)(C)C)cc(C(C)(C)C)c2)c1]

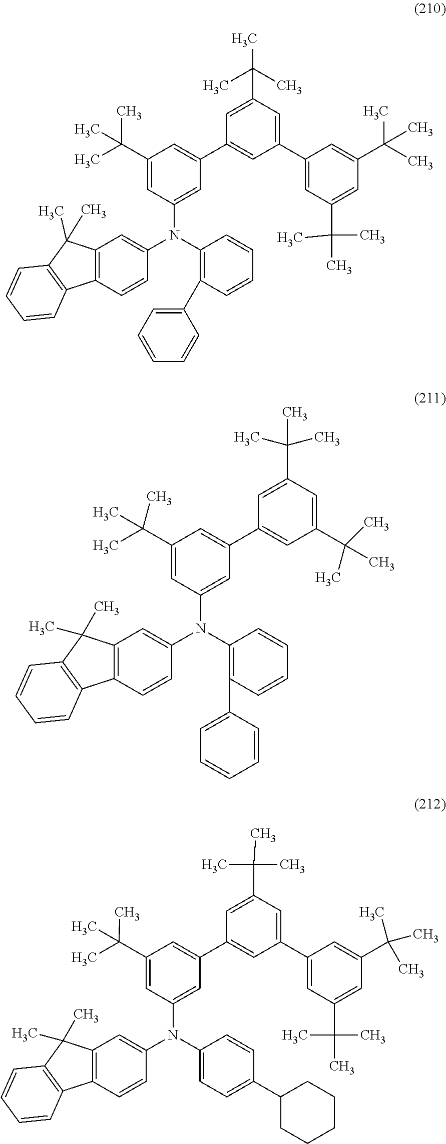 [SMILES: CC(C)(C)c1cc(-c2cc(N(c3ccc4c(c3)C(C)(C)c3ccccc3-4)c3ccccc3-c3ccccc3)cc(C(C)(C)C)c2)cc(-c2cc(C(C)(C)C)cc(C(C)(C)C)c2)c1 ; CC(C)(C)c1cc(-c2cc(C(C)(C)C)cc(C(C)(C)C)c2)cc(N(c2ccc3c(c2)C(C)(C)c2ccccc2-3)c2ccccc2-c2ccccc2)c1 ; CC(C)(C)c1cc(-c2cc(N(c3ccc(C4CCCCC4)cc3)c3ccc4c(c3)C(C)(C)c3ccccc3-4)cc(C(C)(C)C)c2)cc(-c2cc(C(C)(C)C)cc(C(C)(C)C)c2)c1]

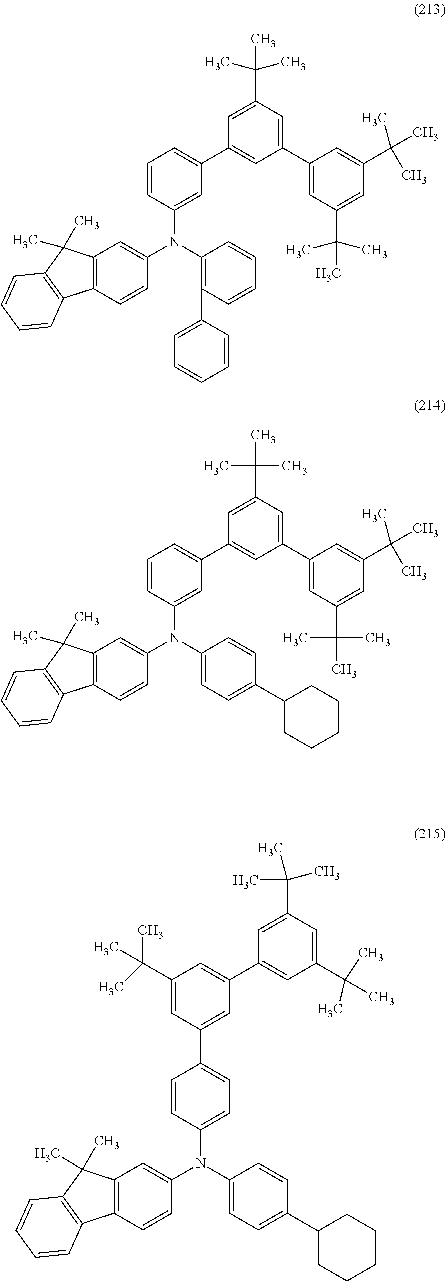 [SMILES: CC(C)(C)c1cc(-c2cccc(N(c3ccc4c(c3)C(C)(C)c3ccccc3-4)c3ccccc3-c3ccccc3)c2)cc(-c2cc(C(C)(C)C)cc(C(C)(C)C)c2)c1 ; CC(C)(C)c1cc(-c2cccc(N(c3ccc(C4CCCCC4)cc3)c3ccc4c(c3)C(C)(C)c3ccccc3-4)c2)cc(-c2cc(C(C)(C)C)cc(C(C)(C)C)c2)c1 ; CC(C)(C)c1cc(-c2ccc(N(c3ccc(C4CCCCC4)cc3)c3ccc4c(c3)C(C)(C)c3ccccc3-4)cc2)cc(-c2cc(C(C)(C)C)cc(C(C)(C)C)c2)c1]

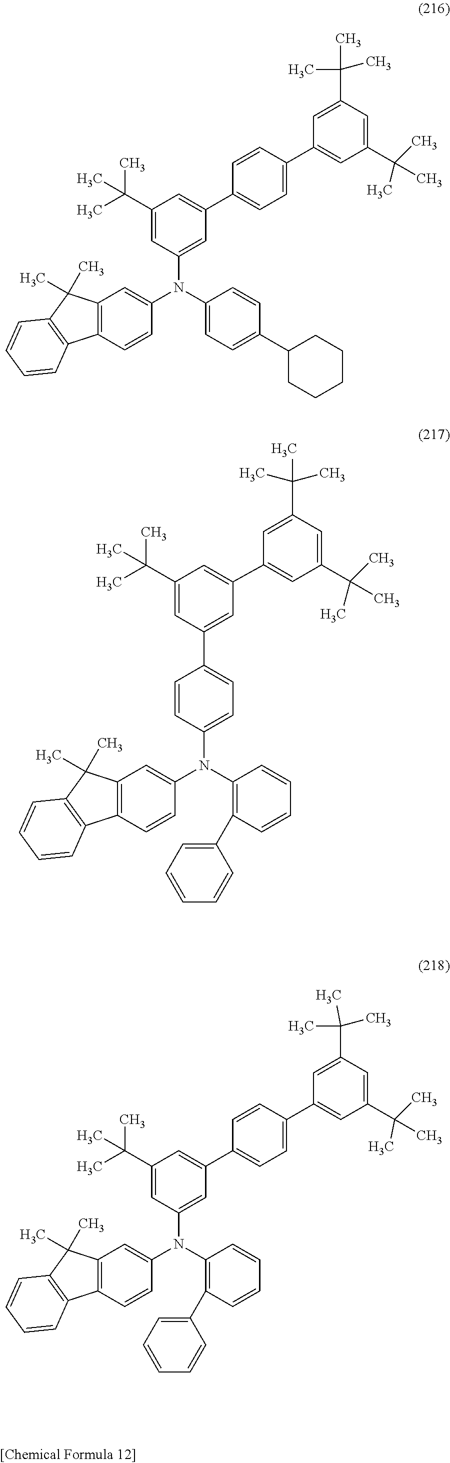 [SMILES: CC(C)(C)c1cc(-c2ccc(-c3cc(C(C)(C)C)cc(C(C)(C)C)c3)cc2)cc(N(c2ccc(C3CCCCC3)cc2)c2ccc3c(c2)C(C)(C)c2ccccc2-3)c1 ; CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; CC(C)(C)c1cc(-c2ccc(-c3cc(C(C)(C)C)cc(C(C)(C)C)c3)cc2)cc(N(c2ccc3c(c2)C(C)(C)c2ccccc2-3)c2ccccc2-c2ccccc2)c1]

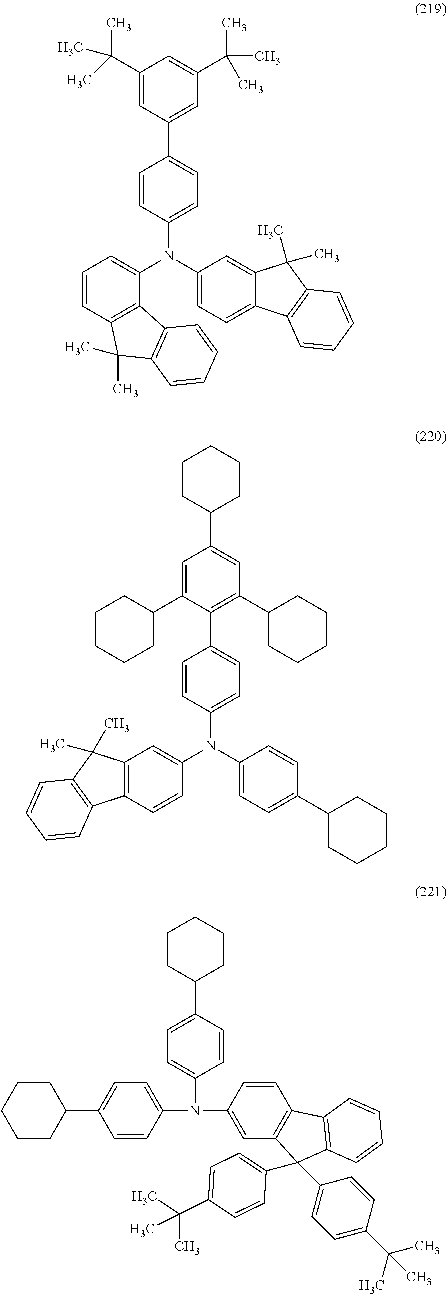 [SMILES: CC(C)(C)c1cc(-c2ccc(N(c3ccc4c(c3)C(C)(C)c3ccccc3-4)c3cccc4c3-c3ccccc3C4(C)C)cc2)cc(C(C)(C)C)c1 ; CC1(C)c2ccccc2-c2ccc(N(c3ccc(-c4c(C5CCCCC5)cc(C5CCCCC5)cc4C4CCCCC4)cc3)c3ccc(C4CCCCC4)cc3)cc21 ; CC(C)(C)c1ccc(C2(c3ccc(C(C)(C)C)cc3)c3ccccc3-c3ccc(N(c4ccc(C5CCCCC5)cc4)c4ccc(C5CCCCC5)cc4)cc32)cc1]

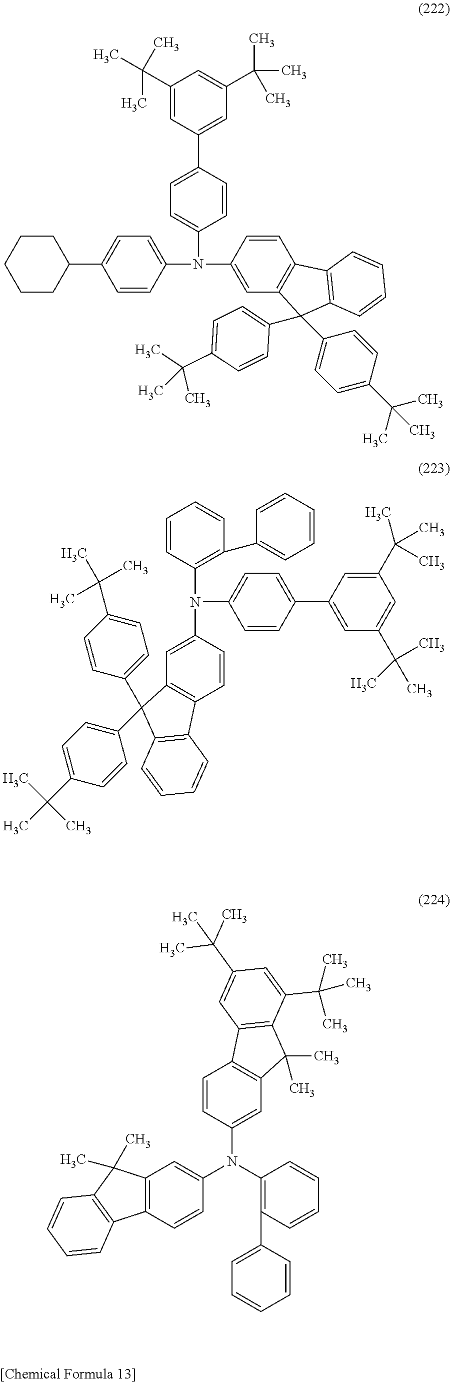

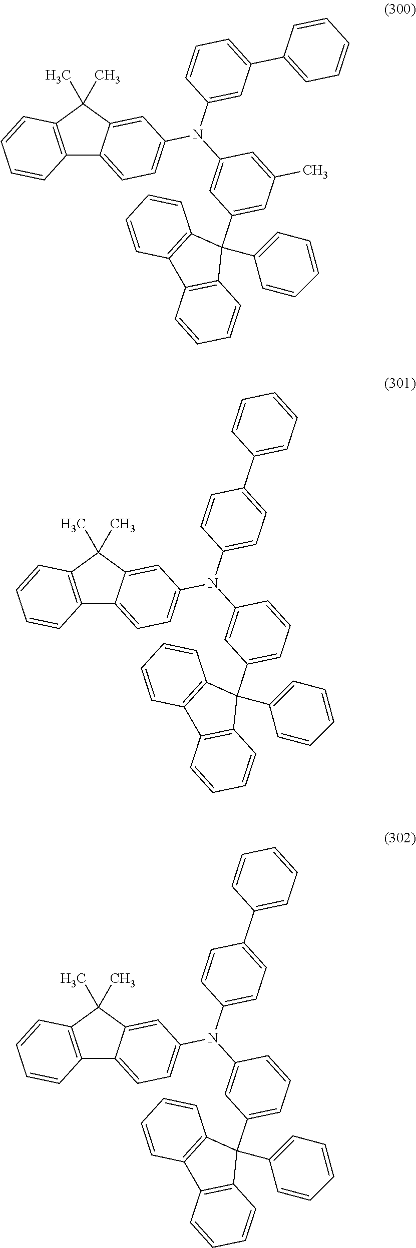 [SMILES: Cc1cc(N(c2cccc(-c3ccccc3)c2)c2ccc3c(c2)C(C)(C)c2ccccc2-3)cc(C2(c3ccccc3)c3ccccc3-c3ccccc32)c1 ; CC1(C)c2ccccc2-c2ccc(N(c3ccc(-c4ccccc4)cc3)c3cccc(C4(c5ccccc5)c5ccccc5-c5ccccc54)c3)cc21 ; CC1(C)c2ccccc2-c2ccc(N(c3ccc(-c4ccccc4)cc3)c3cccc(C4(c5ccccc5)c5ccccc5-c5ccccc54)c3)cc21]

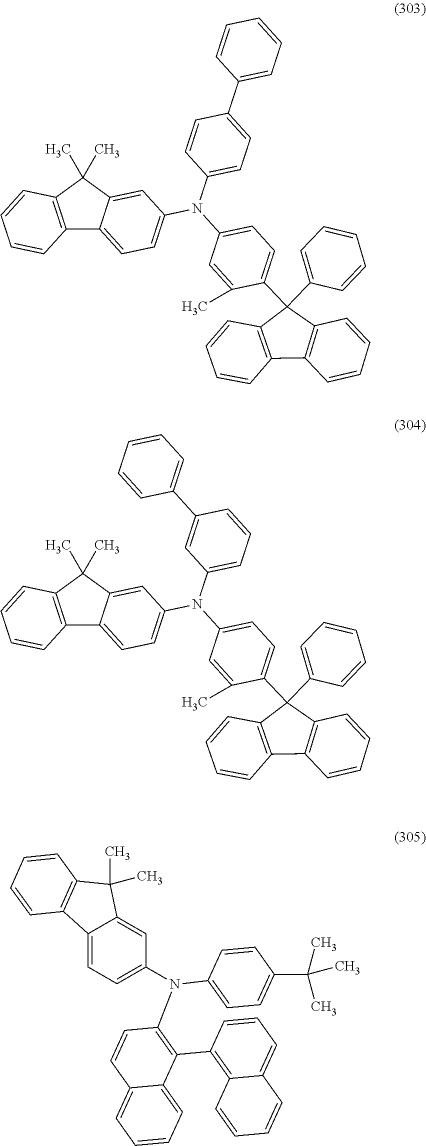 [SMILES: Cc1cc(N(c2ccc(-c3ccccc3)cc2)c2ccc3c(c2)C(C)(C)c2ccccc2-3)ccc1C1(c2ccccc2)c2ccccc2-c2ccccc21 ; Cc1cc(N(c2cccc(-c3ccccc3)c2)c2ccc3c(c2)C(C)(C)c2ccccc2-3)ccc1C1(c2ccccc2)c2ccccc2-c2ccccc21 ; CC(C)(C)c1ccc(N(c2ccc3c(c2)C(C)(C)c2ccccc2-3)c2ccc3ccccc3c2-c2cccc3ccccc23)cc1]

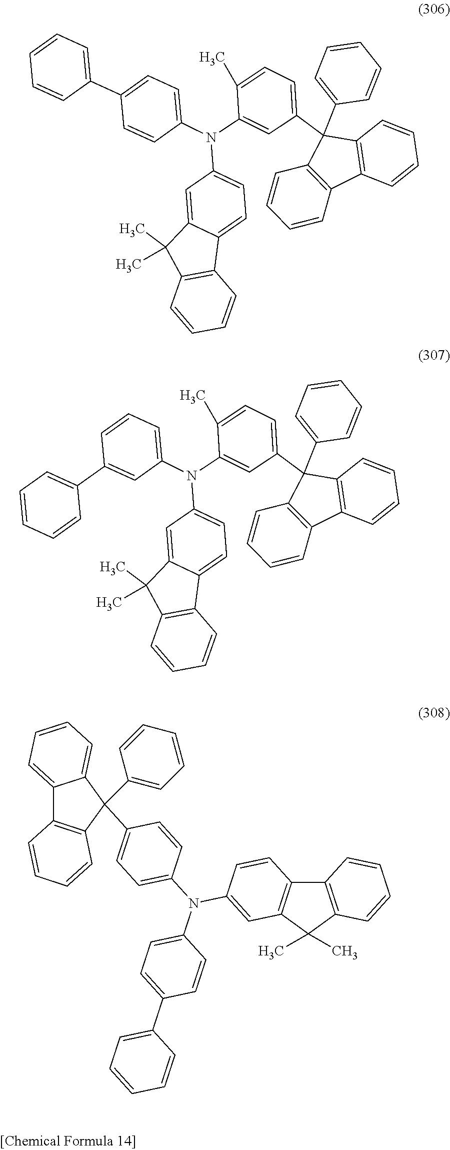 [SMILES: Cc1ccc(C2(c3ccccc3)c3ccccc3-c3ccccc32)cc1N(c1ccc(-c2ccccc2)cc1)c1ccc2c(c1)C(C)(C)c1ccccc1-2 ; Cc1ccc(C2(c3ccccc3)c3ccccc3-c3ccccc32)cc1N(c1cccc(-c2ccccc2)c1)c1ccc2c(c1)C(C)(C)c1ccccc1-2 ; CC1(C)c2ccccc2-c2ccc(N(c3ccc(-c4ccccc4)cc3)c3ccc(C4(c5ccccc5)c5ccccc5-c5ccccc54)cc3)cc21]

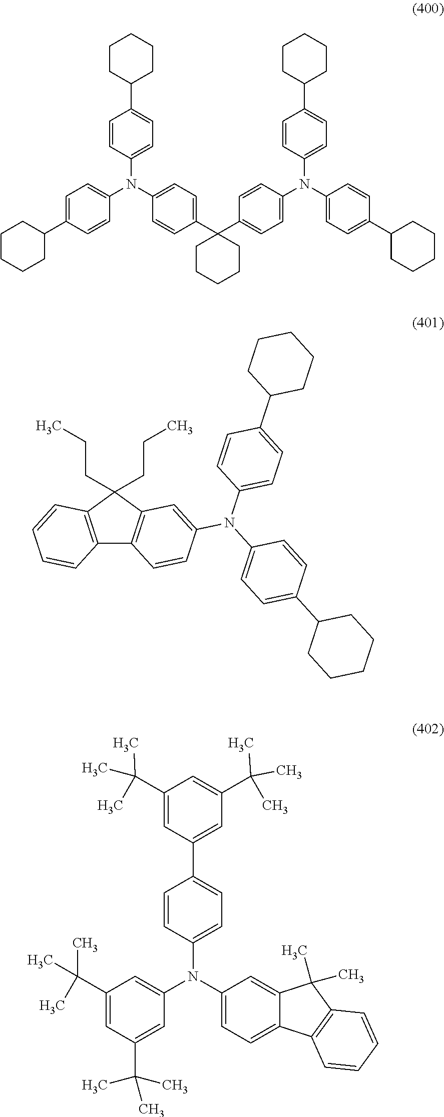 [SMILES: c1cc(N(c2ccc(C3CCCCC3)cc2)c2ccc(C3(c4ccc(N(c5ccc(C6CCCCC6)cc5)c5ccc(C6CCCCC6)cc5)cc4)CCCCC3)cc2)ccc1C1CCCCC1 ; CCCC1(CCC)c2ccccc2-c2ccc(N(c3ccc(C4CCCCC4)cc3)c3ccc(C4CCCCC4)cc3)cc21 ; CC(C)(C)c1cc(-c2ccc(N(c3cc(C(C)(C)C)cc(C(C)(C)C)c3)c3ccc4c(c3)C(C)(C)c3ccccc3-4)cc2)cc(C(C)(C)C)c1]

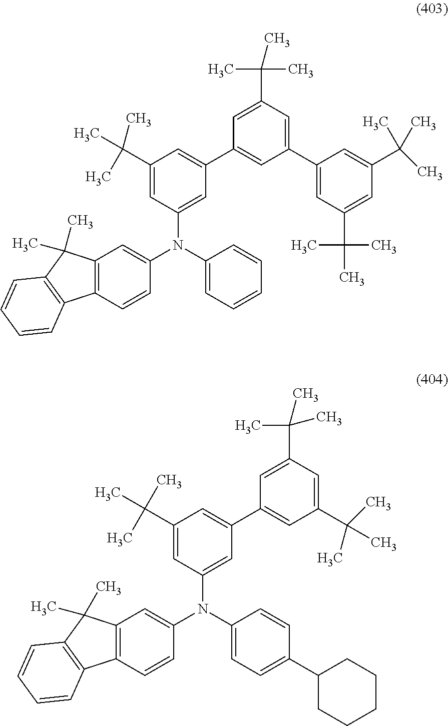 [SMILES: CC(C)(C)c1cc(-c2cc(N(c3ccccc3)c3ccc4c(c3)C(C)(C)c3ccccc3-4)cc(C(C)(C)C)c2)cc(-c2cc(C(C)(C)C)cc(C(C)(C)C)c2)c1 ; CC(C)(C)c1cc(-c2cc(C(C)(C)C)cc(C(C)(C)C)c2)cc(N(c2ccc(C3CCCCC3)cc2)c2ccc3c(c2)C(C)(C)c2ccccc2-3)c1]

Note that the monoamine compound having an alkyl group is preferably any of the organic compounds represented by Structural Formulas (200) to (224) and Structural Formulas (400) to (404) among the organic compounds represented by Structural Formulas (100) to (107), (200) to (224), (300) to (308), and (400) to (404) shown above, in which case a relatively low refractive index can be obtained; and the monoamine compound having an alkyl group is particularly preferably any of the organic compounds represented by Structural Formulas (400) to (404), in which case a lower refractive index can be obtained.

The organic compound having a carbazole skeleton can have a higher refractive index and lower absorption in the visible light region than the organic compound not having the skeleton. Furthermore, the organic compound can have high refractive index anisotropy. Thus, the organic compound having a carbazole skeleton is preferably used as an organic compound with a high refractive index.

More specifically, an evaporated film of the organic compound having a carbazole skeleton preferably has an ordinary refractive index that is higher than or equal to 1.90, further preferably higher than or equal to 2.00 at a wavelength of 380 nm to 500 nm for improvement of the light extraction efficiency.

Alternatively, an evaporated film of the organic compound having a carbazole skeleton preferably has an ordinary refractive index that is higher than or equal to 1.90, further preferably higher than or equal to 1.93 at a wavelength of 500 nm to 600 nm for improvement of the light extraction efficiency.

Alternatively, an evaporated film of the organic compound having a carbazole skeleton preferably has an ordinary refractive index that is higher than or equal to 1.80, further preferably higher than or equal to 1.85 at a wavelength of 600 nm to 760 nm for improvement of the light extraction efficiency.

Note that it is further preferable that the ordinary refractive index of the evaporated film of the first substance at a wavelength of 380 nm to 760 nm be higher than or equal to 1.40 and the ordinary refractive index of the evaporated film of the second substance at a wavelength of 380 nm to 760 nm be lower than or equal to 2.40.

The organic compound having a carbazole skeleton is preferably an organic compound represented by General Formula (G_{H}1).

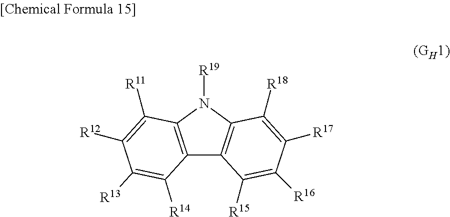

In General Formula (G_{H}1), R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms. Note that all hydrogen atoms may be deuterium atoms. The aromatic hydrocarbon group and the heteroaromatic group may each have a structure in which a plurality of rings are bonded to each other. In the case of the structure in which a plurality of rings are bonded, the plurality of rings may be composed of a plurality of aromatic hydrocarbon groups, a plurality of heteroaromatic groups, or both an aromatic hydrocarbon group and a heteroaromatic group.

When the organic compound having a carbazole skeleton includes a condensed ring in a molecule, the refractive index can be further increased. For example, in the case where an organic compound having a carbazole skeleton is obtained without absorbing visible light, the organic compound preferably includes a phenanthrene ring or a naphthalene ring. These rings are preferably bonded to the carbazole ring as a substituent, in which case the molecular weight can be low, sublimation at a low temperature is possible, and high heat resistance and an effect of increasing the refractive index can be obtained. When one phenanthrene ring or naphthalene ring is included in the molecule, the compound can have a high refractive index, and when two or more phenanthrene or naphthalene rings are included, the refractive index can be further increased. For example, a binaphthalene structure in which two naphthalene rings are directly connected to each other is suitable. In the case where the substituent has a binaphthalene structure, the glass transition temperature T_{g} of the compound can be increased. Furthermore, when the 2-position of naphthalene is bonded to another group (that is, a 2-naphthyl group is included), the refractive index can be further increased. This is because the density of the organic compound in the deposited film is increased. In particular, when a 2,2′-binaphthalene structure in which the 2-positions of naphthalenes are bonded to each other is included in a partial structure, the refractive index can be further increased. Note that T_{g} can be improved in the case where the 1-position of naphthalene is bonded to another group (that is, a 1-naphthyl group is included). The organic compound having such a molecular structure can have both a high refractive index and a property of not absorbing visible light.

In the case where the organic compound having a carbazole skeleton includes a biphenyl group as a substituent, the organic compound preferably includes a p-biphenyl group. A compound including a p-biphenyl group can have higher molecular orientation when deposited and thus have a higher ordinary refractive index than a compound including an m-biphenyl group or an o-biphenyl group. Note that an m-biphenyl group or an o-biphenyl group can also be used, in which case an effect of inhibiting sublimation temperature and crystallization of a film can be expected to be reduced.

The organic compound having a carbazole skeleton preferably includes a phenanthrene ring. Alternatively, the organic compound having a carbazole skeleton is preferably an organic compound including a naphthalene ring. Note that an increase in the number of condensed rings tends to increase the evaporation temperature and there is a concern that decomposition of the compound due to heat might be caused at the time of evaporation; thus, the number of naphthalene rings is preferably less than or equal to 4, further preferably less than or equal to 3.

The organic compound having a carbazole skeleton has one to three phenanthrene rings or two to four naphthalene rings as a substituent of the carbazole ring, thereby having a high refractive index and a low sublimation temperature (or a low evaporation temperature). In addition, the organic compound is unlikely to be thermally decomposed at the time of sublimation and does not absorb visible light. In terms of the sublimation temperature, the number of naphthalene rings is further preferably two or three.

It is effective that the organic compound used in the light-emitting device have a low evaporation temperature. That is, the organic compound can be deposited at a low temperature, and thus is less thermally affected during the deposition and decomposition due to heat can be reduced. The cap layer is formed after the formation of the organic compound layer and the second electrode of the light-emitting device and needs to have a certain thickness; thus, in the case where a material with relatively low heat resistance is used for the organic compound layer of the light-emitting device, the organic compound layer might deteriorate when the evaporation temperature of the cap layer is high, which might degrade the characteristics. When the above-described organic compound with a low evaporation temperature is used for the cap layer, the influence of heat on the organic compound layer of the light-emitting device at the time of deposition of the cap layer can be reduced, whereby the light-emitting device can have favorable characteristics.

In particular, materials are heated continuously for a long time in a mass production process; thus, an organic compound having a high evaporation temperature is easily decomposed. When a material is decomposed, stable mass production is difficult. Thus, an organic compound material that can be deposited at a low temperature can be deposited without decomposition of the material, resulting in stable mass production.

The organic compound having a carbazole skeleton may include a heterocycle as a substituent. Examples of heteroatoms included in the heterocycle include nitrogen, oxygen, and sulfur. When a heteroatom is included, the ordinary refractive index can be increased. Alternatively, the glass transition temperature T_{g} can be increased in some cases. In order to improve the refractive index, the heterocycle preferably has a five-membered heteroaromatic ring skeleton including nitrogen, oxygen, and sulfur and preferably has a pyrrole skeleton, a furan skeleton, a thiophene skeleton, an azole (e.g., imidazole, oxazole, thiazole, oxadiazole, or triazole) skeleton, or the like, for example. In particular, a compound having a molecular structure including an atom with a large atomic radius, like a sulfur atom, is expected to have a high refractive index. The condensed ring preferably has a structure including heteroatoms in order that the condensed ring can have an effect of increasing T_{g} and the heteroatoms can have an effect of increasing the refractive index at the same time. That is, a five-membered condensed heteroaromatic ring including nitrogen, oxygen, and sulfur is preferable; examples include a carbazole ring, a dibenzofuran ring, a benzonaphthofuran ring, a dibenzothiophene ring, a benzonaphthothiophene ring, a benzoxazole ring, and a benzothiazole ring. However, when heteroatoms are included, the solubility in an organic solvent might be lowered depending on the kind of heterocycle (hereinafter, a condensed heterocycle is included) which might result in a decrease in yield of a reaction in synthesis or a decrease in purity in purification. In addition, having a heterocycle in a molecular structure probably increases intermolecular interaction, which leads to an increase in sublimation temperature. Thus, the total number of heteroatoms included in the compound other than the carbazole ring is preferably less than or equal to three, further preferably less than or equal to two, still further preferably less than or equal to one. Alternatively, the total number of heterocycles included in the compound other than the carbazole ring is preferably less than or equal to three, further preferably less than or equal to two, still further preferably less than or equal to one.

The organic compound having a carbazole skeleton is further preferably an organic compound represented by General Formulas (G_{H}2) and (G_{H}3).

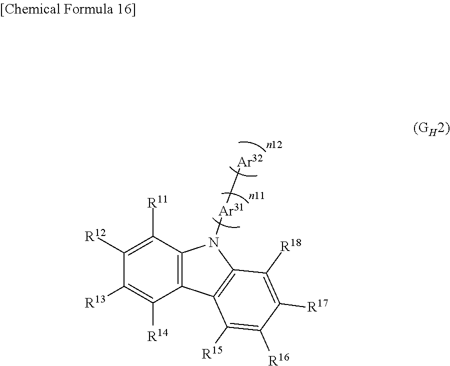

In General Formula (G_{H}2), R¹¹ to R¹⁴ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituent represented by General Formula (G_{H}2-1), R¹⁵ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituent represented by General Formula (G_{H}2-2). Note that at least any one of R¹⁵ to R¹⁸ is preferably a substituent represented by General Formula (G_{H}2-2). Ar³¹ represents a substituted or unsubstituted divalent aromatic hydrocarbon group having 6 to 30 carbon atoms or a substituted or unsubstituted divalent aromatic heterocyclic group having 1 to 30 carbon atoms. Ar³² represents a substituted or unsubstituted monovalent aromatic hydrocarbon group having 6 to 30 carbon atoms or a substituted or unsubstituted monovalent aromatic heterocyclic group having 1 to 30 carbon atoms. In addition, n11 represents an integer greater than or equal to 0 and less than or equal to 3, and n12 represents an integer greater than or equal to 1 and less than or equal to 3.

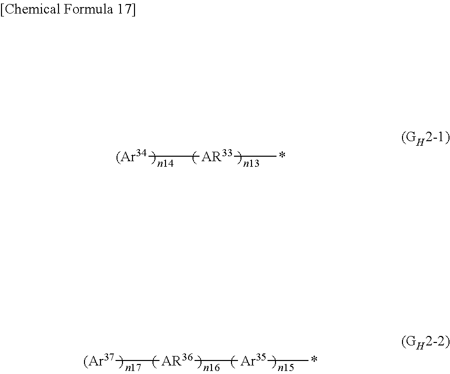

In General Formulas (G_{H}2-1) and (G_{H}2-2), Ar³³, Ar³⁵, and Ar³⁶ each independently represent a substituted or unsubstituted divalent aromatic hydrocarbon group having 6 to 30 carbon atoms (also referred to as an arylene group) or a substituted or unsubstituted divalent aromatic heterocyclic group having 1 to 30 carbon atoms (also referred to as a heteroarylene group). Ar³⁴ and Ar³⁷ each independently represent a substituted or unsubstituted monovalent aromatic hydrocarbon group having 6 to 30 carbon atoms (also referred to as an aryl group) or a substituted or unsubstituted monovalent aromatic heterocyclic group having 1 to 30 carbon atoms (also referred to as a heteroaryl group). At least two of Ar³⁵, Ar³⁶, and Ar³⁷ represent a monovalent or divalent bicyclic or tricyclic aromatic hydrocarbon group or a monovalent or divalent aromatic heterocyclic group (also referred to as a heteroarylene group). In addition, n13, n15, and n16 each independently represent an integer greater than or equal to 0 and less than or equal to 3, and n14 and n17 each independently represent an integer greater than or equal to 1 and less than or equal to 3. Note that it is preferable that n13 be an integer greater than or equal to 0 and less than or equal to 3, n14, n15, n16, and n17 be an integer greater than or equal to 1 and less than or equal to 3, and n15+n16+n17>n13+n14 be satisfied. Note that substituents represented by General Formulas (G_{H}2-1) and (G_{H}2-2) are bonded to General Formula (G_{H}2) in a portion with an asterisk.

Note that when n11 is greater than or equal to two, a plurality of Ar¹¹s may be the same or different substituents. The same applies to Ar³² to Ar³⁷. Each of Ar³¹ to Ar³⁷ preferably includes carbon and hydrogen (including deuterium). Note that each of Ar³², Ar³⁴, and Ar³⁷ may represent hydrogen (including deuterium).

A ring including R¹¹ and R¹², a ring including R¹² and R¹³, a ring including R¹³ and R¹⁴, a ring including R¹⁴ and R¹⁵, a ring including R¹⁵ and R¹⁶, a ring including R¹⁶ and R¹⁷, and a ring including R¹⁷ and R¹⁸ may be formed. For example, in the case where a benzene ring including R² and R³ is formed, the benzene ring and the carbazole ring are condensed to form a structure including a benzocarbazole ring. Such a condensed structure can improve heat resistance and the glass transition temperature (T_{g}). By contrast, in the case where such a condensed structure is not included, the molecular weight is lowered and the sublimation temperature can be increased.

Here, when General Formula (G_{H}2) includes a naphthalene ring or a naphthalene skeleton, the ordinary refractive index can be increased. Note that in this specification, unless otherwise specified, a compound having a naphthalene ring refers to a compound having a naphthalene ring itself, and does not refer to a compound having a naphthalene ring as part of a condensed ring. A compound having a naphthalene skeleton refers to a compound having naphthalene in part of its skeleton. A similar interpretation applies to rings or skeletons other than naphthalene.

When the 2-positions of the naphthalene skeletons are bonded to each other, the ordinary refractive index can be further increased. No bonding at the 1-position of the naphthalene skeleton can increase the refractive index. When the condensed ring having three or less rings is used, the sublimation temperature can be low. Note that a bicyclic condensed ring refers to the one having two rings, such as naphthalene, quinoxaline, or benzoxazole, and a tricyclic condensed ring refers to the one having three rings, such as phenanthrene, anthracene, and carbazole. The same applies to condensed rings having four or more rings.

For example, at least two of Ar³⁵, Ar³⁶, and Ar³⁷ preferably have a substituted or unsubstituted naphthalene ring. In particular, Ar³⁶ and Ar³⁷ preferably have a naphthalene ring. In the case where Ar³⁶ and Ar³⁷ represent naphthalene, the 2-positions of the naphthalenes are preferably bonded to each other to have a high refractive index. In other words, in the case where Ar³⁶ and Ar³⁷ represent naphthalene, the 2-positions of the naphthalenes are bonded to each other to form 2,2′-binaphthalene. The organic compound includes 2,2′-binaphthalene in its partial structure and thus has a preferred molecular structure.

Furthermore, the 2-position of the naphthalene is preferably bonded to another group. Specifically, in the case where Ar³⁵ represents naphthalene, the 2-position and the 6-position of the naphthalene are preferably bonded to the carbazolyl group and Ar³⁶. In the case where Ar³⁶ represents naphthalene, the 2-position and the 6-position of the naphthalene are preferably bonded to Ar³⁷ and Ar³⁵. In the case where Ar³⁷ represents naphthalene, the 2-position of the naphthalene is preferably bonded to Ar³⁶.

In particular, in the case where Ar³, Ar³⁶, and Ar³⁷ are bonded to the 6-positions of Ar³⁵ and Ar³⁶, a material with a high ordinary refractive index can be provided. When this material is used for a device, the device can have high efficiency and low power consumption. A material with high heat resistance can be provided. When this material is used for a device, the device can have high efficiency and high heat resistance.

In the organic compound represented by General Formula (G_{H}2), n15+n16+n17>n13+n14 is preferably satisfied. In this manner, it is preferable that the number of substituents bonded to one of the two benzene rings of the carbazole ring be larger than the number of substituents bonded to the other, in which case the refractive index anisotropy tends to be large. In the organic compound represented by General Formula (G_{H}2), it is preferable that the number of coupled arylene groups or heteroarylene groups that the substituent bonded to one of the two benzene rings of the carbazole ring has (the number of coupled Ar³⁵ to Ar⁷ in the organic compound represented by General Formula (G_{H}2)) be larger than the number of coupled arylene groups or heteroarylene groups that the substituent bonded to the other has (the number of coupled Ar³³ and Ar³⁴ in the organic compound represented by General Formula (G_{H}2)), in which case the refractive index anisotropy tends to be large and the intermolecular interaction can be reduced and thus the sublimation temperature can be decreased. Furthermore, in the organic compound represented by General Formula (G_{H}2), n15+n16+n17>n11+n12 is preferable, in which case the refractive index anisotropy tends to be large. In addition, such a relation of n can increase T_{g}.

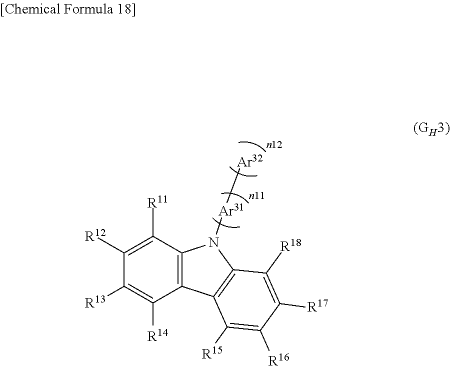

In General Formula (G_{H}3), R¹¹ to R¹⁴ each independently represent any of hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, and a substituent represented by General Formula (G_{H}3-1). R¹⁵ to R¹⁸ each independently represent any of hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, and a substituent represented by General Formula (G_{H}3-2). Note that at least any one of R¹¹ to R¹⁸ is preferably a substituent represented by General Formula (G_{H}3-2). Ar³¹ represents a substituted or unsubstituted divalent aromatic hydrocarbon group having 6 to 30 carbon atoms or a substituted or unsubstituted divalent aromatic heterocyclic group having 1 to 30 carbon atoms. Ar³² represents a substituted or unsubstituted monovalent aromatic hydrocarbon group having 14 to 30 carbon atoms or a substituted or unsubstituted monovalent aromatic heterocyclic group having 1 to 30 carbon atoms. In addition, n11 represents an integer greater than or equal to 0 and less than or equal to 3, and n12 represents an integer greater than or equal to 1 and less than or equal to 3.

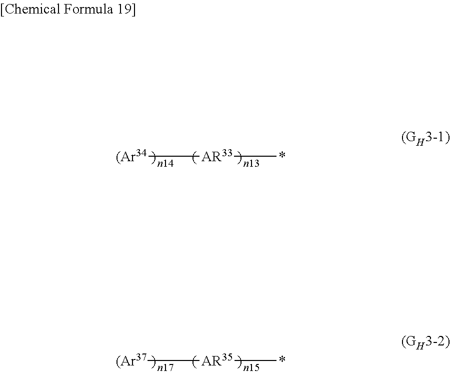

In General Formulas (G_{H}3-1) and (G_{H}3-2), Ar³³ and Ar³⁵ each independently represent a substituted or unsubstituted divalent aromatic hydrocarbon group having 6 to 30 carbon atoms or a substituted or unsubstituted divalent aromatic heterocyclic group having 1 to 30 carbon atoms. Ar³⁴ and Ar³⁷ each independently represent a substituted or unsubstituted monovalent aromatic hydrocarbon group having 6 to 30 carbon atoms or a substituted or unsubstituted monovalent aromatic heterocyclic group having 1 to 30 carbon atoms. At least one of Ar³⁵ and Ar³⁷ represents phenanthrene. When Ar³⁷ represents phenanthrene, the 2- or 3-position of the phenanthrene is bonded to another group. In addition, n13 and n15 each represent an integer greater than or equal to 0 and less than or equal to 3, and n14 and n17 each independently represent an integer greater than or equal to 1 and less than or equal to 3. Note that n13 represents an integer greater than or equal to 0 and less than or equal to 3, and n14, n15, and n17 each independently represent an integer greater than or equal to 1 and less than or equal to 3. Note that substituents represented by General Formulas (G_{H}3-1) and (G_{H}3-2) are bonded to General Formula (G_{H}3) in a portion with an asterisk.

Each of Ar³⁵ and Ar³⁷ may have two or more rings, preferably three or more rings.

At least one of Ar³⁵ and Ar³⁷ is preferably a condensed ring having two or more rings, preferably three or more rings, further preferably four or more rings. Examples of a condensed ring having four or more rings include a triphenylene ring, a benzanthracene ring, a chrysene ring, and a benzophenanthrene ring. The use of a triphenylene ring is preferable because the refractive index is increased and T_{g} can be increased. Note that in order to lower the sublimation temperature, the number of rings is preferably small.

In General Formulas (G_{H}3-1) and (G_{H}3-2), at least one of Ar³³ and Ar³⁴ represents a condensed ring, and at least one of Ar³⁵ and Ar³⁷ represents a condensed ring.

Note that when n15 is greater than or equal to two, a plurality of Ar³⁵s may be the same or different substituents. The same applies to Ar³⁷. Each of Ar³⁵ and Ar³⁷ preferably includes carbon and hydrogen (including deuterium). Note that each of Ar³², Ar³⁴, and Ar³⁷ may each represent hydrogen (deuterium).

In General Formula (G_{H}3-2), when Ar³⁵ or Ar³⁷ represents phenanthrene and the 2- or 3-position of the phenanthrene is bonded to another group, the ordinary refractive index can be increased. Particularly when Ar³⁷ represents phenanthrene, the 2- or 3-position of the phenanthrene is preferably bonded to another group to further increase the ordinary refractive index.

In the organic compound represented by General Formula (G_{H}3), n15+n17>n13+n14 is preferably satisfied. In this manner, it is preferable that the number of substituents bonded to one of the two benzene rings of the carbazole ring be larger than the number of substituents bonded to the other, in which case the refractive index anisotropy tends to be large. In the organic compound represented by General Formula (G_{H}3), it is preferable that the number of coupled divalent aromatic hydrocarbon groups or divalent aromatic heterocyclic groups that the substituent bonded to one of the two benzene rings of the carbazole ring has (the number of coupled Ar³⁵ and Ar³⁷ in the organic compound represented by General Formula (G_{H}3)) be larger than the number of coupled divalent aromatic hydrocarbon groups or divalent aromatic heterocyclic groups that the substituent bonded to the other has (the number of coupled Ar³³ and Ar³⁴ in the organic compound represented by General Formula (G_{H}3)), in which case the refractive index anisotropy tends to be large and the intermolecular interaction can be reduced and thus the sublimation temperature can be decreased. Furthermore, in the organic compound represented by General Formula (G_{H}3), n15+n17>n11+n12 is preferable, in which case the refractive index anisotropy tends to be large. In addition, such a relation of n can increase T_{g}.

As the alkyl group having 1 to 6 carbon atoms represented by R¹¹ to R¹⁸ in General Formulas (G_{H}1) to (G_{H}3), a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a 3-methylpentyl group, a 2-methylpentyl group, a 2-ethylbutyl group, a 1,2-dimethylbutyl group, a 2,3-dimethylbutyl group, or the like can be used, for example. In the case where the alkyl group having 1 to 6 carbon atoms has a substituent, the substituent can be a cycloalkyl group having 1 to 5 carbon atoms or an aromatic hydrocarbon group having 6 to 13 carbon atoms.

As the cycloalkyl group having 3 to 6 carbon atoms represented by R¹¹ to R¹⁸ in General Formulas (G_{H}1) to (G_{H}3), a cyclopropyl group, a cyclobutyl group, a cyclopentyl group, a cyclohexyl group, a 1-methylcyclohexyl group, a cycloheptyl group, an adamantyl group, a bicyclo[2,2,2]octyl group, a norbornyl group, or the like can be used, for example. In the case where the alkyl group having 1 to 6 carbon atoms has a substituent, the substituent can be a cycloalkyl group having 1 to 4 carbon atoms or an aromatic hydrocarbon group having 6 to 13 carbon atoms.

Examples of the aromatic hydrocarbon group having 6 to 30 carbon atoms in General Formulas (G_{H}1) to (G_{H}3) include a phenyl group, an o-tolyl group, a m-tolyl group, ap-tolyl group, a mesityl group, a biphenyl-2-yl group (o-biphenyl group), a biphenyl-3-yl group (m-biphenyl group), a biphenyl-4-yl group (p-biphenyl group), a 1-naphthyl group, a 2-naphthyl group, a phenylnaphthyl group, a naphthylphenyl group, a terphenyl group, a fluorenyl group, a 9,9-dimethylfluorenyl group, a quaterphenyl group, a spirobifluorenyl group, a phenanthryl group, an anthryl group, a binaphthylphenyl group, a fluoranthenyl group, and a triphenylenyl group. In the case where the aromatic hydrocarbon group having 6 to 30 carbon atoms has a substituent, examples of the substituent include an alkyl group having 1 to 4 carbon atoms, a cycloalkyl group having 3 to 6 carbon atoms, or an aromatic hydrocarbon group having 6 to 13 carbon atoms.

Specific examples of the aromatic heterocyclic group having 1 to 30 carbon atoms in General Formulas (G_{H}1) to (G_{H}3) include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. In the case where the aromatic heterocyclic group having 1 to 30 carbon atoms has a substituent, examples of the substituent include an alkyl group having 1 to 4 carbon atoms, a cycloalkyl group having 3 to 6 carbon atoms, and an aromatic hydrocarbon group having 6 to 13 carbon atoms.

In the case where R¹¹ to R¹⁸ and Ar³¹ to Ar³⁷ in any of General Formulas (G_{H}2), (G_{H}3), (G_{H}2-1), (G_{H}2-2), (G_{H}3-1), and (G_{H}3-2) each represent an aromatic hydrocarbon group having 6 to 30 carbon atoms or an aromatic heterocyclic group having 3 to 30 carbon atoms, the group can have a structure that is obtained by removing a number of hydrogen atoms corresponding to the number of substitution sites from the aromatic hydrocarbon or aromatic heterocycle represented by any of Structural Formulas (Ar-1) to (Ar-33).

For example, a naphthyl group refers to a monovalent substituent that is obtained by removing one hydrogen atom from a naphthalene ring (represented by Structural Formula (Ar-17)). A naphthalene-diyl group refers to a divalent substituent that is obtained by removing two hydrogen atoms from a naphthalene ring. The same applies to the others of Structural Formulae (Ar-1) to (Ar-33) and the like. Therefore, for example, in the case where Ar³⁵ represents a pyridine ring (represented by Structural Formula (Ar-5)) and Ar³⁶ and Ar³⁷ represent naphthalene rings in General Formula (G_{H}2-2), it is expressed that “Ar³⁵ represents a pyridine-diyl group, Ar³⁶ represents a naphthalene-diyl group, and Ar³⁷ represents a naphthyl group” in a strict sense; however, it can also be expressed that “Ar³⁵ represents a pyridine ring and Ar³⁶ and Ar³⁷ represent naphthalene rings”.

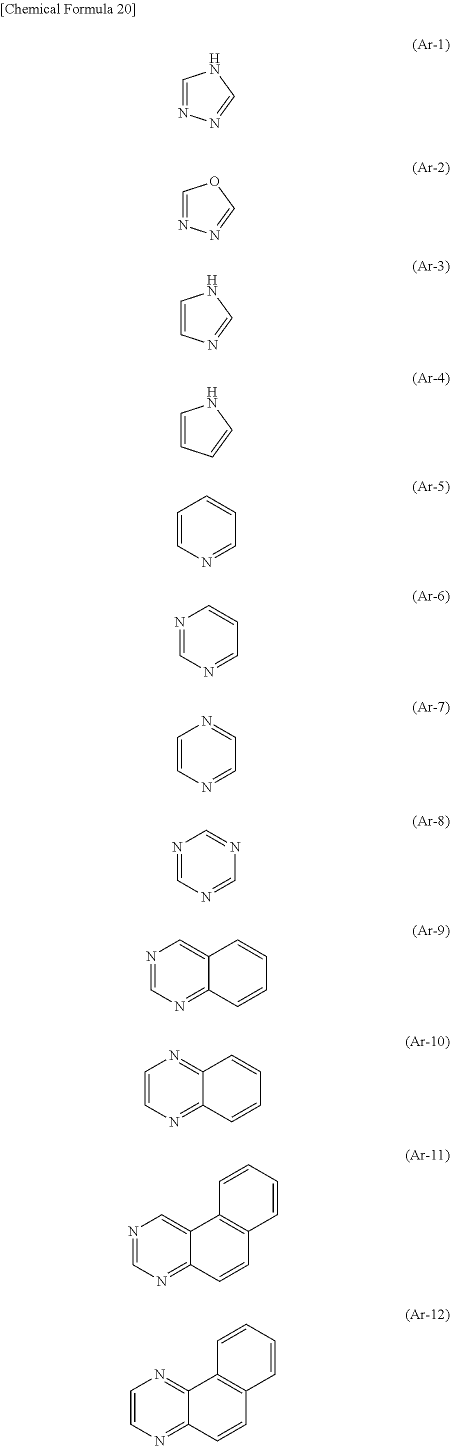

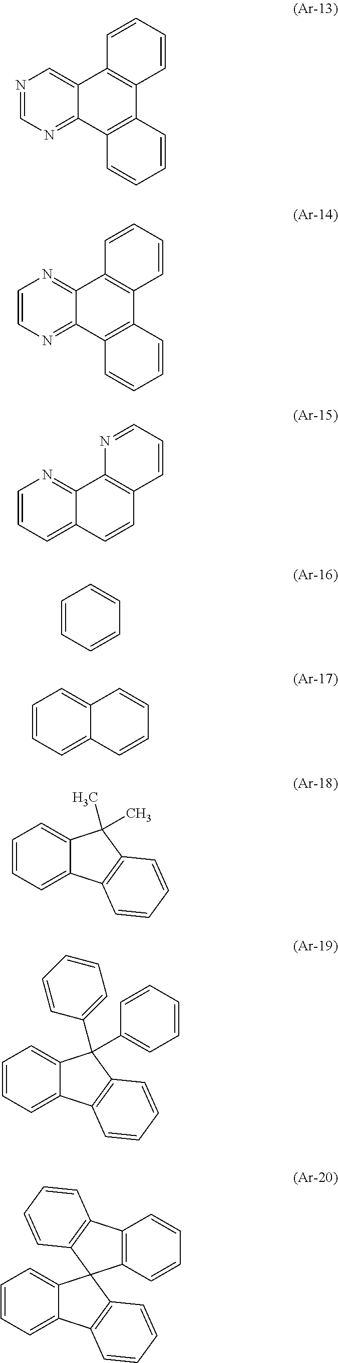

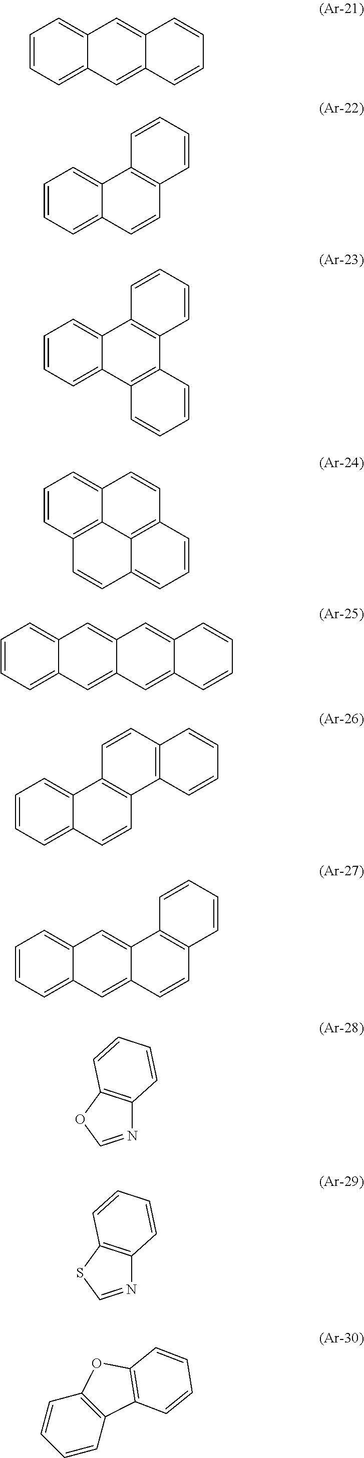

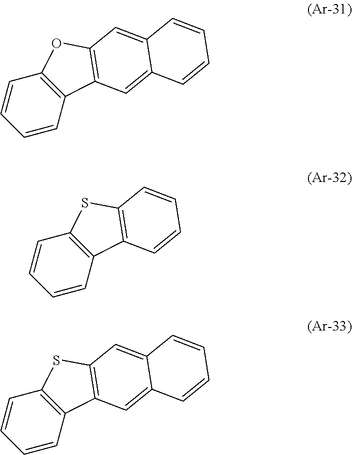 [SMILES: c1ccc2cc3c(cc2c1)oc1ccccc13 ; c1ccc2c(c1)sc1ccccc12 ; c1ccc2cc3c(cc2c1)sc1ccccc13]

In the case where the aromatic hydrocarbon group or the aromatic heterocyclic group has a substituent, examples of the substituent include a cyano group, a halogen group, an alkyl group having 1 to 4 carbon atoms, a cycloalkyl group having 3 to 6 carbon atoms, an aromatic hydrocarbon group having 6 to 13 carbon atoms, and an aromatic heterocyclic group having 3 to 10 carbon atoms. An effect of reducing the driving voltage of the device can be expected by having a cyano group or a halogen group. Furthermore, with an alkyl group or a cycloalkyl group, an effect of decreasing the sublimation temperature can be expected; thus, such a compound can be used in a variety of layers such as a cap layer. Furthermore, with an alkyl group or a cycloalkyl group, the ordinary refractive index is sometimes lowered; thus, such a compound is particularly suitably used for a layer that is required to have a low ordinary refractive index, such as a transport layer (a hole-transport layer or an electron-transport layer). Note that similar effects can be expected when a cyano group, a halogen group, an alkyl group, or a cycloalkyl group is used as R¹¹ to R¹⁸.

As described above, the organic compound having a carbazole skeleton has a molecular structure that includes a condensed ring in a molecule, does not absorb visible light, enables sublimation at a low temperature, and achieves high heat resistance and an effect of increasing the refractive index. By contrast, the monoamine compound having an alkyl group has a relatively low evaporation temperature to be easily evaporated, enables a film with high quality and stability, can have a molecular structure with a short effective conjugation length so as not to absorb visible light, and has a low refractive index.

When the organic compound having a carbazole skeleton and the monoamine compound having an alkyl group are compared to each other, the monoamine compound having an alkyl group has a molecular structure that has a lower sublimation temperature and is less likely to undergo a change in film quality such as crystallization because of having an alkyl group, that is, an extremely stable film can be formed by low-temperature evaporation.

On the other hand, the organic compound having a carbazole skeleton is characterized by having a high refractive index and has a preferred structure with no alkyl group. Although having a high refractive index and a high glass transition temperature (T_{g}), the organic compound having a carbazole skeleton may probably undergo a change in film quality such as crystallization when preserved at a high temperature in a thin film state.

When the cap layer includes a film of the organic compound having a carbazole skeleton and a film of the monoamine compound having an alkyl group, or preferably has a stack of the film of the organic compound having a carbazole skeleton and the film of the monoamine compound having an alkyl group that are in contact with each other, an extremely stable film or cap layer can be provided. This is an effect obtained by combining the film of an organic compound having a carbazole skeleton and the film of a monoamine compound having an alkyl group.

The structure described in this embodiment can be combined as appropriate with any of the structures described in the other embodiments.

Note that information on the stacked-layer structure of the cap layer 155 and the molecular weight, the number, and the like of substances contained in the cap layer 155 can be found by using time-of-flight secondary ion mass spectrometry (ToF-SIMS). In that case, depending on the thickness of the cap layer or the measurement conditions, even when the cap layer has a stacked-layer structure of a layer including the first substance and a layer including the second substance, the cap layer is sometimes detected like a mixed layer.

This embodiment can be freely combined with any of the other embodiments.

### Embodiment 2

In this embodiment, the light-emitting device 600 of one embodiment of the present invention will described in detail. The light-emitting device 600 shown in FIGS. 1A to 1C includes the organic compound layer 103 between the first electrode 101 formed over an insulating layer 1000 and the second electrode 102 facing the first electrode 101, and the cap layer 155 over the second electrode 102. The organic compound layer 103 has a stacked-layer structure of functional layers such as a hole-injection layer 111, a hole-transport layer 112, the light-emitting layer 113, an electron-transport layer 114, and an electron-injection layer 115. As illustrated in FIGS. 1A to 1C, the organic compound layer preferably has a stacked-layer structure including functional layers that have different functions and contain organic compounds with properties required for their respective functions.

There are various functions required for the functional layers, and typical examples of the functional layers are a carrier-injection layer, a carrier-transport layer, a light-emitting layer, a photoelectric conversion layer, a charge-generation layer, a carrier-blocking layer, and an exciton-blocking layer. Additionally, each of the functional layers may further have another function. Each of the functional layers has a stacked-layer structure in some cases.

In the case where the hole-transport layer 112 has a stacked-layer structure, one of the layers that is in contact with the light-emitting layer 113 is specifically referred to as an electron-blocking layer in some cases. In the case where the electron-transport layer 114 has a stacked-layer structure, one of the layers that is in contact with the light-emitting layer is specifically referred to as a hole-blocking layer in some cases.

In this embodiment, the case where the first electrode 101 and the second electrode 102 respectively function as an anode and a cathode is described as an example; however, the first electrode 101 and the second electrode 102 may respectively function as a cathode and an anode. Note that the second electrode 102 is an electrode transmitting visible light, and the light-emitting device of one embodiment of the present invention is what is called a top-emission light-emitting device.

The structure of the cap layer 155 is described in detail in Embodiment 1; thus, repeated description thereof is omitted. The description in Embodiment 1 is to be referred to.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Such conductive metal oxide films are deposited by a sputtering method in many cases, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide including tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium, (Ti), aluminum (Al), nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111, which is described later, is used for a layer (typically, the hole-injection layer) in contact with the anode, an electrode material can be selected regardless of its work function.

The hole-injection layer 111 is provided in contact with the anode and has a function of facilitating injection of holes to the organic compound layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/polystyrenesulfonic acid (abbreviation: PEDOT/PSS), for example.

The hole-injection layer 111 may be formed using a substance having an electron-acceptor property. Examples of the substance having an acceptor property include organic compounds having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,′-1,2,3-cyclopropanetriylidenetris[4-cyano-2,3,5,6-tetrafluorobenzeneacetonitrile], α,′-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds. The substance having an acceptor property can extract electrons from an adjacent hole-transport layer (or hole-transport material) by application of an electric field.

The hole-injection layer 111 is preferably formed using a composite material including any of the aforementioned materials having an acceptor property and a substance having a hole-transport property.

As the substance having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the substance having a hole-transport property used in the composite material preferably has a hole mobility higher than or equal to 1×10⁻⁶ cm²/Vs. The substance having a hole-transport property used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is condensed to a carbazole ring or a dibenzothiophene ring is preferable.

Such a hole-transport substance further preferably has any one or more of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the substance having a hole-transport property preferably has an N,N-bis(4-biphenyl)amino group, enabling manufacturing a light-emitting device with a long lifetime.

Specific examples of the substance having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAPNB), 4-[4-(2-naphthyl)phenyl]-4′,4″-diphenyltriphenylamine (abbreviation: BBAPNBi), 4,4′-diphenyl-4″-(6;1′-binaphthyl-2-yl)triphenylamine (abbreviation: BBAaNQNB), 4,4′-diphenyl-4″-(7;1′-binaphthyl-2-yl)triphenylamine (abbreviation: BBAaNQNB-03), 4,4′-diphenyl-4″-(7-phenyl)naphthyl-2-yltriphenylamine (abbreviation: BBAPPNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAPNaNB), 4,4′-diphenyl-4″-(5;2′-binaphthyl-1-yl)triphenylamine (abbreviation: BBAPNaNB-02), 4-(4-biphenylyl)-4′-(2-naphthyl)-4″-phenyltriphenylamine (abbreviation: TPBiAPNB), 4-(3-biphenylyl)-4′-[4-(2-naphthyl)phenyl]-4″-phenyltriphenylamine (abbreviation: mTPBiAPNBi), 4-(4-biphenylyl)-4′-[4-(2-naphthyl)phenyl]-4″-phenyltriphenylamine (abbreviation: TPBiAPNBi), 4-phenyl-4′-(1-naphthyl)triphenylamine (abbreviation: aNBA1BP), 4,4′-bis(1-naphthyl)triphenylamine (abbreviation: aNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the substance having a hole-transport property include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because it is easily deposited by evaporation.

The hole-transport layer 112 is formed using a substance having a hole-transport property. The substance having a hole-transport property preferably has a hole mobility higher than or equal to 1×10⁻⁶ cm²/Vs.

Examples of the substance having a hole-transport property include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above substances, the compound having an aromatic amine skeleton or the compound having a carbazole skeleton is preferable because the compound is highly reliable and has a high hole-transport property to contribute to a reduction in driving voltage. Any of the organic compounds given as examples of the substance having a hole-transport property used in the composite material for the hole-injection layer 111 can also be suitably used as the material included in the hole-transport layer 112.

The emission center substance included in the light-emitting layer 113 can be a fluorescent substance, a phosphorescent substance, a substance exhibiting thermally activated delayed fluorescence (TADF), or any other light-emitting substance.

Examples of the material that can be used as a fluorescent substance in the light-emitting layer 113 are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(NN,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-NN,N-triphenyl-1,4-phenylenediamine (abbreviation: 2DPAPPA), N,N,N,N,N″,N″,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-NN,N-triphenyl-1,4-phenylenediamine (abbreviation: 2DPAPA), N-[9,10-bis(biphenyl-2-yl)-2-anthryl]-N,NN-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b;6,7-b′]bisbenzofuran-3,10-diamine (abbreviation: 3,1OPCA2Nbf(IV)-02), and 3,10-bis[N-(dibenzofuran-3-yl)-N-phenylamino]naphtho[2,3-b;6,7-b′]bisbenzofuran (abbreviation: 3,1OFrA2Nbf(IV)-02). Condensed aromatic diamine compounds typified by pyrenediamine compounds such as 1,6FLPAPrn, 1,6mMemFLPAPm, and 1,6BnfAPrn-03 are particularly preferable because of their high hole-trapping properties, high emission efficiency, or high reliability.

A condensed heteroaromatic compound including nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y), or the like can be suitably used.

In the case where a phosphorescent substance is used as the light-emitting substance in the light-emitting layer 113, a metal complex, in particular, an iridium complex or a platinum complex is preferable as the phosphorescent substance; examples of the materials are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-KN²]phenyl-KC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-KN³}-4-cyanophenyl-KC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-KC²)phenyl-KC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF3ppy)2(pic)]), and bis[2-(4′,6′-difluorophenyl)pyridinato-N,C²′]iridium(III) acetylacetonate (abbreviation: FIracac); and platinum complexes such as (2-{3-[3-(3,5-di-tert-butylphenyl)benzimidazol-1-yl-2-ylidene-KC²]phenoxy-KC²}-9-(4-tert-butyl-2-pyridinyl-KN)carbazole-2,1-diyl-KC′)platinum(II) (abbreviation: PtON-TBBI). These compounds emit phosphorescent light with a blue hue and have an emission peak in the wavelength range from 450 nm to 520 nm. A compound obtained by substituting a deuterium atom(s) for one or some of hydrogen atoms in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)2(acac)]), (acetylacetonato)bis(6-tert-butyl-4-phenylpyrimidinato)iridium(III) (abbreviation: [Ir(tBuppm)2(acac)]), (acetylacetonato)bis[6-(2-norbornyl)-4-phenylpyrimidinato]iridium(III) (abbreviation: [Ir(nbppm)2(acac)]), (acetylacetonato)bis[5-methyl-6-(2-methylphenyl)-4-phenylpyrimidinato]iridium(III) (abbreviation: [Ir(mpmppm)2(acac)]), and (acetylacetonato)bis(4,6-diphenylpyrimidinato)iridium(III) (abbreviation: [Ir(dppm)2(acac)]); organometallic iridium complexes having a pyrazine skeleton, such as (acetylacetonato)bis(3,5-dimethyl-2-phenylpyrazinato)iridium(III) (abbreviation: [Ir(mppr-Me)2(acac)]) and (acetylacetonato)bis(5-isopropyl-3-methyl-2-phenylpyrazinato)iridium(III) (abbreviation: [Ir(mppr-iPr)2(acac)]); organometallic iridium complexes having a pyridine skeleton, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)2(acac)]), bis(benzo[h]quinolinato)iridium(III) acetylacetonate (abbreviation: [Ir(bzq)2(acac)]), tris(benzo[h]quinolinato)iridium(III) (abbreviation: [Ir(bzq)₃]), tris(2-phenylquinolinato-N,C″)iridium(III) (abbreviation: [Ir(pq)₃]), bis(2-phenylquinolinato-N,C″)iridium(III) acetylacetonate (abbreviation: [Ilr(pq)2(acac)]), [2-d₃-methyl-8-(2-pyridinyl-xN)benzofuro[2,3-b]pyridine-KC]bis[2-(5-d₃-methyl-2-pyridinyl-xN²)phenyl-KC]iridium(III) (abbreviation: Ir(5mppy-d₃)2(mbfpypy-d₃)), {2-(methyl-d₃)-8-[4-(1-methylethyl-1-d)-2-pyridinyl-xN]benzofuro[2,3-b]pyridin-7-yl-cC}bis{5-(methyl-d₃)-2-[5-(methyl-d₃)-2-pyridinyl-KN]phenyl-cC}iridium(III) (abbreviation: Ir(5mtpy-d6)₂(mbfpypy-iPr-d₄)), [2-d₃-methyl-(2-pyridinyl-KN)benzofuro[2,3-b]pyridine-KC]bis[2-(2-pyridinyl-xN)phenyl-KC]iridium(III) (abbreviation: Ir(ppy)₂(mbfpypy-d₃)), [2-(4-methyl-5-phenyl-2-pyridinyl-xN)phenyl-KC]bis[2-(2-pyridinyl-xN)phenyl-KC]iridium(III) (abbreviation: Ir(ppy)2(mdppy)), [2-(4-d₃-methyl-5-phenyl-2-pyridinyl-xN²)phenyl-KC]bis[2-(5-d₃-methyl-2-pyridinyl-xN²)phenyl-KC]iridium(III) (abbreviation: [Ir(5mppy-d₃)2(mdppy-d₃)]), [2-methyl-(2-pyridinyl-xN)benzofuro[2,3-b]pyridine-KC]bis[2-(2-pyridinyl-xN)phenyl-KC]iridium(III) (abbreviation: [Ir(ppy)2(mbfpypy)]), [2-(4-methyl-5-phenyl-2-pyridinyl-xN)phenyl-KC]bis[2-(2-pyridinyl-xN)phenyl-KC]iridium (abbreviation: [Ir(ppy)2(mdppy)]), and tris{2-[5-(methyl-d₃)-4-phenyl-2-pyridinyl-xN]phenyl-KC}iridium(III) (abbreviation: Ir(5m4dppy-d₃)3); organometallic platinum complexes such as (2-{1-(5-tert-butylbiphenyl-2-yl)-4-[3-tert-butyl-5-(4-phenyl-2-pyridinyl-xN)phenyl-KCC⁶]-2-benzimidazolyl-xNN³}-4,6-di-tert-butylphenolato-KO)platinum(II) (abbreviation: Pt(tBudppymmtBubiz-tBubp)) and [2-(4-(3,5-di-tert-butylphenyl)-6-{3-[4-(5′-tert-butyl[1,1′: 3′,1″-terphenyl]-2′-yl)-2-pyridinyl-xN]phenyl-KC²}-2-pyridinyl-xN)phenolato-KO]platinum(II) (abbreviation: Pt(4tButpppypyp-mmtBup)); and rare earth metal complexes such as tris(acetylacetonato) (monophenanthroline)terbium(III) (abbreviation: [Tb(acac)3(Phen)]). These compounds mainly emit phosphorescent light with a green hue and have an emission peak in the wavelength range from 500 nm to 600 nm. Note that organometallic iridium complexes having a pyrimidine skeleton have distinctively high reliability or emission efficiency and thus are particularly preferable. A compound obtained by substituting a deuterium atom(s) for one or some of hydrogen atoms in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(dlnpm)2(dpm)]); organometallic iridium complexes having a pyrazine skeleton, such as (acetylacetonato)bis(2,3,5-triphenylpyrazinato)iridium(III) (abbreviation: [Ir(tppr)2(acac)]), bis(2,3,5-triphenylpyrazinato)(dipivaloylmethanato)iridium(III) (abbreviation: [Ir(tppr)2(dpm)]), and (acetylacetonato)bis[2,3-bis(4-fluorophenyl)quinoxalinato]iridium(III) (abbreviation: [Ir(Fdpq)2(acac)]); organometallic iridium complexes having a pyridine skeleton, such as tris(1-phenylisoquinolinato-N,C″)iridium(III) (abbreviation: [Ir(piq)₃]), bis(1-phenylisoquinolinato-N,C²′)iridium(III) acetylacetonate (abbreviation: [Ir(piq)2(acac)]), (3,7-diethyl-4,6-nonanedionato-k0⁴,k0⁶)bis[2,4-dimethyl-6-[7-(1-methylethyl)-1-isoquinolinyl-N]phenyl-cC]iridium(III), and (3,7-diethyl-4,6-nonanedionato-kO⁴,k0⁶)bis[2,4-dimethyl-6-[5-(1-methylethyl)-2-quinolinyl-KN]phenyl-KC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)3(Phen)]). These compounds emit phosphorescent light with a red hue and have an emission peak in the wavelength range from 600 nm to 700 nm. Furthermore, the organometallic iridium complexes having a pyrazine skeleton can provide red light emission with favorable chromaticity. A compound obtained by substituting a deuterium atom(s) for one or some of hydrogen atoms in any of these compounds can also be used.

Note that in one embodiment of the present invention, the use of a deuterated compound as the emission center substance improves the emission efficiency. Thus, the emission center substance is preferably a deuterated material.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-including porphyrin, such as a porphyrin including magnesium (Mg), zinc (Zn), cadmium (Cd), tin (Sn), platinum (Pt), indium (In), palladium (Pd), or the like can be given. Examples of the metal-including porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulas.

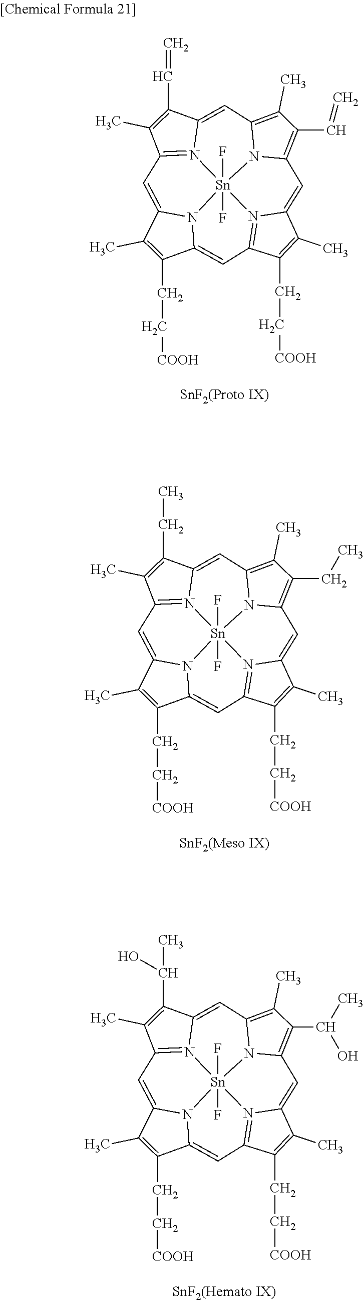

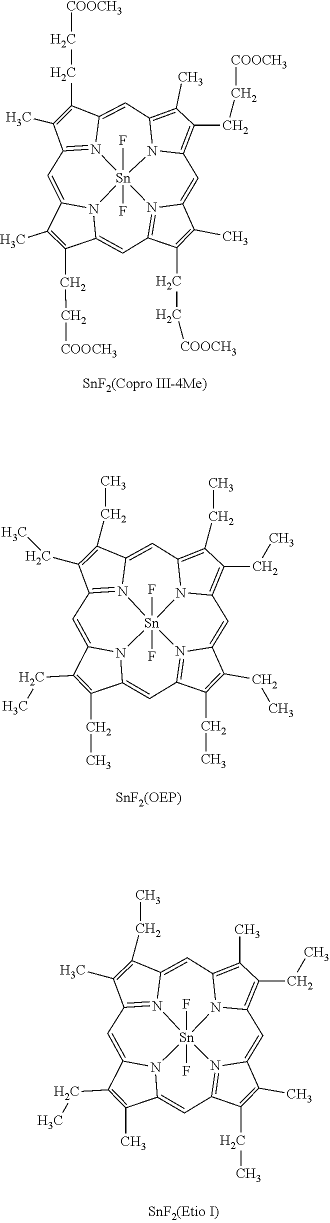

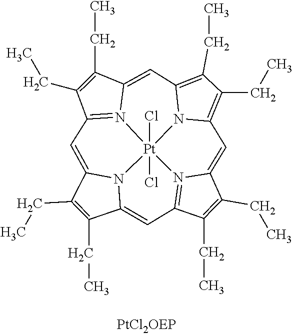

Alternatively, it is possible to use a heterocyclic compound having one or both of a π-electron rich heteroaromatic ring and a π-electron deficient heteroaromatic ring that is represented by the following structural formulas, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(1OH-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-1OH,10′H-spiro[acridin-9,9′-anthracen]-10′-one (abbreviation: ACRSA). Such a heterocyclic compound is preferable because of having high electron-transport and hole-transport properties owing to its π-electron rich heteroaromatic ring and its π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a π-electron deficient heteroaromatic ring is particularly preferable because the electron-donating property of the π-electron rich heteroaromatic ring and the electron-accepting property of the π-electron deficient heteroaromatic ring are both improved, the energy difference between the Si level and the Ti level becomes small, and thus thermally activated delayed fluorescence can be obtained with high efficiency. Note that an aromatic ring to which an electron-withdrawing group such as a cyano group is bonded may be used instead of a π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton or a π-electron rich skeleton can be used instead of at least one of a π-electron deficient heteroaromatic ring and a π-electron rich heteroaromatic ring.

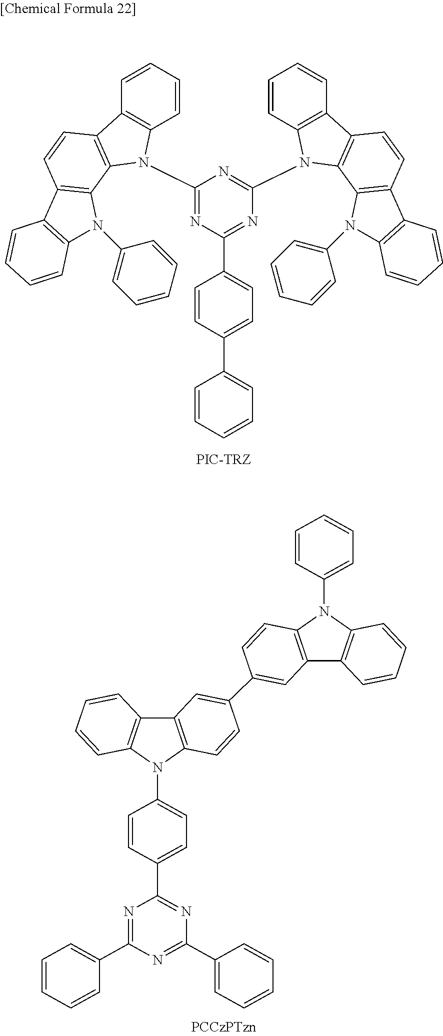 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

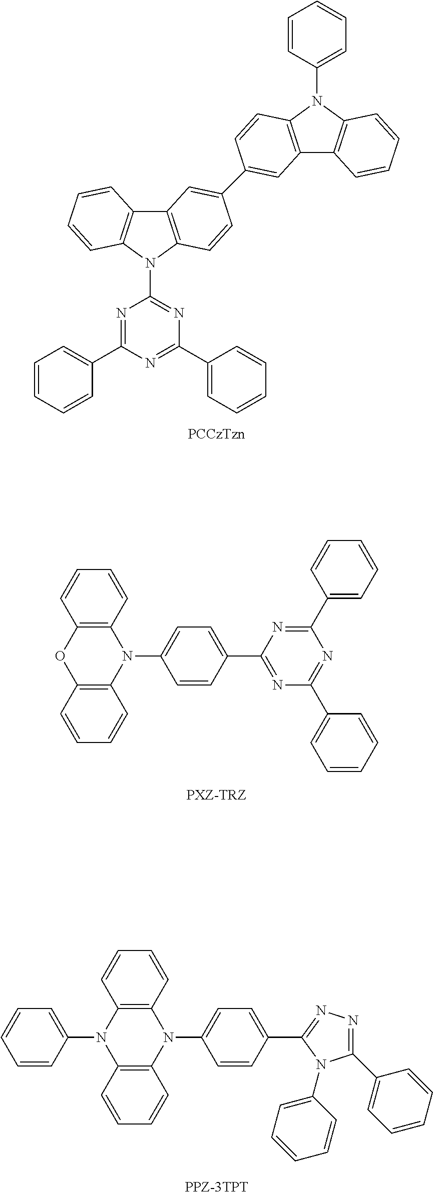 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

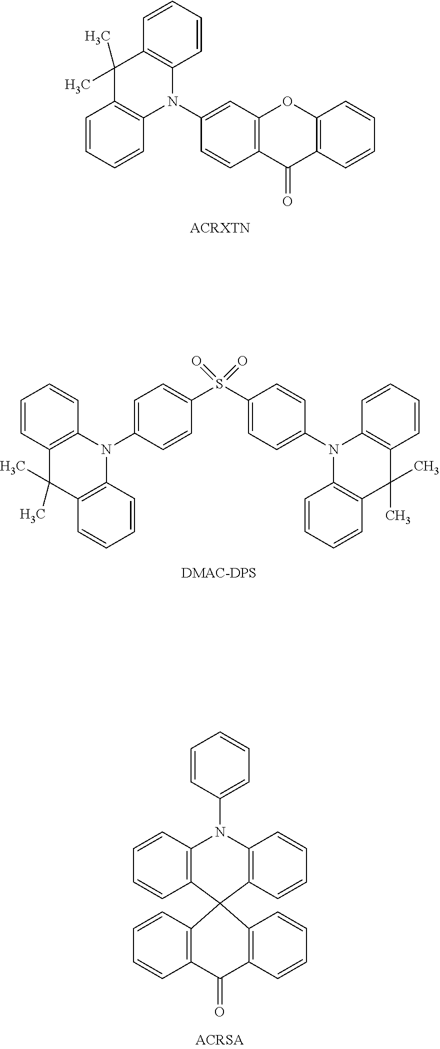 [SMILES: CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specifically, a material having the following molecular structure can be used.

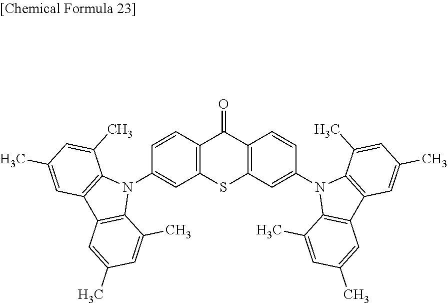

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at low temperatures (e.g., 77 K to 10 K) can be used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer 113, various carrier-transport materials such as a substance having an electron-transport property and/or a substance having a hole-transport property, and the TADF material can be used.

As the substance having a hole-transport property that can be used as the host material of the light-emitting layer 113, an organic compound having an amine skeleton or a π-electron rich heteroaromatic ring skeleton is preferably used, for example. As the π-electron rich heteroaromatic ring, a condensed aromatic ring having any one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is condensed to a carbazole ring or a dibenzothiophene ring is preferable.

Such a hole-transport substance further preferably has any one or more of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the substance having a hole-transport property is preferably an organic compound having an N,N-bis(4-biphenyl)amino group, enabling manufacturing a light-emitting device having a long lifetime.

As such an organic compound, any of the following organic compounds is preferable, for example. Examples include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′: 6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable, have high hole-transport properties, and contribute to a reduction in driving voltage. In addition, the organic compounds given as examples of the material having a hole-transport property that can be used for the hole-transport layer can also be used.

The substance having an electron-transport property that can be used as the host material of the light-emitting layer 113 is preferably a substance having an electron mobility higher than or equal to 1×10⁻⁷ cm²/Vs, preferably higher than or equal to 1×10⁻⁶ cm²/Vs when the square root of electric field strength [V/cm] is 600. Note that any other substance can also be used as long as the substance has an electron-transport property higher than a hole-transport property.

As the substance having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that includes a heteroaromatic ring having an azole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property and contribute to a reduction in driving voltage. A benzofuropyrimidine skeleton, a benzothienopyrimidine skeleton, a benzofuropyrazine skeleton, and a benzothienopyrazine skeleton are preferable because of their high acceptor property and high reliability.

The organic compound having a π-electron deficient heteroaromatic ring skeleton is preferably any of the following organic compounds, for example. Preferable examples of the organic compound having a π-electron deficient heteroaromatic ring include the following organic compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), and 8-(p-terphenyl-3-yl)-4-[3-(dibenzothiophen-4-yl)phenyl]-[1]benzofuro[3,2-d]pyrimidine (abbreviation: 8mpTP-4mDBtPBfpm); and organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 2-[4-(2-naphthyl)phenyl]-4-phenyl-6-spiro[9H-fluorene-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn). The organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound including a heteroaromatic ring having a diazine (pyrimidine or pyrazine) skeleton and the organic compound including a heteroaromatic ring having a triazine skeleton have a high electron-transport property and contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance in the light-emitting layer 113, a material having an acene skeleton, especially an anthracene skeleton is suitably used as the host material. The use of a substance having an anthracene skeleton as the host material for the fluorescent substance enables a light-emitting layer with high emission efficiency and high durability. Among the substances having an anthracene skeleton that is used as the host material, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is condensed to a carbazole skeleton because the HOMO level thereof is higher than that of the host material having a carbazole skeleton by approximately 0.1 eV and thus holes enter the host material easily. In particular, the host material preferably has a dibenzocarbazole skeleton because the HOMO level thereof is higher than that of the host material having a carbazole skeleton by approximately 0.1 eV so that holes enter the host material easily, the hole-transport property is improved, and the heat resistance is increased. Accordingly, a substance having both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Furthermore, a dibenzofuran skeleton is preferably included as the host material, in which case the reliability can be ensured without a reduction in the T₁ level.

Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: aN-QNPAnth), 9-(1-naphthyl)-10-(2-naphthyl)anthracene (abbreviation: a,PADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: PN-mQNPAnth), and 1-{4-[10-(biphenyl-4-yl)-9-anthryl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a substance having an electron-transport property with a substance having a hole-transport property. By mixing the material having an electron-transport property with the material having a hole-transport property, the transport property of the light-emitting layer 113 can be easily adjusted and a recombination region can be easily controlled. The weight ratio of the content of the substance having a hole-transport property to the content of the substance having an electron-transport property is preferably 1:19 to 19:1.

Note that a phosphorescent substance can be used as a part of the mixed host material. When a fluorescent substance is used as the light-emitting substance, the phosphorescent substance can be used as an energy donor for supplying excitation energy to the fluorescent substance.

An exciplex may be formed of these mixed materials. The materials are preferably selected so as to form an exciplex that exhibits light emission whose wavelength overlaps with the wavelength of a lowest-energy-side absorption band of the light-emitting substance, in which case energy can be transferred smoothly and light emission can be obtained efficiently. The use of such a structure is preferable, also enabling the driving voltage to be reduced.

Note that at least one of the materials forming an exciplex may be a phosphorescent substance. In this manner, triplet excitation energy can be efficiently converted into singlet excitation energy by reverse intersystem crossing.

In order to form an exciplex efficiently, a substance having an electron-transport property is preferably combined with a substance having a hole-transport property and a HOMO level higher than or equal to that of the substance having an electron-transport property. In addition, the LUMO level of the substance having a hole-transport property is preferably higher than or equal to that of the substance having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed, for example, in the following manners: when the emission spectrum of the substance having a hole-transport property, the emission spectrum of the substance having an electron-transport property, and the emission spectrum of a mixed film of these substances are compared, it is observed that the emission spectrum of the mixed film is shifted to the longer wavelength than the emission spectrum of each of the substance having a hole-transport property and the substance having an electron-transport property (or has a peak on the longer wavelength side). Alternatively, when the transient photoluminescence (PL) of the substance having a hole-transport property, the transient PL of the substance having an electron-transport property, and the transient PL of the mixed film of these substances are compared, a difference in transient response is observed, for example, the transient PL lifetime of the mixed film has a longer lifetime component or has a larger portion of a delayed component than that of each of the substance having a hole-transport property and the substance having an electron-transport property. The transient PL can be rephrased as transient electroluminescence (EL). That is, the formation of an exciplex can also be confirmed by comparing the transient EL of the substance having a hole-transport property, the transient EL of the substance having an electron-transport property, and the transient EL of the mixed film of these substances and observing a difference in transient response.

The electron-transport layer 114 includes a substance having an electron-transport property. The substance having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having an azole skeleton, an organic compound including a heteroaromatic ring having a pyridine skeleton, an organic compound including a heteroaromatic ring having a diazine skeleton, and an organic compound including a heteroaromatic ring having a triazine skeleton.

As the substance having an electron-transport property that can be used for the electron-transport layer 114, any of the aforementioned organic compounds that can be given as the substance having an electron-transport property in the light-emitting layer 113 can be used. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound including a heteroaromatic ring having a diazine (pyrimidine or pyrazine) skeleton and the organic compound including a heteroaromatic ring having a triazine skeleton have a high electron-transport property and contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of its high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a lower HOMO level than a material included in the light-emitting layer 113 by 0.5 eV or more.

A layer that includes a compound or a complex of an alkali metal or an alkaline earth metal such as 8-hydroxyquinolinato-lithium (abbreviation: Liq), 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. As the electron-injection layer 115, an alkali metal, an alkaline earth metal, or a compound thereof may be included in a layer formed using a substance having an electron-transport property.

Instead of the electron-injection layer 115, a charge-generation layer 116 may be provided (FIG. 1C). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film including the above-described acceptor material as a material included in the composite material and a film including a hole-transport material. When a potential is applied to the p-type layer 117, electrons are injected into the electron-transport layer 114 and holes are injected into the cathode; thus, the light-emitting device operates.

Note that the charge-generation layer 116 preferably includes one or both of an electron-relay layer 118 and an electron-injection buffer layer 119 in addition to the p-type layer 117.

The electron-relay layer 118 includes at least the substance having an electron-transport property and has a function of preventing an interaction between the electron-injection buffer layer 119 and the p-type layer 117 and smoothly transferring electrons. The LUMO level of the substance having an electron-transport property included in the electron-relay layer 118 is preferably positioned between the LUMO level of the acceptor substance in the p-type layer 117 and the LUMO level of a substance included in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case an increase in driving voltage can be suppressed. Note that as the substance having an electron-transport property in the electron-relay layer 118, a phthalocyanine-based material or a metal complex having a metal-oxygen bond and an aromatic ligand is preferably used.

Specific examples of the substance having an electron-transport property in the electron-relay layer 118 include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀—Iₕ)[5,6]fullerene (abbreviation: C₆₀), and (C₇₀-D₅ₕ)[5,6]fullerene (abbreviation: C₇₀). It is also possible to use a compound including a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine including copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The electron-injection buffer layer 119 is preferably formed using a substance having a high electron-injection property such as a metal or metal compound, in particular, an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 includes a substance having an electron-transport property and a donor substance, the donor substance can be an organic compound such as tetrathianaphthacene (abbreviation: TTN), nickelocene or decamethylnickelocene, as well as a metal or metal compound, in particular, an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Groups 1 and 2 of the periodic table, such as alkali metals (e.g., lithium (Li) and cesium (Cs)), magnesium (Mg), calcium (Ca), and strontium (Sr), alloys including these elements (e.g., MgAg and AlLi), compounds including these elements (e.g., lithium fluoride (LiF), cesium fluoride (CsF), and calcium fluoride (CaF₂)), rare earth metals such as europium (Eu) and ytterbium (Yb), and alloys including these rare earth metals. However, when the electron-injection layer 115 or a thin film formed using any of the above materials having a low work function is provided between the second electrode 102 and the electron-transport layer, a variety of conductive materials such as Al, Ag, ITO, and indium oxide-tin oxide including silicon or silicon oxide can be used for the cathode regardless of the work function.

Note that in one embodiment of the present invention, when the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different deposition methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 2. This light-emitting device includes a plurality of light-emitting units between an anode and a cathode. One light-emitting unit has substantially the same structure as the organic compound layer 103 illustrated in FIG. 1A. In other words, the light-emitting device illustrated in FIG. 2 includes a plurality of light-emitting units, and the light-emitting device illustrated in FIG. 1A to 1C includes a single light-emitting unit.

In FIG. 2, a first light-emitting unit 511 and a second light-emitting unit 512 are stacked between a first electrode 501 and a second electrode 502, and an intermediate layer 513 is provided between the first light-emitting unit 511 and the second light-emitting unit 512. The first electrode 501 and the second electrode 502 respectively correspond to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The intermediate layer 513 has a function of injecting electrons into one of the light-emitting units and injecting holes into the other of the light-emitting units when voltage is applied between the first electrode 501 and the second electrode 502. That is, in FIG. 2, the intermediate layer 513 injects electrons into the first light-emitting unit 511 and holes into the second light-emitting unit 512 when voltage is applied such that the potential of the anode becomes higher than the potential of the cathode.

The intermediate layer 513 preferably has a structure similar to that of the charge-generation layer 116 described with reference to FIG. 1C. A composite material of an organic compound and a metal oxide enables low-voltage driving and low-current driving because of having an excellent carrier-injection property and an excellent carrier-transport property. In the case where the anode-side surface of a light-emitting unit is in contact with the intermediate layer 513, the intermediate layer 513 can also function as a hole-injection layer of the light-emitting unit; therefore, a hole-injection layer is not necessarily provided in the light-emitting unit.

In the case where the electron-injection buffer layer 119 is provided in the intermediate layer 513, the electron-injection buffer layer 119 functions as the electron-injection layer in the light-emitting unit on the anode side; thus, an electron-injection layer is not necessarily formed in the light-emitting unit on the anode side.

The light-emitting device having two light-emitting units is described with reference to FIG. 2; however, one embodiment of the present invention can also be applied to a light-emitting device in which three or more light-emitting units are stacked. With a plurality of light-emitting units partitioned by the intermediate layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided. In that case, it is further preferable that the first light-emitting unit and the second light-emitting unit emit light of the same hue.

When the emission colors of the light-emitting units are of different hues, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The organic compound layer 103, the first light-emitting unit 511, the second light-emitting unit 512, the layers such as the intermediate layer, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

### Embodiment 3

In this embodiment, a display device manufactured using the light-emitting device described in Embodiments 1 and 2 will be described with reference to FIGS. 3A and 3B. FIG. 3A is a top view of the display device and FIG. 3B is a cross-sectional view taken along the lines A-B and C-D in FIG. 3A. This display device includes a driver circuit portion (source line driver circuit) 601, a pixel portion 602, and a driver circuit portion (gate line driver circuit) 603, which are to control light emission of a light-emitting device and illustrated with dotted lines. Reference numeral 604 denotes a sealing substrate, reference numeral 605 denotes a sealing material; and reference numeral 607 denotes a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display device in this specification includes, in its category, not only the display device itself but also the display device provided with the FPC or the PWB.

Next, a cross-sectional structure is described with reference to FIG. 3B. The driver circuit portions and the pixel portion are formed over an element substrate 610; FIG. 3B illustrates the source line driver circuit 601, which is a driver circuit portion, and one pixel in the pixel portion 602.

The element substrate 610 may be a substrate including glass, quartz, an organic resin, a metal, an alloy, or a semiconductor or a plastic substrate formed of fiber reinforced plastic (FRP), polyvinyl fluoride (PVF), polyester, or an acrylic resin, for example.

The structure of transistors used in pixels and driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor including at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably includes at least indium (In) or zinc (Zn). Further preferably, the oxide semiconductor includes an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image in each display region is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film may be omitted if not needed.

Note that an FET 623 is described as a transistor formed in the driver circuit portion 601. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and the driver circuit can be formed outside, not over the substrate.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

An insulator 614 is formed to cover an end portion of the first electrode 613. Here, the insulator 614 can be formed using a positive photosensitive acrylic resin film.

In order to improve coverage with an organic compound layer or the like formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film including silicon, an indium oxide film including zinc oxide at 2 wt % to 20 wt %, a titanium nitride film, a chromium film, a tungsten film, a Zn film, a Pt film, or the like, a stack of a titanium nitride film and a film including aluminum as its main component, a stack of three layers of a titanium nitride film, a film including aluminum as its main component, and a titanium nitride film, or the like can be used. The stacked-layer structure enables low wiring resistance, favorable ohmic contact, and a function as an anode.

The organic compound layer 616 is formed by any of a variety of methods such as an evaporation method using an evaporation mask, an ink-jet method, and a spin coating method. The organic compound layer 616 has the structure described in Embodiments 1 and 2. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thinned metal film and a transparent conductive film (e.g., ITO, indium oxide including zinc oxide at 2 wt % to 20 wt %, indium tin oxide including silicon, or zinc oxide (ZnO)) is preferably used for the second electrode 617.

The light-emitting device is formed with the first electrode 613, the organic compound layer 616, and the second electrode 617. The light-emitting device is the light-emitting device described in Embodiments 1 and 2. Note that in the display device of this embodiment, the pixel portion, which includes a plurality of light-emitting devices, may include both the light-emitting device described in Embodiments 1 and 2 and a light-emitting device having another structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler, and may be filled with an inert gas (such as nitrogen or argon) or the sealing material. In a preferable structure, a concave portion is formed in the sealing substrate and a desiccant is provided in the concave portion, in which case deterioration due to the influence of moisture can be inhibited.

An epoxy resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, or an acrylic resin can be used.

Although not illustrated in FIGS. 3A and 3B, a protective film may be provided over the second electrode. As the protective film, an organic resin film or an inorganic insulating film may be formed. The protective film may be formed to cover an exposed portion of the sealing material 605. The protective film may be provided to cover surfaces and side surfaces of the pair of substrates and exposed side surfaces of a sealing layer, an insulating layer, and the like.

The protective film can be formed using a material that is less permeable to an impurity such as water. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may include aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride including titanium and aluminum, an oxide including titanium and aluminum, an oxide including aluminum and zinc, a sulfide including manganese and zinc, a sulfide including cerium and strontium, an oxide including erbium and aluminum, an oxide including yttrium and zirconium, or the like.

The protective film is preferably formed by a film formation method that offers good step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display device manufactured using the light-emitting device described in Embodiments 1 and 2 can be obtained.

The display device in this embodiment is manufactured using the light-emitting device described in Embodiments 1 and 2 and thus can have excellent characteristics. Specifically, since the light-emitting device described in Embodiments 1 and 2 has high emission efficiency, the display device can achieve low power consumption. Since the light-emitting device described in Embodiments 1 and 2 has high reliability, the display device can be highly reliable.

This embodiment can be freely combined with any of the other embodiments.

### Embodiment 4

As illustrated in FIGS. 4A and 4B, a plurality of light-emitting devices 130 are formed over an insulating layer 175 to constitute a part of a display device. In this embodiment, the display device of another embodiment of the present invention will be described in detail.

A display device 100 includes a pixel portion 177 in which a plurality of pixels 178 are arranged in a matrix. The pixels 178 each include a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted from the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and Y, and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 4A illustrates an example in which subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. In the case where the region 141 is provided, the region 141 is provided between the pixel portion 177 and the connection portion 140. In the case where the region 141 is provided, the organic compound layer 103 is provided in the region 141. A conductive layer 151C is provided in the connection portion 140.

Although FIG. 4A illustrates an example in which the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 4B is an example of a cross-sectional view along the dashed-dotted line A1-A2 in FIG. 4A. As illustrated in FIG. 4B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. The cap layer 155 is provided to cover the light-emitting device 130. A substrate 120 is bonded to the cap layer 155 with a resin layer 122. An inorganic insulating layer 125 and an insulating layer 127 over the inorganic insulating layer 125 are preferably provided between the adjacent light-emitting devices 130.

Although each of the inorganic insulating layer 125 and the insulating layer 127 looks like a plurality of layers in the cross-sectional view in FIG. 4B, each of the inorganic insulating layer 125 and the insulating layer 127 is preferably one continuous layer when the display device 100 is seen from above.

In FIG. 4B, a light-emitting device 130R, a light-emitting device 130G, and a light-emitting device 130B are illustrated as the light-emitting devices 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R includes a first electrode (pixel electrode) 101R including a conductive layer 151R and a conductive layer 152R, an organic compound layer 103R over the first electrode, a common layer 104 over the organic compound layer 103R, and the second electrode (common electrode) 102 over the common layer. Although the common layer 104 is not necessarily provided, it is preferable to provide the common layer 104 to reduce damage to the organic compound layer 103R during processing.

The light-emitting device 130G includes a first electrode (pixel electrode) 101G including a conductive layer 151G and a conductive layer 152G, an organic compound layer 103G over the first electrode, the common layer 104 over the organic compound layer 103G, and the second electrode (common electrode) 102 over the common layer. Although the common layer 104 is not necessarily provided, it is preferable to provide the common layer 104 to reduce damage to the organic compound layer 103G during processing.

The light-emitting device 130B has a structure as described in Embodiments 1 and 2. The light-emitting device 130B includes a first electrode (pixel electrode) 101B including a conductive layer 151B and a conductive layer 152B, an organic compound layer 103B over the first electrode, the common layer 104 over the organic compound layer 103B, and the second electrode (common electrode) 102 over the common layer. Although the common layer 104 is not necessarily provided, it is preferable to provide the common layer 104 to reduce damage to the organic compound layer 103B during processing.

Note that the common layer 104 is preferably an electron-injection layer or an electron-transport layer, further preferably an electron-injection layer. In the case of an electron-transport layer, the electron-transport layer preferably has a stacked-layer structure. It is further preferable that a layer on the second electrode side among the stacked layers be the common layer 104 and a layer on the light-emitting layer side among the stacked layers be the organic compound layer 103.

Since the light-emitting device 130R and the light-emitting device 130G are manufactured through a photolithography process, the above structure can inhibit an increase in driving voltage due to the photolithography process so that the light-emitting devices can have low driving voltage.

In the light-emitting device 130, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis or on an emission color basis. Providing the island-shaped organic compound layer 103 in each of the light-emitting devices 130 can suppress leakage current between the adjacent light-emitting devices 130 even in a high-resolution display device. This can prevent crosstalk, so that a display device with extremely high contrast can be obtained. Specifically, a display device having high current efficiency at low luminance can be manufactured.

The island-shaped organic compound layer 103 is formed by forming an EL film and processing the EL film by a photolithography method.

The organic compound layer 103 is preferably provided to cover the top surface and the side surface of the first electrode (pixel electrode) of the light-emitting device 130. In that case, the aperture ratio of the display device 100 can be easily increased as compared to the structure in which an end portion of the organic compound layer 103 is positioned inward from an end portion of the pixel electrode. Covering the side surface of the pixel electrode of the light-emitting device 130 with the organic compound layer 103 can inhibit the pixel electrode from being in contact with the second electrode 102; hence, a short circuit of the light-emitting device 130 can be inhibited.

In the display device of one embodiment of the present invention, the first electrode (pixel electrode) of the light-emitting device preferably has a stacked-layer structure. For example, in the example illustrated in FIG. 4B, the first electrode of the light-emitting device 130 is a stack of the conductive layer 151 and the conductive layer 152.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy including an appropriate combination of any of these metals, for example.

For the conductive layer 152, an oxide including one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide including gallium, titanium oxide, indium zinc oxide including gallium, indium zinc oxide including aluminum, indium tin oxide including silicon, indium zinc oxide including silicon, and the like. In particular, indium tin oxide including silicon can be suitably used for the conductive layer 152 because of having a work function higher than or equal to 4.0 eV, for example.

The conductive layer 151 and the conductive layer 152 may each be a stack of a plurality of layers including different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that the conductive layer 151 preferably has a tapered side surface. Specifically, the side surface of the conductive layer 151 preferably has a tapered shape with a taper angle less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

Next, an exemplary method for manufacturing the display device 100 having the structure illustrated in FIG. 4A is described with reference to FIGS. 5A to 5E, FIGS. 6A and 6B, FIGS. 7A to 7D, FIGS. 8A to 8C, FIGS. 9A to 9C, and FIGS. 10A to 10C.

### Manufacturing Method Example 1

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used.

For etching of thin films, a dry etching method, a wet etching method, a sandblast method, or the like can be used.

First, as illustrated in FIG. 5A, the insulating layer 171 is formed over a substrate (not illustrated). Next, the conductive layer 172 and a conductive layer 179 are formed over the insulating layer 171, and the insulating layer 173 is formed over the insulating layer 171 to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, openings reaching the conductive layer 172 are formed in the insulating layers 175, 174, and 173. Then, the plugs 176 are formed to fill the openings.

Next, a conductive film 151f to be the conductive layers 151R, 151G, 151B, and 151C are formed over the plugs 176 and the insulating layer 175. A metal material can be used for the conductive film 151f, for example.

Then, a resist mask 191 is formed over the conductive film 151f. The resist mask 191 can be formed by application of a photosensitive material (photoresist), light exposure, and development.

Subsequently, as illustrated in FIG. 5B, the conductive film 151f in a region not overlapping with the resist mask 191 is removed, for example. In this manner, the conductive layer 151 is formed.

Next, the resist mask 191 is removed as illustrated in FIG. 5C. The resist mask 191 can be removed by ashing using oxygen plasma, for example.

Then, as illustrated in FIG. 5D, an insulating film 156f to be an insulating layer 156R, an insulating layer 156G, an insulating layer 156B, and an insulating layer 156C is formed over the conductive layers 151R, 151G, 151B, and 151C and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 5E, the insulating film 156f is processed to form the insulating layers 156R, 156G, 156B, and 156C.

Subsequently, as illustrated in FIG. 6A, an EL film 103Rf is formed over the conductive layers 152R, 152G, and 152B and the insulating layer 175. Note that as illustrated in FIG. 6A, the EL film 103Rf is not formed over an conductive layer 152C.

Then, as illustrated in FIG. 6A, a sacrificial film 158Rf and a mask film 159Rf are formed.

Providing the sacrificial film 158Rf over the EL film 103Rf can reduce damage to the EL film 103Rf in the manufacturing process of the display device, resulting in an increase in the reliability of the light-emitting device.

As the sacrificial film 158Rf, a film that is highly resistant to the process conditions for the EL film 103Rf, specifically, a film having high etching selectivity with respect to the EL film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the EL film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., yet still further preferably lower than or equal to 80° C.

The sacrificial film 158Rf and the mask film 159Rf are preferably films that can be removed by a wet etching method.

Note that the sacrificial film 158Rf that is formed over and in contact with the EL film 103Rf is preferably formed by a formation method that is less likely to damage the EL film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. It is preferable to use a metal material that can block ultraviolet rays for one or both of the sacrificial film 158Rf and the mask film 159Rf, in which case the EL film 103Rf can be inhibited from being irradiated with ultraviolet rays and thus deterioration of the EL film 103Rf can be inhibited.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process, for example. Alternatively, a compound including any of the above semiconductor materials can be used.

As each of the sacrificial film 158Rf and the mask film 159Rf, any of a variety of inorganic insulating films can be used. In particular, an oxide insulating film is preferable because its adhesion to the EL film 103Rf is higher than that of a nitride insulating film.

Subsequently, a resist mask 190R is formed as illustrated in FIG. 6A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged in the process of manufacturing the display device.

Next, as illustrated in FIG. 6B, a part of the mask film 159Rf is removed using the resist mask 190R, whereby a mask layer 159R is formed. The mask layer 159R remains over the conductive layers 152R and 152C. After that, the resist mask 190R is removed. Then, a part of the sacrificial film 158Rf is removed using the mask layer 159R as a mask (also referred to as a hard mask), whereby a sacrificial layer 158R is formed.

The use of a wet etching method can reduce damage to the EL film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution including a mixed solution of any of these acids, for example.

In the case of using a dry etching method to process the sacrificial film 158Rf, deterioration of the EL film 103Rf can be inhibited by not using a gas including oxygen as the etching gas.

The resist mask 190R can be removed by a method similar to that for the resist mask 191.

Next, as illustrated in FIG. 6B, the EL film 103Rf is processed to form the organic compound layer 103R. For example, a part of the EL film 103Rf is removed using the mask layer 159R and the sacrificial layer 158R as a hard mask, whereby the organic compound layer 103R is formed.

Accordingly, as illustrated in FIG. 6B, the stacked-layer structure of the organic compound layer 103R, the sacrificial layer 158R, and the mask layer 159R remains over the conductive layer 152R. The conductive layers 152G and 152B are exposed.

The EL film 103Rf is preferably processed by anisotropic etching. Anisotropic dry etching is particularly preferable. Alternatively, wet etching may be used.

In the case of using a dry etching method, deterioration of the EL film 103Rf can be inhibited by not using a gas including oxygen as the etching gas.

A gas including oxygen may be used as the etching gas. When the etching gas includes oxygen, the etching rate can be increased. Thus, the etching can be performed under a low-power condition while an adequately high etching rate is maintained. Accordingly, damage to the EL film 103Rf can be reduced. Furthermore, a defect such as attachment of a reaction product generated during the etching can be inhibited.

In the case of using a dry etching method, it is preferable to use a gas including at least one of H₂, CF₄, C₄F8, SF₆, CHF₃, Cl₂, H₂O, BCl₃, and a Group 18 element such as He or Ar as the etching gas, for example. Alternatively, a gas including oxygen and at least one of the above is preferably used as the etching gas. Alternatively, an oxygen gas may be used as the etching gas.

Then, as illustrated in FIG. 7A, an EL film 103Gf to be the organic compound layer 103G is formed.

The EL film 103Gf can be formed by a method similar to that for forming the EL film 103Rf. The EL film 103Gf can have a structure similar to that of the EL film 103Rf.

Subsequently, a sacrificial film 158Gf and a mask film 159Gf are formed in this order. After that, a resist mask 190G is formed at a position overlapping with the conductive layer 152G. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

Subsequently, as illustrated in FIG. 7B, a part of the mask film 159Gf is removed using the resist mask 190G, whereby a mask layer 159G is formed. The mask layer 159G remains over the conductive layer 152G. After that, the resist mask 190G is removed. Then, a part of the sacrificial film 158Gf is removed using the mask layer 159G as a mask, whereby a sacrificial layer 158G is formed. Next, the EL film 103Gf is processed to form the organic compound layer 103G.

Then, an EL film 103Bf is formed as illustrated in FIG. 7C. The EL film 103Bf can be formed by a method similar to that for forming the EL film 103Rf. The EL film 103Bf can have a structure similar to that of the EL film 103Rf.

Subsequently, a sacrificial film 158Bf and a mask film 159Bf are formed in this order as illustrated in FIG. 7C. After that, a resist mask 190B is formed at a position overlapping with the conductive layer 152B. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

Subsequently, as illustrated in FIG. 7D, a part of the mask film 159Bf is removed using the resist mask 190B, whereby a mask layer 159B is formed. The mask layer 159B remains over the conductive layer 152B. After that, the resist mask 190B is removed. Then, a part of the sacrificial film 158Bf is removed using the mask layer 159B as a mask, whereby a sacrificial layer 158B is formed. Next, the EL film 103Bf is processed to form the organic compound layer 103B. For example, a part of the EL film 103Bf is removed using the mask layer 159B and the sacrificial layer 158B as a hard mask, whereby the organic compound layer 103B is formed.

Accordingly, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angles between the formation surfaces and these side surfaces are preferably greater than or equal to 60° and less than or equal to 90°.

The distance between two adjacent layers among the organic compound layers 103R, 103G, and 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by a distance between opposite end portions of two adjacent layers among the organic compound layers 103R, 103G, and 103B. Reducing the distance between the island-shaped organic compound layers makes it possible to provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, less than or equal to 2 μm, or less than or equal to 1 μm. For example, with the use of a light exposure apparatus for LSI devices, the distance can be reduced to be less than or equal to 500 nm, less than or equal to 200 nm, less than or equal to 100 nm, or even less than or equal to 50 nm.

Next, as illustrated in FIG. 8A, the mask layers 159R, 159G, and 159B are preferably removed.

The step of removing the mask layers can be performed by a method similar to that for the step of processing the mask films. Specifically, by using a wet etching method, damage to the organic compound layer 103 at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 8B.

Then, as illustrated in FIG. 8C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to deposition is reduced and a film with good coverage can be deposited. As the inorganic insulating film 125f, an aluminum oxide film is preferably formed by an ALD method, for example.

The insulating film 127f is preferably formed by the aforementioned wet process. The insulating film 127f is preferably formed by spin coating using a photosensitive material, for example, and specifically preferably formed using a photosensitive resin composition including an acrylic resin.

Then, a part of the insulating film 127f is exposed to visible light or ultraviolet rays. The insulating layer 127 is formed in regions that are interposed between any two of the conductive layers 152R, 152G, and 152B and around the conductive layer 152C.

The width of the insulating layer 127 formed later can be controlled with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

Next, as illustrated in FIG. 9A, development is performed to remove the region of the insulating film 127f exposed to light, whereby an insulating layer 127a is formed.

Next, as illustrated in FIG. 9B, etching treatment is performed using the insulating layer 127a as a mask to remove a part of the inorganic insulating film 125f and reduce the thicknesses of parts of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed at one time.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layers 103R, 103G, and 103B, as compared to the case of using a dry etching method. Wet etching can be performed using, for example, an alkaline solution or an acidic solution.

It is preferable that the sacrificial layers 158R, 158G, and 158B be not completely removed by the first etching treatment, and the etching treatment be stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) is provided as each of the sacrificial layers 158R, 158G, and 158B, diffusion of oxygen to the organic compound layers 103R, 103G, and 103B can be inhibited.

Then, heat treatment (also referred to as post-baking) is performed. The heat treatment can change the insulating layer 127a into the insulating layer 127 having a tapered side surface (FIG. 9C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

Next, as illustrated in FIG. 10A, etching treatment is performed using the insulating layer 127 as a mask to partly remove the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 10A illustrates an example in which a part of the end portion of the sacrificial layer 158G (specifically a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layers 103R, 103G, and 103B, as compared to the case of using a dry etching method. Wet etching can be performed using an alkaline solution or an acidic solution, for example.

Next, as illustrated in FIG. 10B, the second electrode (common electrode) 102 is formed over the organic compound layers 103R, 103G, and 103B, the conductive layer 152C, and the insulating layer 127. The second electrode (common electrode) 102 can be formed by a sputtering method, a vacuum evaporation method, or the like.

Next, as illustrated in FIG. 10C, the cap layer 155 is formed over the second electrode (common electrode) 102. The cap layer 155 can be formed by a vacuum evaporation method, a sputtering method, a CVD method, an ALD method, or the like.

Then, the substrate 120 is bonded to the cap layer 155 using the resin layer 122, so that the display device can be manufactured. In the method for manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device in this embodiment, the island-shaped organic compound layers 103R, 103G, and 103B are formed not by using a fine metal mask but by depositing a film on the entire surface and processing it by a photolithography method; thus, the island-shaped layers can be formed to have a uniform thickness. A display device with high resolution or a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices manufactured by a photolithography method can have excellent characteristics.

### Embodiment 5

In this embodiment, a display device of one embodiment of the present invention will be described.

The display device in this embodiment can be a display device having high resolution. Thus, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game machine, a portable information terminal, and an audio reproducing device, in addition to display portions of electronic appliances with a relatively large screen, such as a television device, desktop and laptop personal computers, a monitor of a computer and the like, digital signage, and a large game machine such as a pachinko machine.

### [Display Module]

FIG. 11A is a perspective view of a display module 280. The display module 280 includes a display device 100A and an FPC 290. Note that the display device included in the display module 280 is not limited to the display device 100A and may be any of a display device 100B, a display device 100C, a display device 100D, a display device 100D2, a display device 100E, and a display device 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 11B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

The display device 100A illustrated in FIG. 12A includes a substrate 301, the light-emitting devices 130R, 130G, and 130B, a capacitor 240, and a transistor 310.

The substrate 301 corresponds to the substrate 291 in FIGS. 11A and 11B. The transistor 310 includes a channel formation region in the substrate 301. As the substrate 301, a semiconductor substrate such as a single crystal silicon substrate can be used, for example. The transistor 310 includes a part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The cap layer 155 is provided over the light-emitting devices 130R, 130G, and 130B. The substrate 120 is bonded to the cap layer 155 with the resin layer 122. Embodiment 4 can be referred to for the details of the light-emitting device 130 and the components thereover up to the substrate 120. The substrate 120 corresponds to the substrate 292 in FIG. 11A.

FIG. 12B illustrates a variation example of the display device 100A illustrated in FIG. 12A. The display device illustrated in FIG. 12B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 12B, the light-emitting device 130 can emit white light, for example. The coloring layer 132R, the coloring layer 132G, and the coloring layer 132B can transmit red light, green light, and blue light, respectively, for example.

### [Display Device 100B]

FIG. 13 is a perspective view of the display device 100B, and FIG. 14 is a cross-sectional view of the display device 100C.

In the display device 100B, a substrate 352 and a substrate 351 are bonded to each other. In FIG. 13, the substrate 352 is denoted by a dashed line.

The display device 100B includes the pixel portion 177, the connection portion 140, a circuit 356, a wiring 355, and the like. FIG. 13 illustrates an example in which an IC 354 and an FPC 353 are mounted on the display device 100B. Thus, the structure illustrated in FIG. 13 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and electric power to the pixel portion 177 and the circuit 356. The signal and power are input to the wiring 355 from the outside through the FPC 353 or from the IC 354.

FIG. 13 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module may have a structure not including an IC. Alternatively, the IC may be mounted on the FPC by a COF method, for example.

FIG. 14 illustrates, as the display device 100C, an example of cross sections of a part of a region including the FPC 353, a part of the circuit 356, a part of the pixel portion 177, a part of the connection portion 140, and a part of a region including an end portion of the display device 100B in FIG. 13.

### [Display Device 100C]

The display device 100C illustrated in FIG. 14 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a concave portion covering an opening provided in the insulating layer 214. A layer 128 is embedded in the concave portion.

The layer 128 has a function of filling the concave portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the concave portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The cap layer 155 is provided over the light-emitting devices 130R, 130G, and 130B. The cap layer 155 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 14, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 14 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 14, the insulating layer 156C is provided to include a region overlapping with the side surface of the conductive layer 151C.

The display device 100C has a top-emission structure. Light from the light-emitting device is emitted toward the substrate 352. For the substrate 352, a material having a high visible-light-transmitting property is preferably used. The pixel electrode includes a material that reflects visible light, and a counter electrode (a common electrode) includes a material that transmits visible light.

An insulating layer 211, an insulating layer 213, an insulating layer 215, and the insulating layer 214 are provided in this order over the substrate 351. A part of the insulating layer 211 functions as a gate insulating layer of each transistor. A part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 that does not overlap with the substrate 352. In the connection portion 204, the source electrode or the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, and in the circuit 356, for example. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

The display device 100D illustrated in FIG. 15 differs from the display device 100C illustrated in FIG. 14 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 15 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 15, the light-emitting device 130G is also provided.

Although FIG. 15 and the like illustrate an example in which the top surface of the layer 128 includes a flat portion, the shape of the layer 128 is not particularly limited.

### [Display Device 100D2]

The display device 100D2 illustrated in FIG. 16A is an example of a bottom-emission display device different from the display device 100D illustrated in FIG. 15. The display device 100D2 is different from the display device 100D in that an organic resin layer 180 is included. Note that the reference numerals of the components that are the same as those in FIG. 15 are sometimes omitted and the description for FIG. 15 is referred to for the details of such components.

FIG. 16B is a top-view layout of the pixels 178 (a pixel 178a and a pixel 178b) each including the subpixels 110 (the subpixels 110R, 110G, 110B, and 110W), and FIG. 16C is a top view of the organic resin layer 180 in a region where the subpixels 110R and 110G of the pixel 178 are formed. Note that the width between the light-blocking layer 317 and another light-blocking layer 317 corresponds to a width 110Rw in the light-emitting region of the subpixel 110R.

As illustrated in FIG. 16A, the organic resin layer 180 is provided over the insulating layer 214. As illustrated in FIG. 16C and the region surrounded by the dashed-dotted line in FIG. 16A, the organic resin layer 180 includes concave portions 181 (concave portions 181a and concave portions 181b) each having a curved surface, at least in a region where the subpixels are formed. Note that the concave portion 181 may be provided outside the light-emitting region, like a concave portion 181c. When the concave portion 181c is provided, light that has been emitted in a region overlapping with the light-blocking layer 317 or light that has progressed to the region overlapping with the light-blocking layer 317 can be refracted and extracted from the light-emitting region, which results in an increase in the emission efficiency.

A plurality of the concave portions 181 may be formed in a matrix. The concave portion 181a and the concave portion 181b may be provided in contact with each other or may have a flat surface therebetween.

Although the top-view shape and the cross-sectional shape of the concave portion are hexagonal (FIG. 16C) and semicircular (FIG. 16A), respectively, other shapes may be employed as needed. Examples of a top surface shape of the concave portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For the organic resin layer 180, for example, a resin that can be used as a color filter transmitting red, blue, or green light and absorbing light of the other colors or a resin that include carbon black as a pigment and functions as a black matrix can be used.

The first electrodes 101 (the first electrode 101R and a first electrode 101W) are provided over the organic resin layer 180, and the organic compound layer 103 is provided over the first electrodes 101. End portions of the first electrodes 101 and the organic compound layer 103 may be covered with the insulating layer 127.

The first electrode 101 formed over the organic resin layer 180 also has a similar concave portion along the concave portion of the organic resin layer 180. Furthermore, the organic compound layer 103 formed over the first electrode 101 also has a similar concave portion along the concave portion of the first electrode 101. Furthermore, the common layer 104 formed over the organic compound layer 103 also has a similar concave portion along the concave portion of the organic compound layer 103. Furthermore, the second electrode 102 formed over the common layer 104 also has a similar concave portion along the concave portion of the common layer 104. That is, the concave portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The cap layer 155 is provided over the second electrode 102, and the substrate 352 is bonded thereto with the adhesive layer 142.

Although the light-emitting devices 130G and 130B are not illustrated in FIG. 16A, the light-emitting devices 130G and 130B are also provided.

With the above-described light-emitting apparatus of one embodiment of the present invention, an organic semiconductor device having high emission efficiency can be provided; thus, an organic semiconductor device having high reliability, low driving voltage, and low power consumption can be provided.

### [Display Device 100E]

The display device 100E illustrated in FIG. 17 is a variation example of the display device 100C illustrated in FIG. 14 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on the surface of the substrate 352 on the substrate 351 side. End portions of the coloring layers 132R, 132G, and 132B can overlap with the light-blocking layer 157.

In the display device 100E, for example, the light-emitting device 130 can emit white light. For example, the coloring layer 132R, the coloring layer 132G, and the coloring layer 132B can transmit red light, green light, and blue light, respectively. Note that in the display device 100E, the coloring layers 132R, 132G, and 132B may be provided between the cap layer 155 and the adhesive layer 142.

### [Display Device 100E2]

The display device 100E2 illustrated in FIG. 18A is a variation example of the display device 100E illustrated in FIG. 17 and includes microlenses 182 over the coloring layers 132R, 132G, and 132B. Note that the reference numerals of the components that are the same as those in FIG. 17 are sometimes omitted and the description for FIG. 17 is referred to for the details of such components.

FIG. 18B is a top-view layout of the pixels 178 (the pixels 178a and 178b) each including the subpixels 110 (the subpixels 110R, 110G, and 110B), and FIG. 18C is a top view of the microlenses 182 in a region where the subpixels 110R and 110G included in the pixel 178 are formed. Note that the width of a region where the common electrode and the organic compound layer 103 are in contact with each other corresponds to a width 110Gw of a light-emitting region of the subpixel 110G.

In the display device 100E2 illustrated in FIG. 18A, a planarization film 143 is provided over the cap layer 155, and the coloring layers 132R, 132G, and 132B are provided over the planarization film 143. A planarization film 144 is provided to cover the coloring layers 132R, 132G, and 132B. The microlenses 182 are provided over the planarization film 144.

As illustrated in FIG. 18C, the microlenses 182 are provided on a subpixel basis in the region where the subpixels are formed.

Although the top surface shape of the microlens 182 is hexagonal in FIG. 18C, a different shape may be employed as needed. Examples of the top-view shape of the microlens 182 include polygons such as a triangle, a tetragon (including a rectangle and a square), and a pentagon; these polygons with rounded corners; an ellipse; and a circle.

The microlenses 182 can be formed using a material similar to that of the organic resin layer 180.

The light-emitting apparatus of one embodiment of the present invention including the above-described microlens 182 includes the cap layer as described in Embodiment 1, whereby an organic semiconductor device having high emission efficiency, high reliability, low driving voltage, and low power consumption, which is suitable for a mobile display, can be provided owing to an indivisible effect of the microlens 182 and the organic semiconductor device including the cap layer.

This embodiment can be combined as appropriate with any of the other embodiments or example. In this specification, in the case where a plurality of structure examples are described in one embodiment, the structure examples can be combined as appropriate.

### Embodiment 6

In this embodiment, electronic appliances of one embodiment of the present invention will be described.

Electronic appliances of this embodiment include the display device of one embodiment of the present invention in their display portions. The display device of one embodiment of the present invention has low power consumption and high reliability. Thus, the display device of one embodiment of the present invention can be used for display portions of a variety of electronic appliances.

Examples of the electronic appliances include a digital camera, a digital video camera, a digital photo frame, a mobile phone, a portable game machine, a portable information terminal, and an audio reproducing device, in addition to electronic appliances with a relatively large screen, such as a television device, desktop and laptop personal computers, a monitor of a computer and the like, digital signage, and a large game machine such as a pachinko machine.

Examples of wearable devices capable of being worn on a head are described with reference to FIGS. 19A to 19D.

An electronic appliance 700A illustrated in FIG. 19A and an electronic appliance 700B illustrated in FIG. 19B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, an electronic appliance having high reliability is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 19C and an electronic appliance 800B illustrated in FIG. 19D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, an electronic appliance having high reliability is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for laterally adjusting the positions of the lenses 832 and the display portions 820 so that the lenses 832 and the display portions 820 are positioned optimally in accordance with the positions of the user's eyes.

The electronic appliance 800A or 800B can be mounted on the user's head with the wearing portions 823.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include earphone portions. The electronic appliance 700B in FIG. 19B includes earphone portions 727. A part of a wiring that connects the earphone portion 727 and the control portion may be positioned inside the housing 721 or the wearing portion 723.

Similarly, the electronic appliance 800B illustrated in FIG. 19D includes earphone portions 827. For example, the earphone portions 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

An electronic appliance 6500 illustrated in FIG. 20A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, an electronic appliance having high reliability is obtained.

FIG. 20B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

A part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be obtained when a part of the display panel 6511 is folded back so that the portion connected to the FPC 6515 is provided on the back side of a pixel portion.

FIG. 20C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, an electron appliance having high reliability is obtained.

The television device 7100 illustrated in FIG. 20C can be operated with an operation switch provided in the housing 7171 and a separate remote control 7151.

FIG. 20D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, an electronic appliance having high reliability is obtained.

FIGS. 20E and 20F illustrate examples of digital signage.

Digital signage 7300 illustrated in FIG. 20E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 20F illustrates digital signage 7400 attached to a cylindrical pillar 7401. The digital signage 7400 includes the display portion 7000 provided along a curved surface of the pillar 7401.

In FIGS. 20E and 20F, the display device of one embodiment of the present invention can be used in the display portion 7000. Thus, an electronic appliance having high reliability is obtained.

A larger area of the display portion 7000 can increase the amount of information that can be provided at a time. The display portion 7000 having a larger area attracts more attention, so that the effectiveness of the advertisement can be increased, for example.

As illustrated in FIGS. 20E and 20F, it is preferable that the digital signage 7300 or the digital signage 7400 be capable of working with an information terminal 7311 or an information terminal 7411, such as a smartphone that a user has, through wireless communication.

Electronic appliances illustrated in FIGS. 21A to 21G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 21A to 21G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances illustrated in FIGS. 21A to 21G are described in detail below.

FIG. 21A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 21A illustrates an example in which three icons 9050 are displayed. Furthermore, information 9051 shown by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 21B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes.

FIG. 21C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 21D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 21E to 21G are perspective views of a foldable portable information terminal 9201. FIG. 21E is a perspective view illustrating the portable information terminal 9201 that is opened. FIG. 21G is a perspective view illustrating the portable information terminal 9201 that is folded. FIG. 21F is a perspective view illustrating the portable information terminal 9201 that is between the states in FIGS. 21E and 21G. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with any of the other embodiments or example. In this specification, in the case where a plurality of structure examples are described in one embodiment, the structure examples can be combined as appropriate.

### Example 1

In this example, manufacturing methods and characteristics of a light-emitting device 1 of one embodiment of the present invention and a comparative light-emitting device 1 will be described in detail. Structural formulas of main compounds used for the light-emitting device 1 and the comparative light-emitting device 1 are shown below.

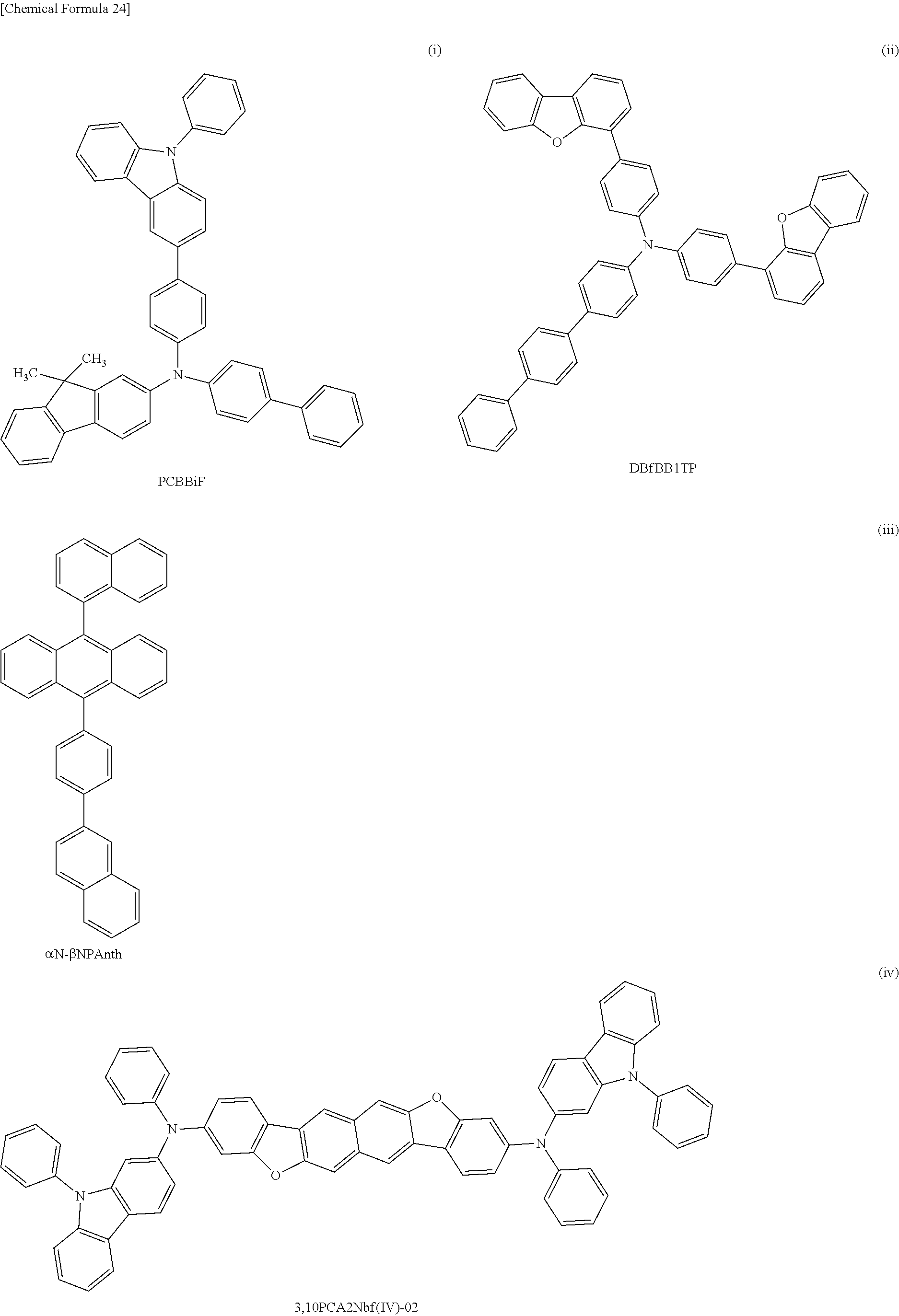

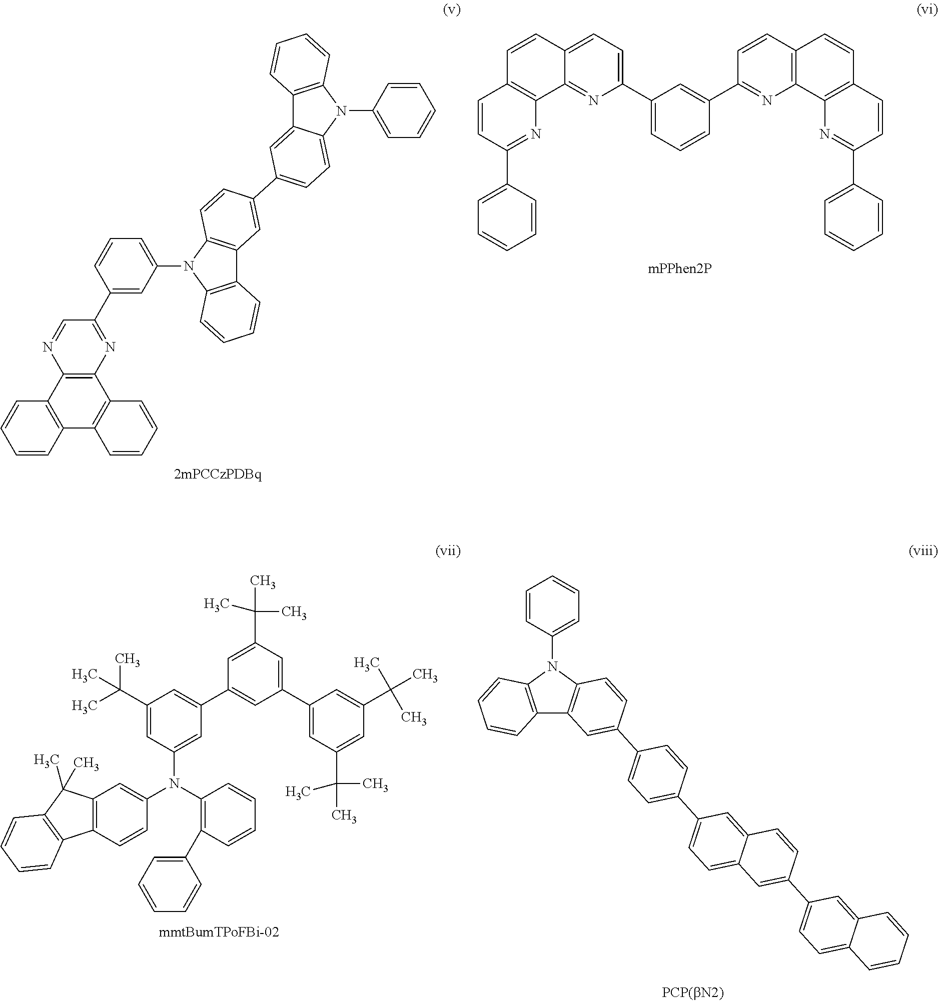 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1cc(-c2cc(N(c3ccc4c(c3)C(C)(C)c3ccccc3-4)c3ccccc3-c3ccccc3)cc(C(C)(C)C)c2)cc(-c2cc(C(C)(C)C)cc(C(C)(C)C)c2)c1 ; c1ccc(-n2c3ccccc3c3cc(-c4ccc(-c5ccc6cc(-c7ccc8ccccc8c7)ccc6c5)cc4)ccc32)cc1]

### (Method for Manufacturing Light-Emitting Device 1)

First, 100-nm-thick silver (Ag) serving as a reflective electrode and 10-nm-thick indium tin oxide including silicon oxide (ITSO) serving as a transparent electrode were stacked sequentially over a glass substrate from the substrate side by a sputtering method, whereby the first electrode 101 with a size of 2 mm×2 mm was formed. Note that the transparent electrode functions as an anode, and the transparent electrode and the reflective electrode are collectively regarded as the first electrode 101.

Next, in pretreatment for forming the light-emitting device over the substrate, the surface of the substrate was washed with water, and baking was performed at 200° C. for one hour.

After that, the substrate was transferred into a vacuum evaporation apparatus where the pressure was reduced to approximately 10′ Pa, and was subjected to vacuum baking at 170° C. for 60 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) and a fluorine-containing electron acceptor material with a molecular weight of 672 (OCHD-003) were deposited by co-evaporation to a thickness of 10 nm at a PCBBiF-to-OCHD-003 weight ratio of 1:0.03, so that the hole-injection layer 111 was formed.

Over the hole-injection layer 111, PCBBiF was deposited by evaporation to a thickness of 102 nm to form a first hole-transport layer, and then N,N-bis[4-(dibenzofuran-4-yl)phenyl]-4-amino-p-terphenyl (abbreviation: DBfBB1TP) represented by Structural Formula (ii) was deposited by evaporation to a thickness of 10 nm to form a second hole-transport layer, so that the hole-transport layer 112 was formed.

Subsequently, over the hole-transport layer 112, 9-(1-naphthyl)-10-[4-(2-naphthyl)phenyl]anthracene (abbreviation: aN-QNPAnth) represented by Structural Formula (iii) and N,N′-diphenyl-N,N′-bis(9-phenyl-9H-carbazol-2-yl)naphtho[2,3-b;6,7-b′]bisbenzofuran-3,10-diamine (abbreviation: 3,1OPCA2Nbf(IV)-02) represented by Structural Formula (iv) were deposited by co-evaporation to a thickness of 25 nm at an aN-QNPAnth-to-3,10PCA2Nbf(IV)-02 weight ratio of 1:0.015, so that the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) was deposited by evaporation to a thickness of 15 nm, and then 2,2′-(1,3-phenylene)bis(9-phenyl-1,10-phenanthroline) (abbreviation: mPPhen2P) represented by Structural Formula (vi) was deposited by evaporation to a thickness of 10 nm, so that the electron-transport layer 114 was formed.

After that, lithium fluoride (LiF) was deposited by evaporation to a thickness of 1 nm to form the electron-injection layer 115, and then silver (Ag) and magnesium (Mg) were deposited by co-evaporation to a thickness of 15 nm at an Ag-to-Mg volume ratio of 1:0.1, so that the second electrode 102 was formed.

After that, over the second electrode 102, N-(biphenyl-2-yl)-N-(3,3″,5′,5″-tetra-tert-butyl-[1,1′: 3′,1″-terphenyl]-5-yl)-9,9-dimethyl-9H-fluoren-2-amine (abbreviation: mmtBumTPoFBi-02) represented by Structural Formula (vii) was deposited by evaporation to a thickness of 10.2 nm, and 3-[4-([2,2′-binaphthalen]-6-yl)phenyl]-9-phenyl-9H-carbazole (abbreviation: PCP(βN2)) represented by Structural Formula (viii) was deposited by evaporation to a thickness of 53.4 nm, so that the cap layer was formed.

Then, the light-emitting device was sealed using a glass substrate in a glove box including a nitrogen atmosphere so as not to be exposed to the air. Specifically, a UV curable sealing material was applied to surround the device, only the sealing material was irradiated with UV such that the light-emitting device was not irradiated with the UV, and heat treatment was performed at 80° C. under an atmospheric pressure for one hour. In this manner, the light-emitting device 1 was manufactured.

### (Method for Manufacturing Comparative Light-Emitting Device 1)

The comparative light-emitting device 1 was formed in a manner similar to that of the light-emitting device 1 except that the hole-transport layer was formed to a thickness of 100 nm and PCP(βN2) was deposited by evaporation to a thickness of 62.8 nm as the cap layer. Note that the thickness of the hole-transport layer was selected so that the chromaticity of the comparative light-emitting device 1 is as close to that of the light-emitting device 1 as possible.

FIG. 22 shows the measurement results of the ordinary refractive indices (n, Ordinary) and the extraordinary refractive indices (n, Extra-ordinary) of mmtBumTPoFBi-02 and PCP(βN2) used for the light-emitting device 1 and the comparative light-emitting device 1 formed in this example. The measurement was performed with an M-2000U spectroscopic ellipsometer (J.A. Woollam Japan). To obtain films used as measurement samples, the material for each layer was deposited to a thickness of approximately 50 nm over a quartz substrate by a vacuum evaporation method.

FIG. 22 confirms that mmtBumTPoFBi-02 included in the first layer 188 of each of the light-emitting device 1 and the comparative light-emitting device 1 is a low refractive index material whose ordinary refractive index at a wavelength of 450 nm is lower than or equal to 1.8, and PCP(βN2) included in the second layer 189 is a high refractive index material whose ordinary refractive index at a wavelength of 450 nm is higher than or equal to 1.9. The difference in refractive index between mmtBumTPoFBi-02 and PCP(βN2) is greater than or equal to 0.1. Note that mmtBumTPoFBi-02 is a monoamine compound having an alkyl group, and PCP(βN2) is an organic compound having a carbazole skeleton.

Device structures of the light-emitting device 1 and the comparative light-emitting device 1 are shown in the following tables.

TABLE 1

| | | | | Comparative |
|---|---|---|---|---|
| | | Film | Light- | light- |
| | | thickness | emitting | emitting |
| | | (nm) | device 1 | device 1 |
| Cap layer | 2 | *3 | PCP(βN2) | — |
| | 1 | *2 | mmtBumTPoFBi-02 | PCP(βN2) |

| Second electrode | | 15 | Ag:Mg (1:0.1) |
|---|---|---|---|
| Electron-injection layer | | 1 | LiF |
| Electron- | 2 | 10 | mPPhen2P |
| transport | 1 | 15 | 2mPCCzPDBq |
| layer | | | |
| Light-emitting layer | | 25 | αN-βNPAnth:3,10PCA2Nbf(IV)- |
| | | | 02 (1:0.015) |
| Hole- | 2 | 10 | DBfBB1TP |
| transport | 1 | *1 | PCBBiF |
| layer | | | |
| Hole-injection layer | | 10 | PCBBiF:OCHD-003 (1:0.03) |
| First | 2 | 10 | ITSO |
| electrode | 1 | 100 | Ag |

TABLE 2

| | | Light- | Comparative |
|---|---|---|---|
| | | emitting | light-emitting |
| | | device 1 | device 1 |
| Film | *3 | 53.4 | — |
| thickness | *2 | 10.2 | 62.8 |
| (nm) | *1 | 102 | 100 |

FIG. 23 shows the luminance-current density characteristics of the light-emitting device 1 and the comparative light-emitting device 1. FIG. 24 shows the current efficiency-luminance characteristics of the light-emitting device 1 and the comparative light-emitting device 1. FIG. 25 shows the luminance-voltage characteristics of the light-emitting device 1 and the comparative light-emitting device 1. FIG. 26 shows the current density-voltage characteristics of the light-emitting device 1 and the comparative light-emitting device 1. FIG. 27 shows the blue index-current density characteristics of the light-emitting device 1 and the comparative light-emitting device 1. FIG. 28 shows the electroluminescence spectra of the light-emitting device 1 and the comparative light-emitting device 1.

The values of the voltage, current, current density, CIE chromaticity, current efficiency, and blue index at an application voltage of 4.40 V are shown below. The luminance, CIE chromaticity, and electroluminescence spectra were measured at normal temperature with a spectroradiometer SR-UL1R (TOPCON TECHNOHOUSE).

Note that the blue index (BI) is a value obtained by dividing current efficiency (cd/A) by the chromaticity y, which is calculated with the CIE1931 color system, and is one of the indicators of characteristics of blue light emission. Blue light emission with a smaller chromaticity y tends to have higher color purity. Blue light emission with high color purity enables a display to express a desired color even with a small number of luminance components. Furthermore, using blue emission with high color purity reduces the required luminance of blue in a display, resulting in lower power consumption. Thus, BI that is based on the chromaticity y, which is one of the indicators of color purity of blue, is used as a means for showing efficiency of blue light emission in some cases. In other words, a higher BI can offer a display with higher blue emission efficiency.

TABLE 3

| | | | Current | | | Current | |
|---|---|---|---|---|---|---|---|
| | Voltage | Current | density | Chromaticity | Chromaticity | efficiency | BI |
| | (V) | (mA) | (mA/cm²) | x | y | (cd/A) | (cd/A/y) |
| Light-emitting | 4.40 | 0.888 | 22.2 | 0.147 | 0.0363 | 3.99 | 110 |
| device 1 | | | | | | | |
| Comparative | 4.40 | 0.860 | 21.5 | 0.148 | 0.0362 | 3.76 | 104 |
| light-emitting | | | | | | | |
| device 1 | | | | | | | |

FIGS. 23 to 28 and Table 3 show that the light-emitting device 1 is a light-emitting element with high color purity. It is also found that with the use of the cap layer made of a stack of materials with different refractive indices, the light-emitting device 1 has higher current efficiency, a higher blue index, and more favorable characteristics than the comparative light-emitting device 1 including a single cap layer.

Described next are the results of examining the deterioration of light-emitting devices that have been preserved at a high temperature (85° C.).

Samples have a structure in which components from the substrate to the second electrode are almost the same as those of the light-emitting device 1 except that the thickness of the first hole-transport layer is 100 nm. After that, the cap layer was formed over the second electrode with a stack of 12.9-nm-thick mmtBumTPoFBi-02 and 48.6-nm-thick PCP(βN2) for a sample 1; a stack of 61.7-nm-thick PCP(βN2) and 1-nm-thick mmtBumTPoFBi-02 for a sample 2; and 61.3-nm-thick PCP(βN2) for a sample 3.

The samples 1 to 3 were preserved at 85° C. for 1000 hours and observed with an optical microscope using a 5× objective lens; the obtained reflected bright-field images are shown in FIG. 29. According to FIG. 29, defective unevenness was observed only in the sample 3, which includes the single cap layer made of an organic compound having a carbazole skeleton, and no defective unevenness was observed in the samples 1 and 2, each of which includes the cap layer made of a monoamine compound having an alkyl group and an organic compound having a carbazole skeleton.

FIG. 30 to FIG. 32 respectively show the blue index-current density characteristics of the sample 1 to the sample 3. The series of each graph indicate the characteristics for the time during which the sample was preserved at a high temperature. Tables 4 to 6 show the characteristics of the samples 1 to 3 to which a voltage of 4.20 V was applied.

TABLE 4
Sample 1

| High- | | | | | | | | |
|---|---|---|---|---|---|---|---|---|
| temperature | | | | Current | | | Current | |
| preservation | | Voltage | Current | density | Chromaticity | Chromaticity | efficiency | BI |
| time | | (V) | (mA) | (mA/cm²) | x | y | (cd/A) | (cd/A/y) |
| 0 | h | 4.20 | 0.462 | 11.5 | 0.137 | 0.0562 | 7.80 | 139 |
| 50 | h | 4.20 | 0.458 | 11.4 | 0.137 | 0.0561 | 7.86 | 140 |
| 94 | h | 4.20 | 0.459 | 11.5 | 0.137 | 0.0561 | 7.87 | 140 |
| 250 | h | 4.20 | 0.479 | 12.0 | 0.136 | 0.0559 | 8.01 | 143 |
| 502 | h | 4.20 | 0.461 | 11.5 | 0.137 | 0.0562 | 7.94 | 141 |
| 1000 | h | 4.20 | 0.449 | 11.2 | 0.137 | 0.0561 | 7.95 | 142 |

TABLE 5
Sample 2

| High- | | | | | | | | |
|---|---|---|---|---|---|---|---|---|
| temperature | | | | Current | | | Current | |
| preservation | | Voltage | Current | density | Chromaticity | Chromaticity | efficiency | BI |
| time | | (V) | (mA) | (mA/cm²) | x | y | (cd/A) | (cd/A/y) |
| 0 | h | 4.20 | 0.456 | 11.4 | 0.138 | 0.0543 | 8.01 | 147 |
| 50 | h | 4.20 | 0.457 | 11.4 | 0.138 | 0.0543 | 8.09 | 149 |
| 94 | h | 4.20 | 0.459 | 11.5 | 0.138 | 0.0542 | 8.08 | 149 |
| 250 | h | 4.20 | 0.477 | 11.9 | 0.138 | 0.0540 | 8.22 | 152 |
| 502 | h | 4.20 | 0.456 | 11.4 | 0.138 | 0.0542 | 8.12 | 150 |
| 1000 | h | 4.20 | 0.446 | 11.1 | 0.138 | 0.0541 | 8.13 | 150 |

TABLE 6
Sample 3

| High- | | | | | | | | |
|---|---|---|---|---|---|---|---|---|
| temperature | | | | Current | | | Current | |
| preservation | | Voltage | Current | density | Chromaticity | Chromaticity | efficiency | BI |
| time | | (V) | (mA) | (mA/cm²) | x | y | (cd/A) | (cd/A/y) |
| 0 | h | 4.20 | 0.462 | 11.5 | 0.138 | 0.0547 | 8.02 | 147 |
| 50 | h | 4.20 | 0.460 | 11.5 | 0.138 | 0.0551 | 8.10 | 147 |
| 94 | h | 4.20 | 0.464 | 11.6 | 0.138 | 0.0555 | 8.11 | 146 |
| 250 | h | 4.20 | 0.486 | 12.2 | 0.138 | 0.0570 | 8.24 | 145 |
| 502 | h | 4.20 | 0.463 | 11.6 | 0.139 | 0.0625 | 8.16 | 130 |
| 1000 | h | 4.20 | 0.456 | 11.4 | 0.138 | 0.0667 | 8.01 | 120 |

FIGS. 30 to 32 and Tables 4 to 6 confirm that the light-emitting devices of the samples 1 and 2 have characteristics hardly changing even through high-temperature preservation, and only the sample 3 has lower blue index-current density characteristics as the high-temperature preservation time increases. Table 6 shows that the decrease in blue index is caused by the increased chromaticity y. This is due to deterioration of the cap layer owing to the high-temperature preservation as shown in FIG. 29.

As described above, the light-emitting device of one embodiment of the present invention, which includes the cap layer made of a monoamine compound having an alkyl group and an organic compound having a carbazole skeleton, is found to be a light-emitting device that has high heat resistance and hardly deteriorates even when preserved at a high temperature.

The sample 3, which includes the single cap layer made of an organic compound having a carbazole skeleton, is confirmed to have an abnormal appearance in the high-temperature preservation test. Meanwhile, although including the cap layer made of an organic compound having a carbazole skeleton, the samples 1 and 2 have no abnormal appearance because the organic compound having a carbazole skeleton is stacked over the monoamine compound layer including an alkyl group. These results indicate that a combination of the organic compound layer having a carbazole skeleton and the monoamine compound layer including an alkyl group has an effect of preventing an abnormal appearance in the high-temperature preservation test. This effect is found to be obtained by using these two materials at the same time. The effect is found to be noticeable particularly when the organic compound layer having a carbazole skeleton is provided in contact with the monoamine compound layer including an alkyl group.

In the case where a thin film of an organic compound having a carbazole skeleton is used for a cap layer of a device, the thin film probably undergoes a change in film quality such as crystallization in a high-temperature environment particularly when the thin film is used as the outermost surface, which was revealed by the above experiment. It is suggested that, however, the abnormal change in film quality is inhibited when the thin film of an organic compound having a carbazole skeleton is formed in contact with a thin film of a monoamine compound having an alkyl group. This means that the thin film of a monoamine compound having an alkyl group has an effect of increasing the heat resistance of an adjacent thin film, and particularly has a noticeable effect of increasing the heat resistance of the thin film of an organic compound having a carbazole skeleton. This effect is found to be obtained by forming the thin film of a monoamine compound having an alkyl group as a base of the thin film of an organic compound having a carbazole skeleton. It is also found that the effect is obtained when the thin film of a monoamine compound having an alkyl group is formed as an upper layer of the thin film of an organic compound having a carbazole skeleton, even when the thin film of a monoamine compound having an alkyl group formed as the upper layer has a small thickness of 1 nm. This effect is an effect of combination of the thin film of an organic compound having a carbazole skeleton and the thin film of a monoamine compound having an alkyl group.

This application is based on Japanese Patent Application Serial No. 2024-112240 filed with Japan Patent Office on Jul. 12, 2024, the entire contents of which are hereby incorporated by reference.

What is claimed is:

1. A light-emitting device comprising:
a first electrode;
a second electrode;
a light-emitting layer between the first electrode and the second electrode; and
a cap layer,
wherein the second electrode is between the light-emitting layer and the cap layer,
wherein the cap layer comprises at least a first substance and a second substance,
wherein the first substance and the second substance are substances having a difference of 0.1 or more between ordinary refractive indices of respective evaporated films at a wavelength of 380 nm to 760 nm,
wherein the first substance is a monoamine compound comprising an alkyl group, and
wherein the second substance is an organic compound comprising a carbazole skeleton.

2. A light-emitting device comprising:
a first electrode;
a second electrode;
a light-emitting layer between the first electrode and the second electrode; and
a cap layer,
wherein the second electrode is between the light-emitting layer and the cap layer,
wherein the cap layer comprises at least a first layer comprising a first substance and a second layer comprising a second substance,
wherein the first substance and the second substance are substances having a difference of 0.1 or more between ordinary refractive indices of respective evaporated films at a wavelength of 380 nm to 760 nm,
wherein the first substance is a monoamine compound comprising an alkyl group, and
wherein the second substance is an organic compound comprising a carbazole skeleton.

3. A light-emitting device comprising:
a first electrode;
a second electrode;
a light-emitting layer between the first electrode and the second electrode; and
a cap layer,
wherein the second electrode is between the light-emitting layer and the cap layer,
wherein the cap layer comprises at least a first layer comprising a second substance and a second layer comprising a first substance,
wherein the first layer is between the second electrode and the second layer,
wherein the first substance and the second substance are substances having a difference of 0.1 or more between ordinary refractive indices of respective evaporated films at a wavelength of 380 nm to 760 nm,
wherein the first substance is a monoamine compound comprising an alkyl group, and
wherein the second substance is an organic compound comprising a carbazole skeleton.

4. The light-emitting device according to claim 2,
wherein the first layer is in contact with the second electrode.

5. The light-emitting device according to claim 1,
wherein the first substance and the second substance are substances having a difference of 0.3 or more between ordinary refractive indices of respective evaporated films at a wavelength of 380 nm to 760 nm.

6. The light-emitting device according to claim 1,
wherein the monoamine compound does not comprise a trifluoromethyl group.

7. The light-emitting device according to claim 1,
wherein the monoamine compound is an organic compound represented by General Formula (G_{L}1), 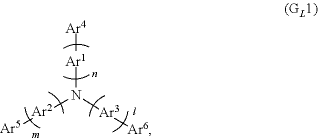
wherein Ar¹ to Ar³ each independently represent any one of a substituted or unsubstituted arylene group having 6 to 30 carbon atoms and a substituted or unsubstituted heteroarylene group having 1 to 30 carbon atoms,
wherein Ar⁴ to Ar⁶ each independently represent any one of a substituted or unsubstituted aryl group having 6 to 30 carbon atoms and a substituted or unsubstituted heteroaryl group having 1 to 30 carbon atoms,
wherein n, m, and l each independently represent any one integer of 0 to 3, and
wherein the organic compound represented by General Formula (G_{L}1) comprises one or more alkyl groups and the one or more alkyl groups are each any of a straight-chain or branched-chain alkyl group having 1 to 10 carbon atoms and a cycloalkyl group having 3 to 10 carbon atoms.

8. The light-emitting device according to claim 1,
wherein the organic compound comprising the carbazole skeleton is an organic compound represented by General Formula (G_{H}1), 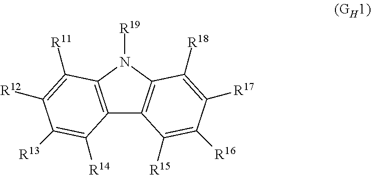
wherein R¹¹ to R¹⁸ each independently represent hydrogen, a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, and
wherein R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms.

9. The light-emitting device according to claim 1,
wherein the monoamine compound is an organic compound represented by General Formula (G_{L}1),
wherein the organic compound comprising the carbazole skeleton is an organic compound represented by General Formula (G_{H}1), 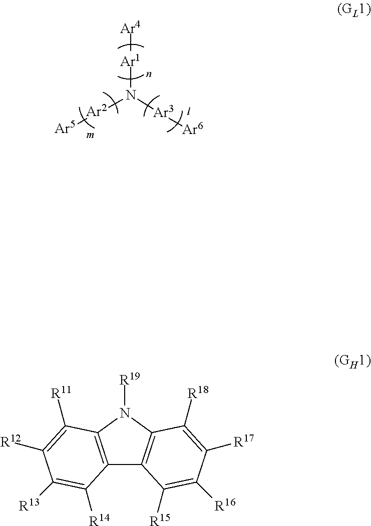
wherein in General Formula (G_{L}1),
Ar¹ to Ar³ each independently represent any one of a substituted or unsubstituted arylene group having 6 to 30 carbon atoms and a substituted or unsubstituted heteroarylene group having 1 to 30 carbon atoms,
Ar⁴ to Ar⁶ each independently represent any one of a substituted or unsubstituted aryl group having 6 to 30 carbon atoms and a substituted or unsubstituted heteroaryl group having 1 to 30 carbon atoms, and
n, m, and l each independently represent any one integer of 0 to 3,
wherein the organic compound represented by General Formula (G_{L}1) comprises one or more alkyl groups and the one or more alkyl groups are each any of a straight-chain or branched-chain alkyl group having 1 to 10 carbon atoms and a cycloalkyl group having 3 to 10 carbon atoms, and
wherein in General Formula (G_{H}1),
R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, and
R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms.

10. The light-emitting device according to claim 9,
wherein an ordinary refractive index of the evaporated film of the first substance is lower than or equal to 1.70 at a wavelength of 450 nm, and
wherein an ordinary refractive index of the evaporated film of the second substance is higher than or equal to 1.80 at the wavelength of 450 nm.

11. The light-emitting device according to claim 7,
wherein hydrogen atoms in the organic compound represented by General Formula (G_{L}1) are each independently a deuterium atom.

12. The light-emitting device according to claim 2,
wherein the first substance and the second substance are substances having a difference of 0.3 or more between ordinary refractive indices of respective evaporated films at a wavelength of 380 nm to 760 nm.

13. The light-emitting device according to claim 2,
wherein the monoamine compound is an organic compound represented by General Formula (G_{L}1), 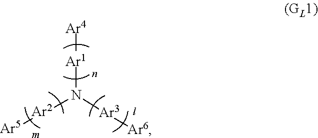
wherein Ar¹ to Ar³ each independently represent any one of a substituted or unsubstituted arylene group having 6 to 30 carbon atoms and a substituted or unsubstituted heteroarylene group having 1 to 30 carbon atoms,
wherein Ar⁴ to Ar⁶ each independently represent any one of a substituted or unsubstituted aryl group having 6 to 30 carbon atoms and a substituted or unsubstituted heteroaryl group having 1 to 30 carbon atoms,
wherein n, m, and l each independently represent any one integer of 0 to 3, and
wherein the organic compound represented by General Formula (G_{L}1) comprises one or more alkyl groups and the one or more alkyl groups are each any of a straight-chain or branched-chain alkyl group having 1 to 10 carbon atoms and a cycloalkyl group having 3 to 10 carbon atoms.

14. The light-emitting device according to claim 2,
wherein the organic compound comprising the carbazole skeleton is an organic compound represented by General Formula (G_{H}1), 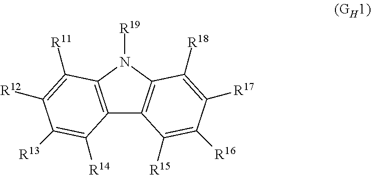
wherein R¹¹ to R¹⁸ each independently represent hydrogen, a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, and
wherein R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms.

15. The light-emitting device according to claim 2,
wherein the monoamine compound is an organic compound represented by General Formula (G_{L}1),
wherein the organic compound comprising the carbazole skeleton is an organic compound represented by General Formula (G_{H}1), 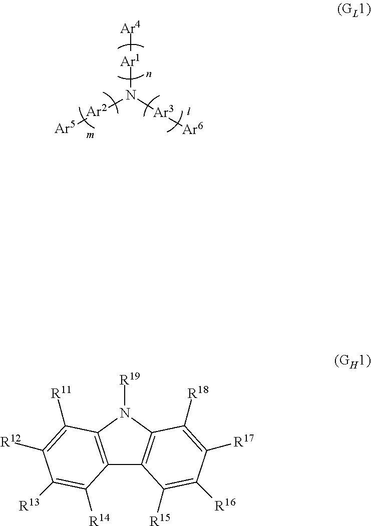
wherein in General Formula (G_{L}1),
Ar¹ to Ar³ each independently represent any one of a substituted or unsubstituted arylene group having 6 to 30 carbon atoms and a substituted or unsubstituted heteroarylene group having 1 to 30 carbon atoms,
Ar⁴ to Ar⁶ each independently represent any one of a substituted or unsubstituted aryl group having 6 to 30 carbon atoms and a substituted or unsubstituted heteroaryl group having 1 to 30 carbon atoms, and
n, m, and l each independently represent any one integer of 0 to 3,
wherein the organic compound represented by General Formula (G_{L}1) comprises one or more alkyl groups and the one or more alkyl groups are each any of a straight-chain or branched-chain alkyl group having 1 to 10 carbon atoms and a cycloalkyl group having 3 to 10 carbon atoms, and
wherein in General Formula (G_{H}1),
R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, and
R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms.

16. The light-emitting device according to claim 15,
wherein an ordinary refractive index of the evaporated film of the first substance is lower than or equal to 1.70 at a wavelength of 450 nm, and
wherein an ordinary refractive index of the evaporated film of the second substance is higher than or equal to 1.80 at the wavelength of 450 nm.

17. The light-emitting device according to claim 13,
wherein hydrogen atoms in the organic compound represented by General Formula (G_{L}1) are each independently a deuterium atom.

18. The light-emitting device according to claim 3,
wherein the first substance and the second substance are substances having a difference of 0.3 or more between ordinary refractive indices of respective evaporated films at a wavelength of 380 nm to 760 nm.

19. The light-emitting device according to claim 3,
wherein the monoamine compound is an organic compound represented by General Formula (G_{L}1),
wherein the organic compound comprising the carbazole skeleton is an organic compound represented by General Formula (G_{H}1), 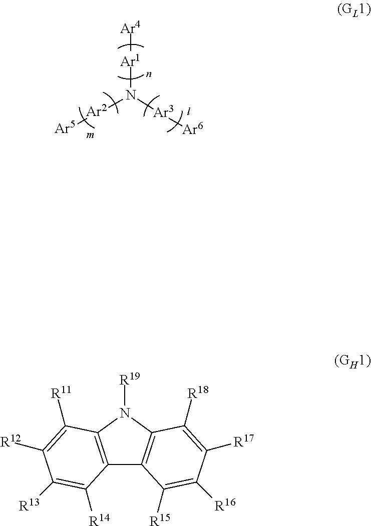
wherein in General Formula (G_{L}1),
Ar¹ to Ar³ each independently represent any one of a substituted or unsubstituted arylene group having 6 to 30 carbon atoms and a substituted or unsubstituted heteroarylene group having 1 to 30 carbon atoms,
Ar⁴ to Ar⁶ each independently represent any one of a substituted or unsubstituted aryl group having 6 to 30 carbon atoms and a substituted or unsubstituted heteroaryl group having 1 to 30 carbon atoms, and
n, m, and l each independently represent any one integer of 0 to 3,
wherein the organic compound represented by General Formula (G_{L}1) comprises one or more alkyl groups and the one or more alkyl groups are each any of a straight-chain or branched-chain alkyl group having 1 to 10 carbon atoms and a cycloalkyl group having 3 to 10 carbon atoms, and
wherein in General Formula (G_{H}1),
R¹¹ to R¹⁸ each independently represent hydrogen (including deuterium), a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms, and
R¹⁹ represents a substituted or unsubstituted alkyl group having 1 to 6 carbon atoms, a substituted or unsubstituted cycloalkyl group having 3 to 6 carbon atoms, a substituted or unsubstituted aromatic hydrocarbon group having 6 to 30 carbon atoms, or a substituted or unsubstituted heteroaromatic group having 1 to 30 carbon atoms.

20. The light-emitting device according to claim 19,
wherein an ordinary refractive index of the evaporated film of the first substance is lower than or equal to 1.70 at a wavelength of 450 nm, and
wherein an ordinary refractive index of the evaporated film of the second substance is higher than or equal to 1.80 at the wavelength of 450 nm.
